(19) United States
(12) Patent Application Publication
(10) Pub. No.: US 2017/0170325 A1
(43) Pub. Date: Jun. 15, 2017

(54) OXIDE SEMICONDUCTOR FILM, SEMICONDUCTOR DEVICE, AND DISPLAY DEVICE

(71) Applicant: Semiconductor Energy Laboratory Co., Ltd., Atsugi-shi (JP)

(72) Inventors: Junichi KOEZUKA, Tochigi (JP); Yukinori SHIMA, Tatebayashi (JP); Toshimitsu OBONAI, Shimotsuke (JP); Hiroshi KANEMURA, Tochigi (JP); Daisuke KUROSAKI, Utsunomiya (JP)

(21) Appl. No.: 15/372,554

(22) Filed: Dec. 8, 2016

(30) Foreign Application Priority Data
Dec. 11, 2015 (JP) 2015-241798

(51) Int. Cl. H01L 29/786; H01L 21/465; H01L 29/24; H01L 29/04

(52) U.S. Cl. CPC H01L 29/7869; H01L 29/045; H01L 21/465; H01L 29/24; H01L 29/78696

(57) ABSTRACT

An oxide semiconductor film contains In, M (M is Al, Ga, Y, or Sn), and Zn and includes a region with a film density higher than or equal to 6.3 g/cm³ and lower than 6.5 g/cm³. Alternatively, the oxide semiconductor film contains In, M (M is Al, Ga, Y, or Sn), and Zn and includes a region with etching at an etching rate higher than or equal to 10 nm/min and lower than or equal to 45 nm/min when a phosphoric acid aqueous solution obtained by diluting 85 vol % phosphoric acid with water 100 times is used for etching.

### TECHNICAL FIELD

One embodiment of the present invention relates to an oxide semiconductor film. One embodiment of the present invention relates to a semiconductor device including an oxide semiconductor film and a display device including the semiconductor device.

Note that one embodiment of the present invention is not limited to the above technical field. The technical field of one embodiment of the invention disclosed in this specification and the like relates to an object, a method, and a manufacturing method. In addition, one embodiment of the present invention relates to a process, a machine, manufacture, and a composition of matter. In particular, one embodiment of the present invention relates to a semiconductor device, a display device, a light-emitting device, a power storage device, a storage device, a driving method thereof, and a manufacturing method thereof.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. An imaging device, a display device, a liquid crystal display device, a light-emitting device, an electro-optical device, a power generation device (including a thin film solar cell, an organic thin film solar cell, and the like), and an electronic appliance may each include a semiconductor device.

### BACKGROUND ART

As a semiconductor material applicable to a transistor, an oxide semiconductor has been attracting attention. For example, Patent Document 1 discloses a semiconductor device achieving high field-effect mobility (simply referred to “mobility” or “μFE” in some cases) with such a structure that a plurality of oxide semiconductor layers are stacked, the oxide semiconductor layer functioning as a channel in the plurality of oxide semiconductor layers contains indium and gallium, and the proportion of indium is higher than the proportion of gallium.

Non-Patent Document 1 discloses that an oxide semiconductor containing indium, gallium, and zinc has a homologous series represented by In₁₋ₓGa₁₊ₓO₃(ZnO)ₘ (x fulfills −1≦x≦1, and m is a natural number). Furthermore, Non-Patent Document 1 discloses a solid solution range of the homologous series. For example, in the solid solution range of the homologous series in the case where m is 1, x ranges from −0.33 to 0.08, and in the solid solution range of the homologous series in the case where m is 2, x ranges from −0.68 to 0.32.

### REFERENCE

### Patent Document

[Patent Document 1] Japanese Published Patent Application No. 2014-007399

### Non-Patent Document

[Non-Patent Document 1] M. Nakamura, N. Kimizuka, and T. Mohri, “The Phase Relations in the In₂O₃—Ga₂ZnO₄—ZnO System at 1350° C.,” J. Solid State Chem., 1991, Vol. 93, pp. 298-315.

### DISCLOSURE OF INVENTION

It is preferable for a transistor using an oxide semiconductor film for a channel region to have a high field-effect mobility. However, an increase in the field-effect mobility of the transistor causes a problem in that the transistor is likely to have normally-on characteristics. Here, the “normally-on” refers to a state in which a channel exists even when voltage is not applied to the gate electrode and current flows in the transistor.

Furthermore, in a transistor using an oxide semiconductor film for a channel region, an oxygen vacancy which is formed in the oxide semiconductor film adversely affects the transistor characteristics. For example, oxygen vacancy formed in the oxide semiconductor film is bonded with hydrogen to serve as a carrier supply source. The carrier supply source generated in the oxide semiconductor film causes a change in the electrical characteristics, typically, shift in the threshold voltage, of the transistor including the oxide semiconductor film.

When the amount of oxygen vacancies in the oxide semiconductor film is too large, the threshold voltage of the transistor is shifted in the negative direction, and the transistor has normally-on characteristics. Thus, in the channel region of the oxide semiconductor film, the amount of oxygen vacancies is preferably small or the amount with which the normally-on characteristics are not exhibited.

In view of the foregoing problems, an object of one embodiment of the present invention is to provide an oxide semiconductor film which enables a high field-effect mobility when the oxide semiconductor film is used for a channel region of the transistor. Another object of one embodiment of the present invention is to prevent a change in electrical characteristics of a transistor including an oxide semiconductor film and to improve the reliability of the transistor. Another object of one embodiment of the present invention is to provide a semiconductor device with low power consumption. Another object of one embodiment of the present invention is to provide a novel semiconductor device. Another object of one embodiment of the present invention is to provide a novel display device.

Note that the description of the above object does not disturb the existence of other objects. In one embodiment of the present invention, there is no need to achieve all the objects. Objects other than the above objects will be apparent from and can be derived from the description of the specification and the like.

One embodiment of the present invention is an oxide semiconductor film containing In, M (M is any one of Al, Ga, Y, and Sn), and Zn, and the oxide semiconductor film includes a region with a film density higher than or equal to 6.3 g/cm³ and lower than 6.5 g/cm³.

Another embodiment of the present invention is an oxide semiconductor film containing In, M (M is any one of Al, Ga, Y, and Sn), and Zn, and when the oxide semiconductor film is etched using a phosphoric acid aqueous solution obtained by diluting 85 vol % phosphoric acid with water 100 times, the oxide semiconductor film includes a region obtained by etching at an etching rate that is higher than or equal to 10 nm/min and lower than or equal to 45 nm/min.

In the above embodiments, the oxide semiconductor film preferably includes a crystal part, and the crystal part preferably includes a region having c-axis alignment and a region having alignment different from the c-axis alignment.

In the above embodiments, it is preferable that the oxide semiconductor film have an atomic ratio in a neighborhood of In:M:Zn=4:2:3 and in the case where the proportion of In is 4, the proportion of M be greater than or equal to 1.5 and less than or equal to 2.5 and the proportion of Zn be greater than or equal to 2 and less than or equal to 4.

Another embodiment of the present invention is a semiconductor device including an oxide semiconductor film, and the semiconductor device includes the oxide semiconductor film over a first insulating film, a gate insulating film over the oxide semiconductor film, a gate electrode over the gate insulating film, and a second insulating film over the oxide semiconductor film and the gate electrode. The oxide semiconductor film includes a channel region in contact with the gate insulating film, a source region in contact with the second insulating film, and a drain region in contact with the second insulating film. The oxide semiconductor film includes a region with a film density higher than or equal to 6.3 g/cm³ and lower than 6.5 g/cm³.

Another embodiment of the present invention is a semiconductor device including an oxide semiconductor film, and the semiconductor device includes a gate electrode, a gate insulating film over the gate electrode, the oxide semiconductor film over the gate insulating film, and a pair of electrodes over the oxide semiconductor film. The oxide semiconductor film includes a region with a film density higher than or equal to 6.3 g/cm³ and lower than 6.5 g/cm³.

In the above embodiments, it is preferable that the oxide semiconductor film include In, M (M is Al, Ga, Y, or Sn), and Zn. In the above embodiments, the oxide semiconductor film preferably includes a crystal part, and the crystal part preferably includes a region having c-axis alignment and a region having alignment different from the c-axis alignment.

Another embodiment of the present invention is a display device including the semiconductor device according to any one of the above embodiments, and a display element. Another embodiment of the present invention is a display module including the display device and a touch sensor. Another embodiment of the present invention is an electronic device including the semiconductor device according to any one of the above embodiments, the display device, or the display module, and an operation key or a battery.

According to one embodiment of the present invention, an oxide semiconductor film which enables a high field-effect mobility can be provided in the case where the oxide semiconductor film is used for a channel region of a transistor. According to one embodiment of the present invention, a change in electrical characteristics can be suppressed and reliability can be improved in a transistor including an oxide semiconductor film. Alternatively, according to one embodiment of the present invention, a semiconductor device with low power consumption can be provided. According to one embodiment of the present invention, a novel semiconductor device can be provided. According to one embodiment of the present invention, a novel display device can be provided.

Note that the description of these effects does not preclude the existence of other effects. One embodiment of the present invention does not necessarily achieve all the effects listed above. Other effects will be apparent from and can be derived from the description of the specification, the drawings, the claims, and the like.

### BRIEF DESCRIPTION OF DRAWINGS

FIG. 1 shows film densities of oxide semiconductor films.

FIG. 2 shows a correlation between the film density of an oxide semiconductor film and the etching rate of the oxide semiconductor film.

FIGS. 3A to 3C show XRD measurement results of oxide semiconductor films.

FIGS. 4A to 4C show XRD measurement results of oxide semiconductor films.

FIGS. 5A to 5C show XRD measurement results of oxide semiconductor films.

FIGS. 6A to 6C show XRD measurement results of oxide semiconductor films.

FIG. 7 shows a correlation between the film density of an oxide semiconductor film and the integral intensity of a peak around 2θ=31° of the oxide semiconductor film.

FIGS. 8A to 8C each show a range of the atomic ratio of an oxide semiconductor film.

FIG. 9 illustrates an InMZnO₄ crystal.

FIGS. 10A to 10E show structural analysis of a CAAC-OS and a single crystal oxide semiconductor film by XRD and selected-area electron diffraction patterns of a CAAC-OS.

FIGS. 11A to 11E show a cross-sectional TEM image and plan-view TEM images of a CAAC-OS and images obtained through analysis thereof.

FIGS. 12A to 12D show electron diffraction patterns and a cross-sectional TEM image of an nc-OS.

FIGS. 13A and 13B are cross-sectional TEM images of an a-like OS.

FIG. 14 shows changes in crystal parts of In—Ga—Zn oxides induced by electron irradiation.

FIG. 15A is a top view illustrating a semiconductor device, and FIGS. 15B and 15C are cross-sectional views illustrating the semiconductor device.

FIGS. 16A to 16C are a top view and cross-sectional views illustrating a semiconductor device.

FIGS. 17A and 17B are cross-sectional views illustrating a semiconductor device.

FIGS. 18A and 18B are cross-sectional views illustrating a semiconductor device.

FIGS. 19A and 19B are cross-sectional views illustrating a semiconductor device.

FIGS. 20A and 20B are cross-sectional views illustrating a semiconductor device.

FIGS. 21A and 21B are cross-sectional views illustrating a semiconductor device.

FIGS. 22A and 22B are cross-sectional views illustrating a semiconductor device.

FIGS. 23A and 23B are cross-sectional views illustrating a semiconductor device.

FIGS. 24A and 24B are cross-sectional views illustrating a semiconductor device.

FIGS. 25A and 25B are cross-sectional views illustrating a semiconductor device.

FIGS. 26A to 26C show band structures.

FIGS. 27A to 27C are a top view and cross-sectional views illustrating a semiconductor device.

FIGS. 28A to 28C are a top view and cross-sectional views illustrating a semiconductor device.

FIGS. 29A to 29C are a top view and cross-sectional views illustrating a semiconductor device.

FIGS. 30A to 30C are a top view and cross-sectional views illustrating a semiconductor device.

FIGS. 31A and 31B are cross-sectional views illustrating a semiconductor device.

FIGS. 32A and 32B are cross-sectional views illustrating a semiconductor device.

FIGS. 33A to 33C are a top view and cross-sectional views illustrating a semiconductor device.

FIG. 34 is a top view illustrating one embodiment of a display device.

FIG. 35 is a cross-sectional view illustrating one embodiment of a display device.

FIG. 36 is a cross-sectional view illustrating one embodiment of a display device.

FIG. 37 is a cross-sectional view illustrating one embodiment of a display device.

FIG. 38 is a cross-sectional view illustrating one embodiment of a display device.

FIG. 39 is a cross-sectional view illustrating one embodiment of a display device.

FIGS. 40A to 40C are a block diagram and circuit diagrams illustrating a display device.

FIGS. 41A to 41C are circuit diagrams and a timing chart illustrating one embodiment of the present invention.

FIGS. 42A to 42C are a graph and circuit diagrams illustrating one embodiment of the present invention.

FIGS. 43A and 43B are a circuit diagram and a timing chart illustrating one embodiment of the present invention.

FIGS. 44A and 44B are a circuit diagram and a timing chart illustrating one embodiment of the present invention.

FIGS. 45A to 45E are a block diagram, circuit diagrams, and waveform diagrams illustrating one embodiment of the present invention.

FIGS. 46A and 46B are a circuit diagram and a timing chart illustrating one embodiment of the present invention.

FIGS. 47A and 47B are circuit diagrams each illustrating one embodiment of the present invention.

FIGS. 48A to 48C are circuit diagrams each illustrating one embodiment of the present invention.

FIG. 49 illustrates a display module.

FIGS. 50A to 50E illustrate electronic devices.

FIGS. 51A to 51G illustrate electronic devices.

FIGS. 52A and 52B are perspective views illustrating a display device.

FIGS. 53A and 53B are graphs each showing carrier densities of oxide semiconductor films.

FIG. 54 shows measurement results of I_{d}-V_{g} characteristics of transistors.

FIG. 55 shows measurement results of I_{d}-V_{g} characteristics of transistors.

FIG. 56 shows measurement results of I_{d}-V_{g} characteristics of transistors.

FIG. 57A shows a correlation between a field-effect mobility of a transistor and an etching rate of an oxide semiconductor film, and FIG. 57B shows a correlation between a threshold voltage of the transistor and an etching rate of the oxide semiconductor film.

FIGS. 58A and 58B are a top view and a cross-sectional view illustrating a structure of a sample in Example.

FIG. 59 shows sheet resistance of samples in Example.

FIGS. 60A and 60B each show I_{d}-V_{g} characteristics of transistors in Example.

FIGS. 61A and 61B each show I_{d}-V_{g} characteristics of transistors in Example.

FIG. 62 shows I_{d} in samples in Example.

FIG. 63 shows a display example of a display device in Example.

FIGS. 64A to 64C illustrate a method for fabricating a sample in Example, and FIG. 64D is a cross-sectional view illustrating a structure of the sample.

FIG. 65 shows resistivity of samples in Example.

FIGS. 66A and 66B each show measurement results of I_{d}-V_{g} characteristics of transistors.

FIGS. 67A and 67B each show measurement results of I_{d}-V_{g} characteristics of transistors.

FIGS. 68A and 68B each show measurement results of I_{d}-V_{g} characteristics of transistors.

FIGS. 69A and 69B each show measurement results of I_{d}/W−V_{d} characteristics of transistors.

FIG. 70 is a cross-sectional TEM image of a transistor.

FIG. 71 shows measurement results of I_{d}-V_{g} characteristics of a transistor.

FIG. 72 is a cross-sectional TEM image of a transistor.

### BEST MODE FOR CARRYING OUT THE INVENTION

Hereinafter, embodiments will be described with reference to drawings. However, the embodiments can be implemented in many different modes, and it will be readily appreciated by those skilled in the art that modes and details thereof can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings are schematic views showing ideal examples, and embodiments of the present invention are not limited to shapes or values shown in the drawings.

Note that in this specification, ordinal numbers such as “first”, “second”, and “third” are used in order to avoid confusion among components, and the terms do not limit the components numerically.

In this specification, terms for describing arrangement, such as “over”, “above”, “under”, and “below”, are used for convenience in describing a positional relation between components with reference to drawings. Furthermore, the positional relationship between components is changed as appropriate in accordance with a direction in which each component is described. Thus, there is no limitation on terms used in this specification, and description can be made appropriately depending on the situation.

In this specification and the like, a transistor is an element having at least three terminals of a gate, a drain, and a source. The transistor has a channel region between a drain (a drain terminal, a drain region, or a drain electrode) and a source (a source terminal, a source region, or a source electrode), and current can flow through the drain, the channel region, and the source. Note that in this specification and the like, a channel region refers to a region through which current mainly flows.

Furthermore, functions of a source and a drain might be switched when transistors having different polarities are employed or a direction of current flow is changed in circuit operation, for example. Therefore, the terms “source” and “drain” can be switched in this specification and the like.

Note that in this specification and the like, the term “electrically connected” includes the case where components are connected through an object having any electric function. There is no particular limitation on the “object having any electric function” as long as electric signals can be transmitted and received between components that are connected through the object. Examples of an “object having any electric function” are a switching element such as a transistor, a resistor, an inductor, a capacitor, and an element with a variety of functions as well as an electrode and a wiring.

In this specification and the like, the term “parallel” indicates that the angle formed between two straight lines is greater than or equal to −10° and less than or equal to 10°, and accordingly also includes the case where the angle is greater than or equal to −5° and less than or equal to 5°. In addition, the term “perpendicular” means that the angle formed between two straight lines is greater than or equal to 80° and less than or equal to 100°. Thus, the case where the angle is greater than or equal to 85° and less than or equal to 95° is also included.

In this specification and the like, the terms “film” and “layer” can be interchanged with each other depending on the case or circumstances. For example, the term “conductive layer” can be changed into the term “conductive film” in some cases. In addition, the term “insulating film” can be changed into the term “insulating layer” in some cases.

Unless otherwise specified, off-state current in this specification and the like refers to drain current of a transistor in an off state (also referred to as a non-conducting state and a cutoff state). Unless otherwise specified, the off state of an n-channel transistor means that the voltage between its gate and source (V_{gs}: gate-source voltage) is lower than the threshold voltage Vₜₕ, and the off state of a p-channel transistor means that the gate-source voltage V_{gs} is higher than the threshold voltage Vₜₕ. For example, the off-state current of an n-channel transistor sometimes refers to a drain current that flows when the gate-source voltage V_{gs} is lower than the threshold voltage Vₜₕ.

The off-state current of a transistor depends on V_{gs} in some cases. Thus, “the off-state current of a transistor is lower than or equal to I” may mean “there is V_{gs} with which the off-state current of the transistor becomes lower than or equal to I”. Furthermore, “the off-state current of a transistor” means “the off-state current in an off state at predetermined V_{gs}”, “the off-state current in an off state at V_{gs} in a predetermined range”, “the off-state current in an off state at V_{gs} with which sufficiently reduced off-state current is obtained”, or the like.

As an example, the assumption is made of an n-channel transistor where the threshold voltage Vₜₕ is 0.5 V and the drain current is 1×10⁻⁹ A at V_{gs} of 0.5 V, 1×10⁻¹³ A at V_{gs} of 0.1 V, 1×10⁻¹⁹ A at V_{gs} of −0.5 V, and 1×10⁻²² A at V_{gs} of −0.8 V. The drain current of the transistor is 1×10⁻¹⁹ A or lower at V_{gs} of −0.5 V or at V_{gs} in the range of −0.8 V to −0.5 V; therefore, it can be said that the off-state current of the transistor is 1×10⁻¹⁹ A or lower. Since there is V_{gs} at which the drain current of the transistor is 1×10⁻²² A or lower, it may be said that the off-state current of the transistor is 1×10⁻²² A or lower.

In this specification and the like, the off-state current of a transistor with a channel width W is sometimes represented by a current value per channel width W or by a current value per given channel width (e.g., 1 μm). In the latter case, the off-state current may be expressed in the unit with the dimension of current per length (e.g., A/μm).

The off-state current of a transistor depends on temperature in some cases. Unless otherwise specified, the off-state current in this specification may be an off-state current at room temperature, 60° C., 85° C., 95° C., or 125° C. Alternatively, the off-state current may be an off-state current at a temperature at which the reliability required in a semiconductor device or the like including the transistor is ensured or a temperature at which the semiconductor device or the like including the transistor is used (e.g., temperature in the range of 5° C. to 35° C.). The description “an off-state current of a transistor is lower than or equal to I” may refer to a situation where there is V_{gs} at which the off-state current of a transistor is lower than or equal to I at room temperature, 60° C., 85° C., 95° C., 125° C., a temperature at which the reliability required in a semiconductor device or the like including the transistor is ensured, or a temperature at which the semiconductor device or the like including the transistor is used (e.g., temperature in the range of 5° C. to 35° C.).

The off-state current of a transistor depends on voltage Vas between its drain and source in some cases. Unless otherwise specified, the off-state current in this specification may be an off-state current at V_{ds} of 0.1 V, 0.8 V, 1 V, 1.2 V, 1.8 V, 2.5 V, 3 V, 3.3 V, 10 V, 12 V, 16 V, or 20 V. Alternatively, the off-state current might be an off-state current at Vas at which the required reliability of a semiconductor device or the like including the transistor is ensured or Vas at which the semiconductor device or the like including the transistor is used. The description “an off-state current of a transistor is lower than or equal to a current I” may mean that there is V_{gs} at which the off-state current of the transistor is lower than or equal to the current I at a voltage V_{ds} of 0.1 V, 0.8 V, 1 V, 1.2 V, 1.8 V, 2.5 V, 3 V, 3.3 V, 10 V, 12 V, 16 V, or 20 V, at a voltage V_{ds} at which the reliability of a semiconductor device or the like including the transistor is ensured, or at a voltage V_{ds} at which in the semiconductor device or the like including the transistor is used.

In the above description of off-state current, a drain may be replaced with a source. That is, the off-state current sometimes refers to a current that flows through a source of a transistor in the off state.

In this specification and the like, the term “leakage current” sometimes expresses the same meaning as “off-state current”. In this specification and the like, the off-state current sometimes refers to current that flows between a source and a drain of a transistor in the off state, for example.

In this specification and the like, a “semiconductor” includes characteristics of an “insulator” in some cases when the conductivity is sufficiently low, for example. Further, a “semiconductor” and an “insulator” cannot be strictly distinguished from each other in some cases because a border between the “semiconductor” and the “insulator” is not clear. Accordingly, a “semiconductor” in this specification and the like can be called an “insulator” in some cases. Similarly, an “insulator” in this specification and the like can be called a “semiconductor” in some cases. An “insulator” in this specification and the like can be called a “semi-insulator” in some cases.

In this specification and the like, a “semiconductor” includes characteristics of a “conductor” in some cases when the conductivity is sufficiently high, for example. Further, a “semiconductor” and a “conductor” cannot be strictly distinguished from each other in some cases because a border between the “semiconductor” and the “conductor” is not clear. Accordingly, a “semiconductor” in this specification and the like can be called a “conductor” in some cases. Similarly, a “conductor” in this specification and the like can be called a “semiconductor” in some cases.

In this specification and the like, an impurity in a semiconductor refers to an element that is not a main component of the semiconductor film. For example, an element with a concentration lower than 0.1 atomic % is an impurity. If a semiconductor contains an impurity, the density of states (DOS) may be formed therein, the carrier mobility may be decreased, or the crystallinity may be decreased, for example. In the case where the semiconductor includes an oxide semiconductor, examples of an impurity which changes the characteristics of the semiconductor include Group 1 elements, Group 2 elements, Group 13 elements, Group 14 elements, Group 15 elements, and transition metals other than the main components; specific examples are hydrogen (included in water), lithium, sodium, silicon, boron, phosphorus, carbon, and nitrogen. When the semiconductor is an oxide semiconductor, oxygen vacancies may be formed by entry of impurities such as hydrogen, for example. Furthermore, in the case where the semiconductor includes silicon, examples of an impurity which changes the characteristics of the semiconductor include oxygen, Group 1 elements except hydrogen, Group 2 elements, Group 13 elements, and Group 15 elements.

### Embodiment 1

In this embodiment, an oxide semiconductor film which is one embodiment of the present invention is described.

The oxide semiconductor film of one embodiment of the present invention includes indium (In), M (M is Al, Ga, Y, or Sn), and zinc (Zn). Specifically, M is preferably gallium (Ga). In the following description, Ga is used as M

An oxide semiconductor film containing In has high carrier mobility (electron mobility), for example. An oxide semiconductor film has high energy gap (Eg) by containing Ga, for example. Note that Ga is an element having high bonding energy with oxygen, which is higher than the bonding energy of In with oxygen. In addition, an oxide semiconductor film containing Zn is easily crystallized.

The oxide semiconductor film of one embodiment of the present invention preferably has a crystal structure exhibiting a single phase, particularly, homologous series. For example, the oxide semiconductor film has a composition of In_{1+M}M₁₋ₓO₃(ZnO)_{y} structure (x satisfies 0<x<0.5, and y is approximately 1) where the content of In is higher than that of M, so that the carrier density (electron mobility) of the oxide semiconductor film can be high.

In particular, the oxide semiconductor film of one embodiment of the present invention preferably has a composition in the neighborhood of the In₁₊ₓM₁₋ₓO₃(ZnO)_{y} structure (x satisfies 0<x<0.5, and y is approximately 1), specifically a composition in the neighborhood of a structure where In:M:Zn=1.33:0.67:1 (around In:M:Zn=4:2:3).

In this specification and the like, “neighborhood” means a range of ±1, preferably ±0.5 with respect to the proportion of atoms of a metal element. For example, in the case where the oxide semiconductor film has a composition in the neighborhood of In:Ga:Zn=4:2:3 where the proportion of In is 4, the proportion of Ga may be greater than or equal to 1 and less than or equal to 3 (1≦Ga≦3) and the proportion of Zn is greater than or equal to 2 and less than or equal to 4 (2≦Zn≦4), preferably the proportion of Ga is greater than or equal to 1.5 and less than or equal to 2.5 (1.5≦Ga≦2.5) and the proportion of Zn is greater than or equal to 2 and less than or equal to 4 (2≦Zn≦4).

The oxide semiconductor film of one embodiment of the present invention has a high film density. Specifically, the oxide semiconductor film has a region where the film density is higher than or equal to 6.3 g/cm³ and lower than 6.5 g/cm³.

When the oxide semiconductor film having the above composition and the above film density is used for a channel region of a transistor, a semiconductor device with high field-effect mobility and high reliability can be provided.

Examples of a method for forming the oxide semiconductor film of one embodiment of the present invention include a sputtering method, a pulsed laser deposition (PLD) method, a plasma-enhanced chemical vapor deposition (PECVD) method, a thermal chemical vapor deposition (CVD) method, an atomic layer deposition (ALD) method, and a vacuum evaporation method. As an example of a thermal CVD method, a metal organic chemical vapor deposition (MOCVD) method can be given. It is particularly preferable that the oxide semiconductor film of one embodiment of the present invention be formed with use of a sputtering apparatus because the oxide semiconductor film can have a high film density.

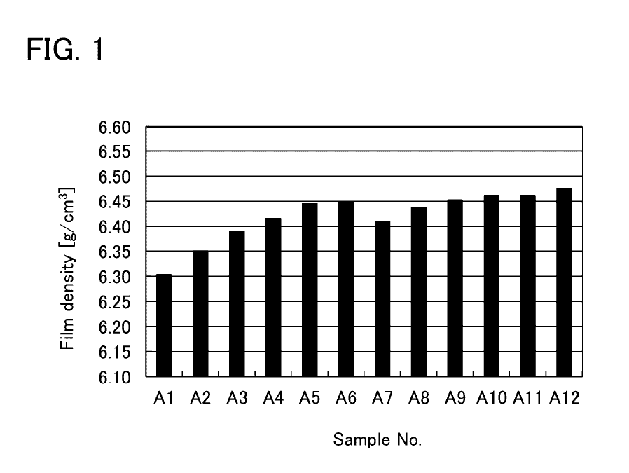

Here, the film density of the oxide semiconductor film of one embodiment of the present invention is described with reference to FIG. 1.

### <1-1. Film Density of Oxide Semiconductor Film>

FIG. 1 shows measurement results of film densities of oxide semiconductor films (Samples A1 to A12) of embodiments of the present invention. Note that Samples A1 to A12 are each a sample in which the oxide semiconductor film of one embodiment of the present invention is formed.

First, methods for fabricating Samples A1 to A12 are described below.

### (Sample A1)

Sample A1 is a sample in which a 100-nm-thick oxide semiconductor film containing indium, gallium, and zinc (hereinafter, the film is referred to as an IGZO film) is deposited over a glass substrate. The deposition conditions of the IGZO film were as follows: the substrate temperature was room temperature (R.T.); an argon gas with a flow rate of 180 sccm and an oxygen gas with a flow rate of 20 sccm were introduced into a chamber of a sputtering apparatus; the pressure was 0.6 Pa; and an alternating current (AC) power of 2.5 kW was applied to a metal oxide target containing indium, gallium, and zinc (In:Ga:Zn=4:2:4.1 [atomic ratio]). Note that the proportion of oxygen flow rate with respect to the total gas flow rate is referred to as an oxygen flow rate ratio in some cases. Thus, the oxygen flow rate ratio for fabricating Sample A1 was 10%.

### (Sample A2)

Sample A2 is a sample in which a 100-nm-thick IGZO film is deposited over a glass substrate. The deposition conditions of the oxide semiconductor film in Sample A2 were as follows: an argon gas with a flow rate of 140 sccm and an oxygen gas with a flow rate of 60 sccm were introduced into a chamber of a sputtering apparatus; and the conditions other than the flow rates of the argon gas and the oxygen gas were the same as those for Sample A1 described above. Note that the oxygen flow rate ratio for fabricating Sample A2 was 30%.

### (Sample A3)

Sample A3 is a sample in which a 100-nm-thick IGZO film is deposited over a glass substrate. The deposition conditions of the oxide semiconductor film in Sample A3 were as follows: an argon gas with a flow rate of 100 sccm and an oxygen gas with a flow rate of 100 sccm were introduced into a chamber of a sputtering apparatus; and the conditions other than the flow rates of the argon gas and the oxygen gas were the same as those for Sample A1 described above. Note that the oxygen flow rate ratio for fabricating Sample A3 was 50%.

### (Sample A4)

Sample A4 is a sample in which a 100-nm-thick IGZO film is deposited over a glass substrate. The deposition conditions of the oxide semiconductor film in Sample A4 were as follows: the substrate temperature was 100° C.; and the conditions other than the substrate temperature were the same as those for Sample A1 described above. Note that the oxygen flow rate ratio for fabricating Sample A4 was 10%.

### (Sample A5)

Sample A5 is a sample in which a 100-nm-thick IGZO film is deposited over a glass substrate. The deposition conditions of the oxide semiconductor film in Sample A5 were as follows: the substrate temperature was 100° C.; and the conditions other than the substrate temperature were the same as those for Sample A2 described above. Note that the oxygen flow rate ratio for fabricating Sample A5 was 30%.

### (Sample A6)

Sample A6 is a sample in which a 100-nm-thick IGZO film is deposited over a glass substrate. The deposition conditions of the oxide semiconductor film in Sample A6 were as follows: the substrate temperature was 100° C.; and the conditions other than the substrate temperature were the same as those for Sample A3 described above. Note that the oxygen flow rate ratio for fabricating Sample A6 was 50%.

### (Sample A7)

Sample A7 is a sample in which a 100-nm-thick IGZO film is deposited over a glass substrate. The deposition conditions of the oxide semiconductor film in Sample A7 were as follows: the substrate temperature was 130° C.; and the conditions other than the substrate temperature were the same as those for Sample A1 described above. Note that the oxygen flow rate ratio for fabricating Sample A7 was 10%.

### (Sample A8)

Sample A8 is a sample in which a 100-nm-thick IGZO film is deposited over a glass substrate. The deposition conditions of the oxide semiconductor film in Sample A8 were as follows: the substrate temperature was 130° C.; and the conditions other than the substrate temperature were the same as those for Sample A2 described above. Note that the oxygen flow rate ratio for fabricating Sample A8 was 30%.

### (Sample A9)

Sample A9 is a sample in which a 100-nm-thick IGZO film is deposited over a glass substrate. The deposition conditions of the oxide semiconductor film in Sample A9 were as follows: the substrate temperature was 130° C.; and the conditions other than the substrate temperature were the same as those for Sample A3 described above. Note that the oxygen flow rate ratio for fabricating Sample A9 was 50%.

### (Sample A10)

Sample A10 is a sample in which a 100-nm-thick IGZO film is deposited over a glass substrate. The deposition conditions of the oxide semiconductor film in Sample A10 were as follows: the substrate temperature was 170° C.; and the conditions other than the substrate temperature were the same as those for Sample A1 described above. Note that the oxygen flow rate ratio for fabricating Sample A10 was 10%.

### (Sample A11)

Sample A11 is a sample in which a 100-nm-thick IGZO film is deposited over a glass substrate. The deposition conditions of the oxide semiconductor film in Sample A11 were as follows: the substrate temperature was 170° C.; and the conditions other than the substrate temperature were the same as those for Sample A2 described above. Note that the oxygen flow rate ratio for fabricating Sample A11 was 30%.

### (Sample A12)

Sample A12 is a sample in which a 100-nm-thick IGZO film is deposited over a glass substrate. The deposition conditions of the oxide semiconductor film in Sample A12 were as follows: the substrate temperature was 170° C.; and the conditions other than the substrate temperature were the same as those for Sample A3 described above. Note that the oxygen flow rate ratio for fabricating Sample A12 was 50%.

Table 1 shows the deposition conditions and film densities of the oxide semiconductor films in Samples A1 to A12.

TABLE 1

| | Deposition condition | | |
|---|---|---|---|
| | Substrate | Oxygen flow | |
| | temperature [° C.] | rate ratio [%] | Film density [g/cm³] |
| Sample A1 | Room temperature | 10 | 6.30 |
| Sample A2 | Room temperature | 30 | 6.35 |
| Sample A3 | Room temperature | 50 | 6.39 |
| Sample A4 | 100° C. | 10 | 6.42 |
| Sample A5 | 100° C. | 30 | 6.45 |
| Sample A6 | 100° C. | 50 | 6.45 |
| Sample A7 | 130° C. | 10 | 6.41 |
| Sample A8 | 130° C. | 30 | 6.44 |
| Sample A9 | 130° C. | 50 | 6.45 |
| Sample A10 | 170° C. | 10 | 6.46 |
| Sample A11 | 170° C. | 30 | 6.46 |
| Sample A12 | 170° C. | 50 | 6.48 |

Note that X-ray reflectometry (XRR) was used for measurement of the film densities of the oxide semiconductor films.

As shown in FIG. 1 and Table 1, the film density of the oxide semiconductor film can be controlled by changes in the deposition conditions such as the substrate temperature and the oxygen flow rate ratio.

The ideal film density of the oxide semiconductor film satisfying In:Ga:Zn=1:1:1 [atomic ratio] is 6.357 g/cm³ that is the ideal density of single crystal InGaZnO₄. On the other hand, the oxide semiconductor satisfying In:Ga:Zn=4:2:3 [atomic ratio] has no ideal crystal structure. Note that Non-Patent Document 1 discloses that the density of crystal powder satisfying In:Ga:Zn=4:2:3 [atomic ratio] is 6.462 g/cm³. Thus, in this specification and the like, the ideal film density of the oxide semiconductor film satisfying In:Ga:Zn=4:2:3 [atomic ratio] is assumed to be 6.462 g/cm³, on the basis of the density of crystal powder satisfying In:Ga:Zn=4:2:3 [atomic ratio].

However, in some cases, the deposited oxide semiconductor film has a composition different from that represented by In:Ga:Zn=4:2:3 [atomic ratio] or a crystal structure different from that of a single crystal. Alternatively, a slight error is caused in the film density of the deposited oxide semiconductor film in some cases, depending on the measurement accuracy or analysis accuracy in measuring the film density of the deposited oxide semiconductor by XRR. Thus, the ideal density of the oxide semiconductor film satisfying In:Ga:Zn=4:2:3 [atomic ratio] has a margin of deviation of ±3% of 6.462 g/cm³. In other words, the ideal film density of the oxide semiconductor film satisfying In:Ga:Zn=4:2:3 [atomic ratio] is higher than or equal to 6.268 g/cm³ and lower than or equal to 6.656 g/cm³.

When the thickness of the oxide semiconductor film is thin, e.g., less than or equal to 50 nm, the film density of the oxide semiconductor film cannot be measured accurately in some cases. However, it is sometimes possible to estimate the film density of the oxide semiconductor film on some level by measuring the etching speed (also referred to as etching rate) of the oxide semiconductor film.

### <1-2. Etching Rate of Oxide Semiconductor Film>

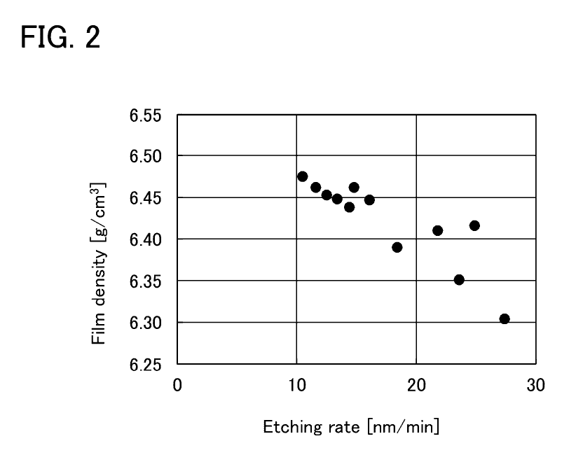

The etching rate of the oxide semiconductor film of one embodiment of the present invention is described with reference to FIG. 2.

FIG. 2 shows a correlation between the film density of the oxide semiconductor film and the etching rate of the oxide semiconductor film. In FIG. 2, the vertical axis represents the film density, and the horizontal axis represents the etching rate. Note that the etching rate is a value obtained by etching of the oxide semiconductor films in Samples A1 to A12, with use of a phosphoric acid aqueous solution that is obtained by diluting 85 vol % phosphoric acid with water 100 times.

According to FIG. 2, the correlation exists between the film density of the oxide semiconductor film and the etching rate of the oxide semiconductor film. Thus, the etching rate of the oxide semiconductor film is one of the most important data for estimating the film density of the oxide semiconductor film.

### <1-3. Evaluation of Crystallinity of Oxide Semiconductor Film>

Next, the oxide semiconductor films in Samples A1 to A12 described above were analyzed by X-ray diffraction (XRD), whereby the crystallinity of the oxide semiconductor films was evaluated.

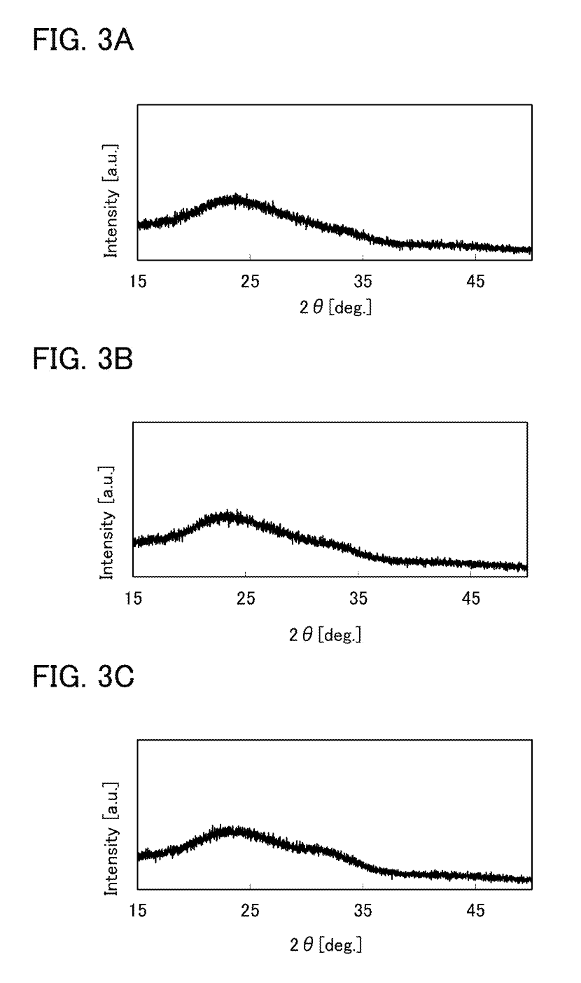

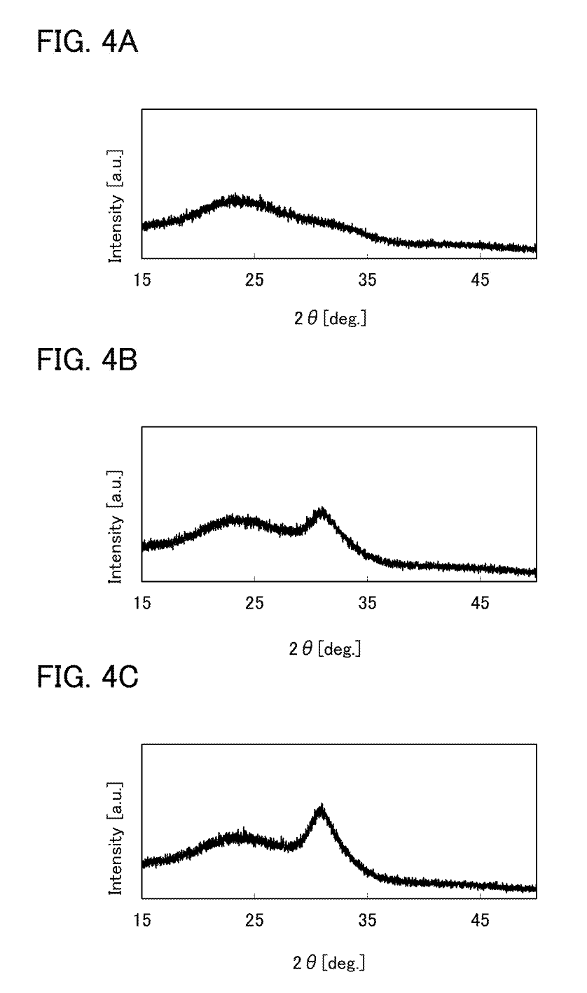

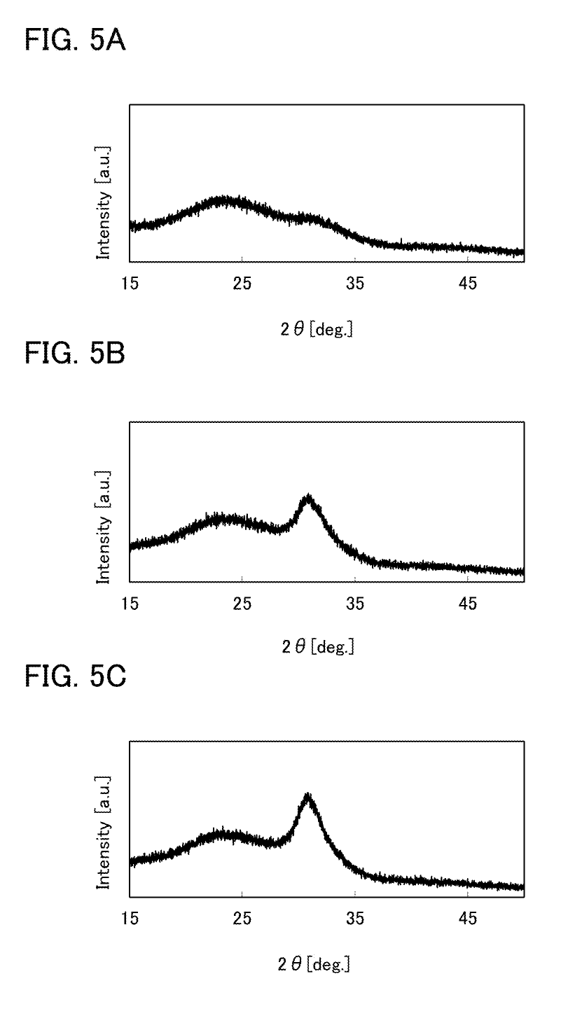

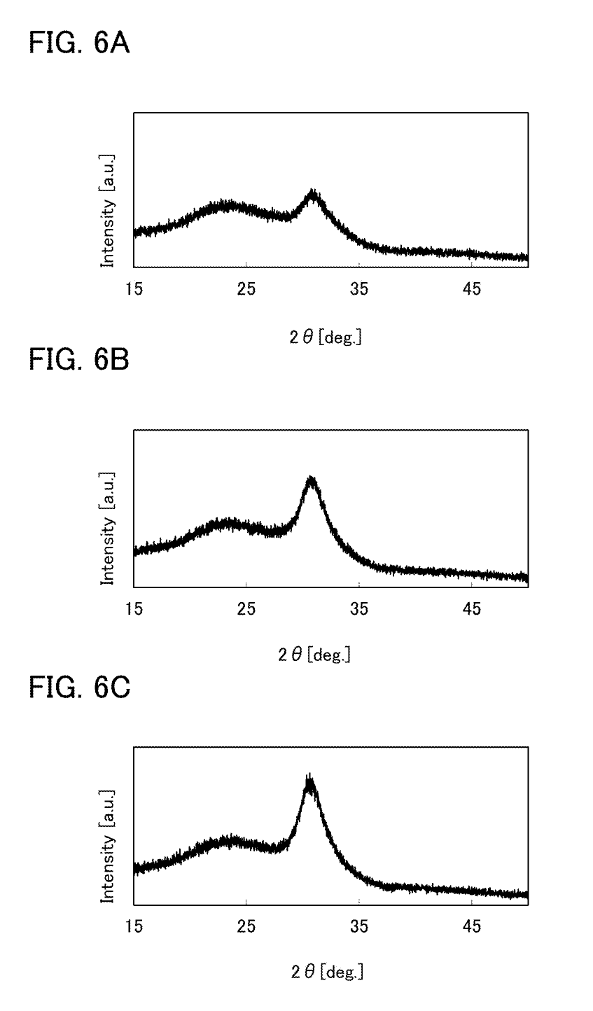

The XRD measurement results of Samples A1 to A12 are shown in FIGS. 3A to 3C, FIGS. 4A to 4C, FIGS. 5A to 5C, and FIGS. 6A to 6C. FIG. 3A shows the XRD measurement result of Sample A1, FIG. 3B shows the XRD measurement result of Sample A2, FIG. 3C shows the XRD measurement result of Sample A3, FIG. 4A shows the XRD measurement result of Sample A4, FIG. 4B shows the XRD measurement result of Sample A5, FIG. 4C shows the XRD measurement result of Sample A6, FIG. 5A shows the XRD measurement result of Sample A7, FIG. 5B shows the XRD measurement result of Sample A8, FIG. 5C shows the XRD measurement result of Sample A9, FIG. 6A shows the XRD measurement result of Sample A10, FIG. 6B shows the XRD measurement result of Sample A11, and FIG. 6C shows the XRD measurement result of Sample A12.

As shown in FIGS. 3A to 3C, FIGS. 4A to 4C, FIGS. 5A to 5C, and FIGS. 6A to 6C, in each of Samples A5 to A12, a peak indicating crystallinity is observed at around 2θ=31°. In contrast, in each of Samples A1 to A4, a peak indicating crystallinity is not clearly observed at around 2θ=31°.

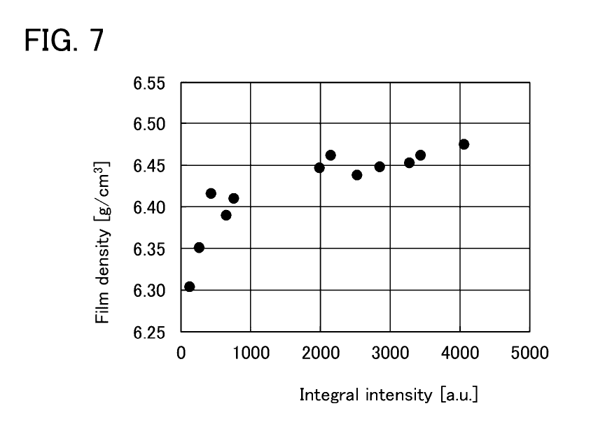

From the XRD measurement results shown in FIGS. 3A to 3C, FIGS. 4A to 4C, FIGS. 5A to 5C, and FIGS. 6A to 6C, the integral intensities of peaks at around 2θ=31° were analyzed, so that a correlation between the film density of the oxide semiconductor film and the integral intensity of the XRD peak at around 2θ=31° was examined. FIG. 7 shows a correlation between the film density of the oxide semiconductor film and the integral intensity of the XRD peak at around 2θ=31°.

As shown in FIG. 7, the correlation between the film density of the oxide semiconductor film and the integral intensity of the XRD peak at around 2θ=31° is observed. As the integral intensity of the XRD peak at around 2θ=31° increases, the film density of the oxide semiconductor becomes high. Thus, the integral intensity of the XRD peak at around 2θ=31° is one of the important data for estimating the film density of the oxide semiconductor film.

### <1-4. Composition and Structure of Oxide Semiconductor Film>

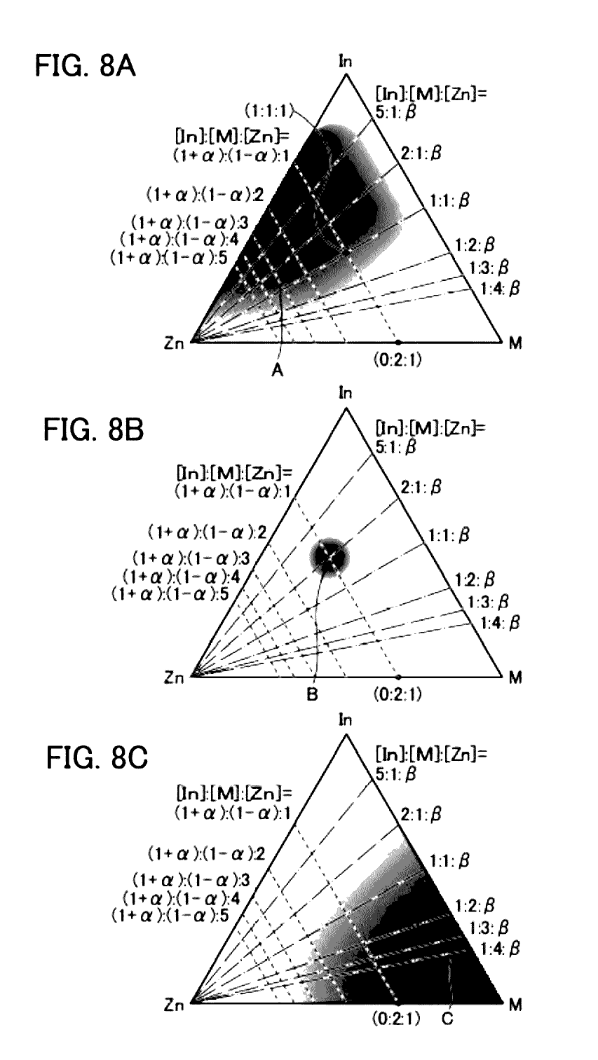

Next, a composition, structure, and the like of the oxide semiconductor film of one embodiment of the present invention are described with reference to FIGS. 8A to 8C, FIG. 9, FIGS. 10A to 10E, FIGS. 11A to 11E, FIGS. 12A to 12D, FIGS. 13A and 13B, and FIG. 14.

### <1-5. Composition of Oxide Semiconductor Film>

First, composition of an oxide semiconductor film is described.

The oxide semiconductor film contains indium (In), M (M is Al, Ga, Y, or Sn), and zinc (Zn) as described above.

Although the element M is aluminum, gallium, yttrium or tin, other the above, the following elements can be used as the element M: boron; silicon; titanium; iron; nickel; germanium; zirconium; molybdenum; lanthanum; cerium; neodymium; hafnium; tantalum; tungsten; and magnesium. Note that two or more of the above elements may be used in combination as the element M

Next, preferred ranges of the atomic ratio of indium, the element M, and zinc contained in an oxide semiconductor according to the present invention are described with reference to FIGS. 8A to 8C. Note that the atomic ratio of oxygen is not shown in FIGS. 8A to 8C. Terms of the atomic ratio of indium to the element M and zinc in the oxide semiconductor are denoted by [In], [M], and [Zn].

In FIGS. 8A to 8C, broken lines indicate a line where the atomic ratio [In]:[M]:[Zn] is (1+α):(1−α):1, where −1≦α≦1, a line where the atomic ratio [In]:[M]:[Zn] is (1+α):(1−α):2, a line where the atomic ratio [In]:[M]:[Zn] is (1+α):(1−α):3, a line where the atomic ratio [In]:[M]:[Zn] is (1+α):(1−α):4, and a line where the atomic ratio [In]:[M]:[Zn] is (1+α):(1−α):5.

Dashed-dotted lines correspond to a line representing the atomic ratio of [In]:[M]:[Zn]=1:1:β(β≧0), a line representing the atomic ratio of [In]:[M]:[Zn]=1:2:β, a line representing the atomic ratio of [In]:[M]:[Zn]=1:3:β, a line representing the atomic ratio of [In]:[M]:[Zn]=1:4:β, a line representing the atomic ratio of [In]:[M]:[Zn]=2:1:β, and a line representing the atomic ratio of [In]:[M]:[Zn]=5:1:β.

Dashed-double dotted lines corresponds to a line representing the atomic ratio of [In]:[M]:[Zn]=(1+γ):2:(1−γ)(−1≦γ≦1). The oxide semiconductor shown in FIGS. 8A to 8C with an atomic ratio of [In]:[M]:[Zn]=0:2:1 or an atomic ratio which is in the neighborhood is likely to have a spinel crystal structure.

FIGS. 8A and 8B illustrate examples of the preferred ranges of the atomic ratio of indium, the element M, and zinc contained in an oxide semiconductor in one embodiment of the present invention.

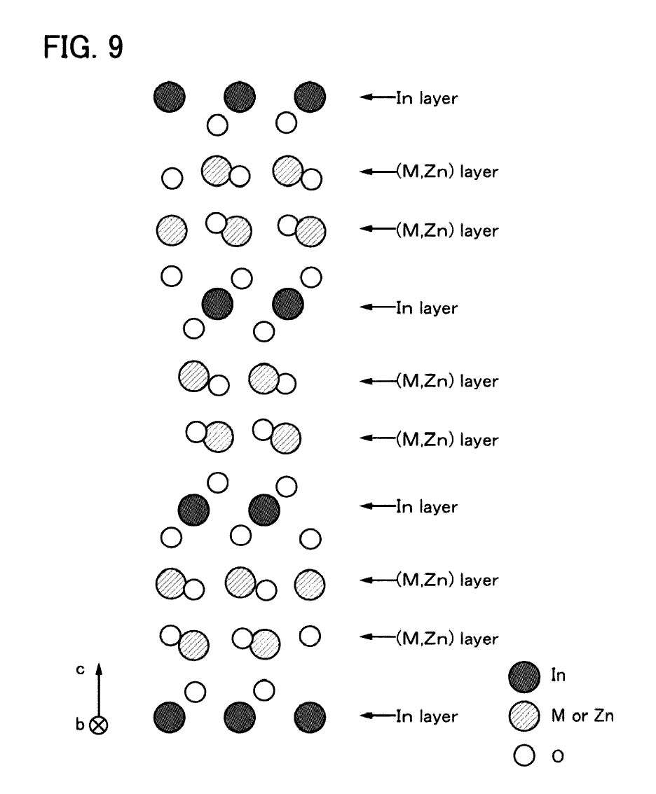

FIG. 9 shows an example of the crystal structure of InMZnO₄ whose atomic ratio [In]:[M]:[Zn] is 1:1:1. The crystal structure shown in FIG. 9 is InMZnO₄ observed from a direction parallel to a b-axis. Note that a metal element in a layer that contains M, Zn, and oxygen (hereinafter, this layer is referred to as an “(M,Zn) layer”) in FIG. 9 represents the element M or zinc. In that case, the proportion of the element M is the same as the proportion of zinc. The element M and zinc can be replaced with each other, and their arrangement is random.

InMZnO₄ has a layered crystal structure (also referred to as a layered structure) and includes one layer that contains indium and oxygen (hereinafter referred to as an In layer) for every two (M,Zn) layers that contain the element M, zinc, and oxygen, as shown in FIG. 9.

Indium and the element M can be replaced with each other. Therefore, when the element M in the (M,Zn) layer is replaced with indium, the layer can also be referred to as an (In,M,Zn) layer. In that case, a layered structure that contains one In layer for every two (In,M,Zn) layers is obtained.

An oxide semiconductor whose atomic ratio [In]:[M]:[Zn] is 1:1:2 has a layered structure that contains one In layer for every three (M,Zn) layers. In other words, if [Zn] is higher than [In] and [M], the proportion of the (M,Zn) layer to the In layer becomes higher when the oxide semiconductor is crystallized.

Note that in the case where the number of (M,Zn) layers with respect to In layer is not an integer in the oxide semiconductor, the oxide semiconductor might have plural kinds of layered structures where the number of (M,Zn) layers with respect to In layer is an integer. For example, in the case of [In]:[M]:[Zn]=1:1:1.5, the oxide semiconductor might have the following layered structures: a layered structure of one In layer for every two (M,Zn) layers and a layered structure of one In layer for every three(M,Zn) layers.

For example, in the case where the oxide semiconductor is deposited with a sputtering apparatus, a film having an atomic ratio deviated from the atomic ratio of a target is formed. In particular, [Zn] in the film might be lower than [Zn] in the target depending on the substrate temperature in deposition.

A plurality of phases (e.g., two phases or three phases) exist in the oxide semiconductor in some cases. For example, with an atomic ratio [In]:[M]:[Zn] that is in the neighborhood of 0:2:1, two phases of a spinel crystal structure and a layered crystal structure are likely to exist.

In addition, with an atomic ratio [In]:[M]:[Zn] that in the neighborhood of 1:0:0, two phases of a bixbyite crystal structure and a layered crystal structure are likely to exist. In the case where a plurality of phases exist in the oxide semiconductor, a grain boundary might be formed between different crystal structures.

In addition, the oxide semiconductor containing indium in a higher proportion can have high carrier mobility (electron mobility).

In contrast, when the indium content and the zinc content in an oxide semiconductor become lower, carrier mobility becomes lower. Thus, with an atomic ratio of [In]:[M]:[Zn]=0:1:0 and neighborhoods thereof (e.g., a region C in FIG. 8C), insulation performance becomes better.

Accordingly, an oxide semiconductor in one embodiment of the present invention preferably has an atomic ratio represented by a region A in FIG. 8A. With the atomic ratio, a layered structure with high carrier mobility and a few grain boundaries is easily obtained.

A region B in FIG. 8B represents an atomic ratio of [In]:[M]:[Zn]=4:2:3 to 4.1 and the neighborhood thereof. The neighborhood includes an atomic ratio of [In]:[M]:[Zn]=5:3:4. An oxide semiconductor with an atomic ratio represented by the region B is an excellent oxide semiconductor that has particularly high crystallinity and high carrier mobility.

Note that conditions where a layered structure of an oxide semiconductor is formed are not uniquely determined by the atomic ratio. There is a difference in the degree of difficulty in forming a layered structure among atomic ratios. Even with the same atomic ratio, whether a layered structure is formed or not depends on a formation condition. Therefore, the illustrated regions show atomic ratios at which a layered structure of an oxide semiconductor can be formed; boundaries of the regions A to C are not clear.

<1-6. Structure in which Oxide Semiconductor Film is Used for Transistor>

Next, a structure in which the oxide semiconductor film is used for a transistor is described.

Note that when the oxide semiconductor film is used for a transistor, carrier scattering or the like at a grain boundary can be reduced as compared with a transistor using polycrystalline silicon in a channel region; thus, the transistor can have high field-effect mobility. In addition, the transistor can have high reliability.

Note that the oxide semiconductor film of one embodiment of the present invention has a film density higher than or equal to 6.3 g/cm³ and lower than 6.5 g/cm³. With use of the oxide semiconductor film with such a high film density for a transistor, the transistor can have high reliability.

An oxide semiconductor film with low carrier density is preferably used for a channel region of the transistor. For example, the carrier density of the oxide semiconductor film is preferably higher than or equal to 1×10⁵ cm⁻³ and lower than 1×10¹⁸ cm⁻³, further preferably higher than or equal to 1×10⁷ cm⁻³ and lower than or equal to 1×10¹⁷ cm⁻³, still further preferably higher than or equal to 1×10⁹ cm⁻³ and lower than or equal to 5×10¹⁶ cm⁻³, yet further preferably higher than or equal to 1×10¹⁰ cm⁻³ and lower than or equal to 1×10¹⁶ cm⁻³, and yet still preferably higher than or equal to 1×10¹¹ cm⁻³ and lower than or equal to 1×10¹⁵ cm⁻³.

A highly purified intrinsic or substantially highly purified intrinsic oxide semiconductor film has few carrier generation sources, and thus can have a low carrier density. A highly purified intrinsic or substantially highly purified intrinsic oxide semiconductor film has a low density of defect states in some cases.

In contrast, when the carrier density of the oxide semiconductor film is increased, the field-effect mobility of the transistor can be increased in some cases. For example, the carrier density of the oxide semiconductor film may be increased as far as the transistor is not in a normally-on state, whereby the field-effect mobility of the transistor can be increased. Note that in order to increase the carrier density of the oxide semiconductor film, the oxide semiconductor film has somewhat n-type conductivity. In other words, the oxide semiconductor film with the increased carrier density is referred to as a “slightly-n” oxide semiconductor film in some cases.

For example, in the case where the voltage (V_{g}) applied to a gate of the transistor is higher than 0 V and lower than or equal to 30 V, the carrier density of the oxide semiconductor film is preferably higher than 1×10¹⁶ cm⁻³ and lower than 1×10¹⁸ cm⁻³, and further preferably, higher than 1×10¹⁶ cm⁻³ and lower than or equal to 1×10¹⁷ cm⁻³.

Charges trapped by the defect states in the oxide semiconductor film take a long time to be released and may behave like fixed charges. Thus, the transistor in which a channel region is formed in the oxide semiconductor film having a high density of defect states might have unstable electrical characteristics.

To obtain stable electrical characteristics of the transistor, it is effective to reduce the concentration of impurities in the oxide semiconductor film. In order to reduce the concentration of impurities in the oxide semiconductor film, the concentration of impurities in a film that is adjacent to the oxide semiconductor film is preferably reduced. As examples of the impurities, hydrogen, nitrogen, alkali metal, alkaline earth metal, iron, nickel, silicon, and the like are given.

Here, the influence of impurities in the oxide semiconductor film will be described.

When silicon or carbon that is one of Group 14 elements is contained in the oxide semiconductor film, defect states are formed in the oxide semiconductor film. Thus, the concentration of silicon or carbon (measured by secondary ion mass spectrometry (SIMS)) in the oxide semiconductor film and around an interface with the oxide semiconductor film is set lower than or equal to 2×10¹⁸ atoms/cm³, and preferably lower than or equal to 2×10¹⁷ atoms/cm³.

When the oxide semiconductor film contains alkali metal or alkaline earth metal, defect states are formed and carriers are generated, in some cases. Thus, a transistor including an oxide semiconductor film which contains alkali metal or alkaline earth metal is likely to be normally on. Therefore, it is preferable to reduce the concentration of alkali metal or alkaline earth metal in the oxide semiconductor film. Specifically, the concentration of alkali metal or alkaline earth metal of the oxide semiconductor film, which is measured by SIMS, is lower than or equal to 1×10¹⁸ atoms/cm³, preferably lower than or equal to 2×10¹⁶ atoms/cm³.

When the oxide semiconductor film contains nitrogen, the oxide semiconductor film easily becomes n-type by generation of electrons serving as carriers and an increase of carrier density. Thus, a transistor whose semiconductor includes an oxide semiconductor film that contains nitrogen is likely to be normally-on. For this reason, nitrogen in the oxide semiconductor film is preferably reduced as much as possible; for example, the concentration of nitrogen in the oxide semiconductor film measured by SIMS is set to be lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Hydrogen contained in an oxide semiconductor film reacts with oxygen bonded to a metal atom to be water, and thus causes an oxygen vacancy, in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor including an oxide semiconductor film that contains hydrogen is likely to be normally on. Accordingly, it is preferable that hydrogen in the oxide semiconductor film be reduced as much as possible. Specifically, the hydrogen concentration in the oxide semiconductor film measured by SIMS is set lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor film with sufficiently reduced impurity concentration is used for a channel formation region in a transistor, the transistor can have stable electrical characteristics.

The energy gap of the oxide semiconductor film is preferably 2 eV or more or 2.5 eV or more.

The thickness of the oxide semiconductor film is greater than or equal to 3 nm and less than or equal to 200 nm, preferably greater than or equal to 3 nm and less than or equal to 100 nm, further preferably greater than or equal to 3 nm and less than or equal to 60 nm.

When the oxide semiconductor film is an In-M-Zn oxide, as the atomic ratio of metal elements in a sputtering target used for formation of the In-M-Zn oxide, In:M:Zn=1:1:0.5, In:M:Zn=1:1:1, In:M:Zn=1:1:1.2, In:M:Zn=2:1:1.5, In:M:Zn=2:1:2.3, In:M:Zn=2:1:3, In:M:Zn=3:1:2, In:M:Zn=4:2:4.1, In:M:Zn=5:1:7, or the like is preferable.

Note that the atomic ratios of metal elements in the formed oxide semiconductor films may each vary from the above atomic ratio of metal elements in the sputtering target within a range of approximately ±40%. For example, when a sputtering target with an atomic ratio of In:Ga:Zn=4:2:4.1 is used, the atomic ratio of In to Ga and Zn in the oxide semiconductor film may be 4:2:3 or in the neighborhood of 4:2:3. In the case where a sputtering target whose atomic ratio of In to Ga and Zn is 5:1:7 is used, the atomic ratio of In to Ga and Zn in the deposited oxide semiconductor film may be in the neighborhood of 5:1:6.

### <1-7. Structure of Oxide Semiconductor Film>

Next, a structure of the oxide semiconductor film is described.

An oxide semiconductor film is classified into a single crystal oxide semiconductor film and a non-single-crystal oxide semiconductor film. Examples of a non-single-crystal oxide semiconductor include a c-axis-aligned crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor film is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

An amorphous structure is generally thought to be isotropic and have no non-uniform structure, to be metastable and not to have fixed positions of atoms, to have a flexible bond angle, and to have a short-range order but have no long-range order, for example.

In other words, a stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. In contrast, an a-like OS, which is not isotropic, has an unstable structure that contains a void. Because of its instability, an a-like OS is close to an amorphous oxide semiconductor in terms of physical properties.

### [CAAC-OS]

First, a CAAC-OS is described.

A CAAC-OS is one of oxide semiconductors having a plurality of c-axis aligned crystal parts (also referred to as pellets).

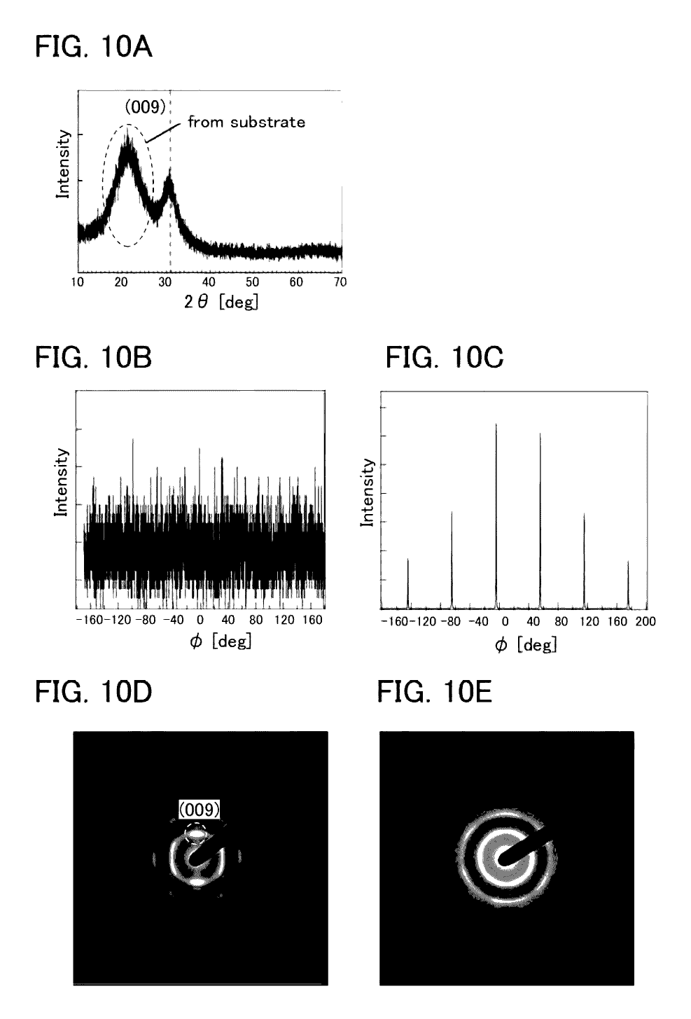

Analysis of a CAAC-OS by XRD is described. For example, when the structure of a CAAC-OS including an InGaZnO₄ crystal that is classified into the space group R-3m is analyzed by an out-of-plane method, a peak appears at a diffraction angle (2θ) of around 31° as shown in FIG. 10A. This peak is derived from the (009) plane of the InGaZnO₄ crystal, which indicates that crystals in the CAAC-OS have c-axis alignment, and that the c-axes are aligned in a direction substantially perpendicular to a surface over which the CAAC-OS film is formed (also referred to as a formation surface) or the top surface of the CAAC-OS film. Note that a peak sometimes appears at a 2θ of around 36° in addition to the peak at a 2θ of around 31°. The peak at a 2θ of around 36° is derived from a crystal structure classified into the space group Fd-3m. Therefore, it is preferred that the CAAC-OS do not show the peak at a 2θ of around 36°.

On the other hand, in structural analysis of the CAAC-OS by an in-plane method in which an X-ray is incident on the CAAC-OS in a direction parallel to the formation surface, a peak appears at a 2θ of around 56°. This peak is derived from the (110) plane of the InGaZnO₄ crystal. When analysis (φ scan) is performed with 2θ fixed at around 56° and with the sample rotated using a normal vector to the sample surface as an axis (0 axis), as shown in FIG. 10B, a peak is not clearly observed. In contrast, in the case where single crystal InGaZnO₄ is subjected to φ scan with 2θ fixed at around 56°, as shown in FIG. 10C, six peaks which are derived from crystal planes equivalent to the (110) plane are observed. Accordingly, the structural analysis using XRD shows that the directions of a-axes and b-axes are irregularly oriented in the CAAC-OS.

Next, a CAAC-OS analyzed by electron diffraction will be described. For example, when an electron beam with a probe diameter of 300 nm is incident on a CAAC-OS including an InGaZnO₄ crystal in a direction parallel to the formation surface of the CAAC-OS, a diffraction pattern (also referred to as a selected-area electron diffraction pattern) shown in FIG. 10D can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in the direction substantially perpendicular to the formation surface or the top surface of the CAAC-OS. Meanwhile, FIG. 10E shows a diffraction pattern obtained in such a manner that an electron beam with a probe diameter of 300 nm is incident on the same sample in the direction perpendicular to the sample surface. As shown in FIG. 10E, a ring-like diffraction pattern is observed. Thus, the electron diffraction using an electron beam with a probe diameter of 300 nm also indicates that the a-axes and b-axes of the pellets included in the CAAC-OS do not have regular orientation. The first ring in FIG. 10E is considered to be derived from the (010) plane, the (100) plane, and the like of the InGaZnO₄ crystal. The second ring in FIG. 10E is considered to be derived from the (110) plane and the like.

In a combined analysis image (also referred to as a high-resolution TEM image) of a bright-field image and a diffraction pattern of a CAAC-OS, which is obtained using a transmission electron microscope (TEM), a plurality of pellets can be observed. However, even in the high-resolution TEM image, a boundary between pellets, that is, a crystal grain boundary is not clearly observed in some cases. Thus, in the CAAC-OS, a reduction in electron mobility due to the grain boundary is less likely to occur.

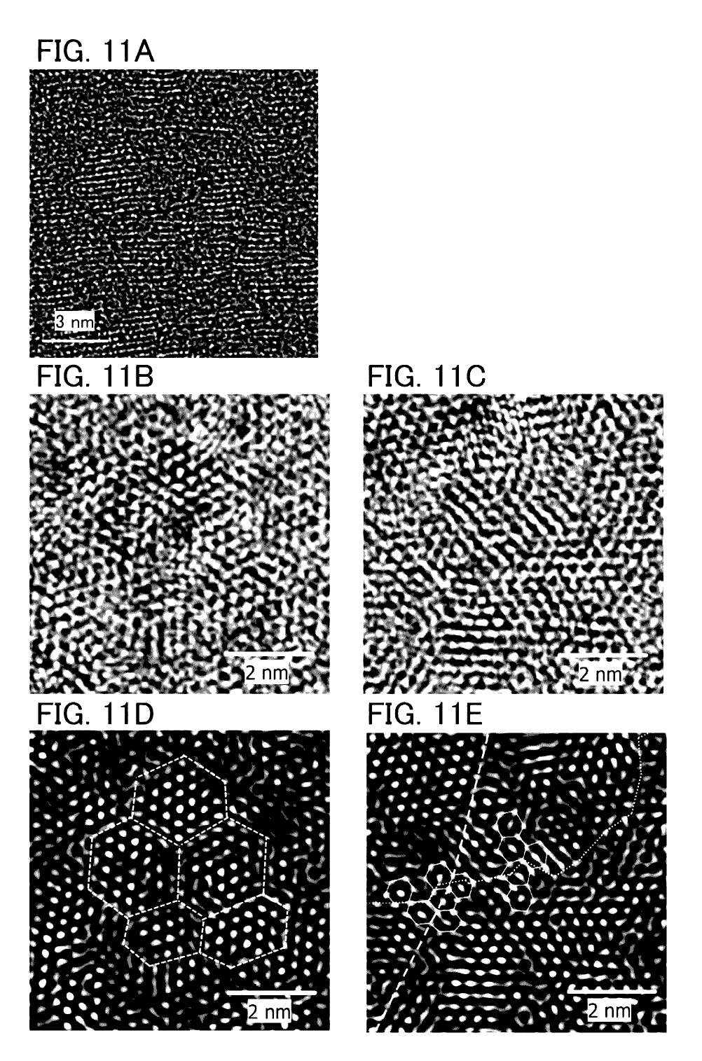

FIG. 11A shows a high-resolution TEM image of a cross section of the CAAC-OS which is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be observed with, for example, an atomic resolution analytical electron microscope JEM-ARM200F manufactured by JEOL Ltd.

FIG. 11A shows pellets in which metal atoms are arranged in a layered manner. FIG. 11A proves that the size of a pellet is greater than or equal to 1 nm or greater than or equal to 3 nm. Therefore, the pellet can also be referred to as a nanocrystal (nc). Furthermore, the CAAC-OS can also be referred to as an oxide semiconductor including c-axis aligned nanocrystals (CANC). A pellet reflects unevenness of a formation surface or a top surface of the CAAC-OS, and is parallel to the formation surface or the top surface of the CAAC-OS.

FIGS. 11B and 11C show Cs-corrected high-resolution TEM images of a plane of the CAAC-OS observed from a direction substantially perpendicular to the sample surface. FIGS. 11D and 11E are images obtained through image processing of FIGS. 11B and 11C. The method of image processing is as follows. The image in FIG. 11B is subjected to fast Fourier transform (FFT) to obtain an FFT image. Then, mask processing is performed such that a range of from 2.8 nm⁻¹ to 5.0 nm⁻¹ from the origin in the obtained FFT image remains. After the mask processing, the FFT image is processed by inverse fast Fourier transform (IFFT) to obtain a processed image. The image obtained in this manner is called an FFT filtering image. The FFT filtering image is a Cs-corrected high-resolution TEM image from which a periodic component is extracted, and shows a lattice arrangement.

In FIG. 11D, a portion where a lattice arrangement is broken is denoted with a dashed line. A region surrounded by a dashed line is one pellet. The portion denoted with the dashed line is a junction of pellets. The dashed line draws a hexagon, which means that the pellet has a hexagonal shape. Note that the shape of the pellet is not always a regular hexagon but is a non-regular hexagon in many cases.

In FIG. 11E, a dotted line denotes a portion where the direction of a lattice arrangement changes between a region with a regular lattice arrangement and another region with a regular lattice arrangement, and a dashed line denotes the change in the direction of the lattice arrangement. A clear crystal grain boundary cannot be observed even in the vicinity of the dotted line. When a lattice point in the vicinity of the dotted line is regarded as a center and surrounding lattice points are joined, a distorted hexagon, a distorted pentagon, and/or a distorted heptagon can be formed, for example. That is, a lattice arrangement is distorted so that formation of a crystal grain boundary is inhibited. This is probably because the CAAC-OS can tolerate distortion owing to a low density of the atomic arrangement in an a-b plane direction, the interatomic bond distance changed by substitution of a metal element, and the like.

As described above, the CAAC-OS has c-axis alignment, its pellets (nanocrystals) are connected in an a-b plane direction, and the crystal structure has distortion. For this reason, the CAAC-OS can also be referred to as an oxide semiconductor including a c-axis-aligned a-b-plane-anchored (CAA) crystal.

The CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. For example, impurities contained in the oxide semiconductor might serve as carrier traps or carrier generation sources. For example, oxygen vacancy in the oxide semiconductor might serve as a carrier trap or serve as a carrier generation source when hydrogen is captured therein.

The CAAC-OS having small amounts of impurities and oxygen vacancies is an oxide semiconductor with low carrier density. Such an oxide semiconductor is referred to as a highly purified intrinsic or substantially highly purified intrinsic oxide semiconductor. A CAAC-OS has a low impurity concentration and a low density of defect states. Thus, the CAAC-OS can be referred to as an oxide semiconductor having stable characteristics.

[nc-OS]

Next, an nc-OS is described.

Analysis of an nc-OS by XRD is described. When the structure of an nc-OS is analyzed by an out-of-plane method, a peak indicating orientation does not appear. That is, a crystal of an nc-OS does not have orientation.

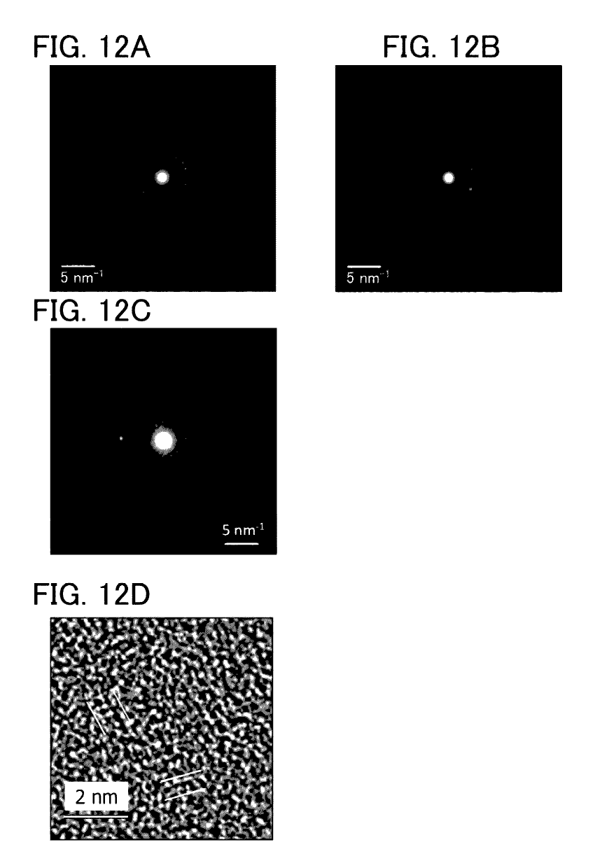

For example, when an electron beam with a probe diameter of 50 nm is incident on a 34-nm-thick region of a thinned nc-OS including an InGaZnO₄ crystal in the direction parallel to the formation surface, a ring-like diffraction pattern (a nanobeam electron diffraction pattern) is observed as shown in FIG. 12A. FIG. 12B shows a diffraction pattern obtained when an electron beam with a probe diameter of 1 nm is incident on the same sample. As shown in FIG. 12B, a plurality of spots is observed in a ring-like region. In other words, ordering in an nc-OS is not observed with an electron beam with a probe diameter of 50 nm but is observed with an electron beam with a probe diameter of 1 nm.

Furthermore, an electron diffraction pattern in which spots are arranged in an approximately regular hexagonal shape is observed in some cases as shown in FIG. 12C when an electron beam having a probe diameter of 1 nm is incident on a region with a thickness of less than 10 nm. This means that an nc-OS has a well-ordered region, i.e., a crystal, in the range of less than 10 nm in thickness. Note that an electron diffraction pattern having regularity is not observed in some regions because crystals are aligned in various directions.

FIG. 12D shows a Cs-corrected high-resolution TEM image of a cross section of an nc-OS observed from the direction substantially parallel to the formation surface. In a high-resolution TEM image, an nc-OS has a region in which a crystal part is observed, such as the part indicated by additional lines, and a region in which a crystal part is not clearly observed. In most cases, the size of a crystal part included in the nc-OS is greater than or equal to 1 nm and less than or equal to 10 nm, or specifically, greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. In a high-resolution TEM image of the nc-OS, for example, a grain boundary is not clearly observed in some cases. Note that there is a possibility that the origin of the nanocrystal is the same as that of a pellet in a CAAC-OS. Therefore, a crystal part of the nc-OS may be referred to as a pellet in the following description.

As described above, in the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, the nc-OS cannot be distinguished from an a-like OS or an amorphous oxide semiconductor, depending on an analysis method.

Since there is no regularity of crystal orientation between the pellets (nanocrystals) as mentioned above, the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared with an amorphous oxide semiconductor. Therefore, the nc-OS is likely to have a lower density of defect states than an a-like OS and an amorphous oxide semiconductor. Note that there is no regularity of crystal orientation between different pellets in the nc-OS. Therefore, the nc-OS has a higher density of defect states than the CAAC-OS.

[a-like OS]

An a-like OS has a structure intermediate between those of the nc-OS and the amorphous oxide semiconductor.

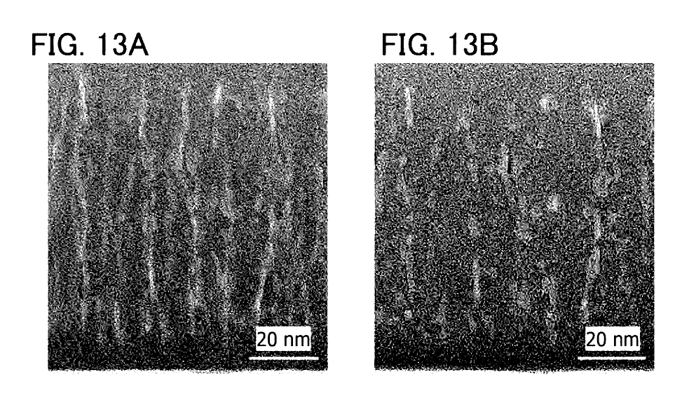

FIGS. 13A and 13B are high-resolution cross-sectional TEM images of an a-like OS. FIG. 13A is the high-resolution cross-sectional TEM image of the a-like OS at the start of the electron irradiation. FIG. 13B is the high-resolution cross-sectional TEM image of a-like OS after the electron (e⁻) irradiation at 4.3×10⁸ e⁻/nm². FIGS. 13A and 13B show that stripe-like bright regions extending vertically are observed in the a-like OS from the start of the electron irradiation. It can also be found that the shape of the bright region changes after the electron irradiation. Note that the bright region is presumably a void or a low-density region.

The a-like OS has an unstable structure because it contains a void. To verify that an a-like OS has an unstable structure as compared with a CAAC-OS and an nc-OS, a change in structure caused by electron irradiation is described below.

An a-like OS, an nc-OS, and a CAAC-OS are prepared as samples. Each of the samples is an In—Ga—Zn oxide.

First, a high-resolution cross-sectional TEM image of each sample is obtained. The high-resolution cross-sectional TEM images show that all the samples have crystal parts.

It is known that a unit cell of an InGaZnO₄ crystal has a structure in which nine layers including three In—O layers and six Ga—Zn—O layers are stacked in the c-axis direction. Accordingly, the spacing between these adjacent layers is equivalent to the lattice spacing on the (009) plane (also referred to as a d value). The value is calculated to be 0.29 nm from crystal structure analysis. Accordingly, a portion where the spacing between lattice fringes is greater than or equal to 0.28 nm and less than or equal to 0.30 nm is regarded as a crystal part of InGaZnO₄ in the following description. Each of lattice fringes corresponds to the a-b plane of the InGaZnO₄ crystal.

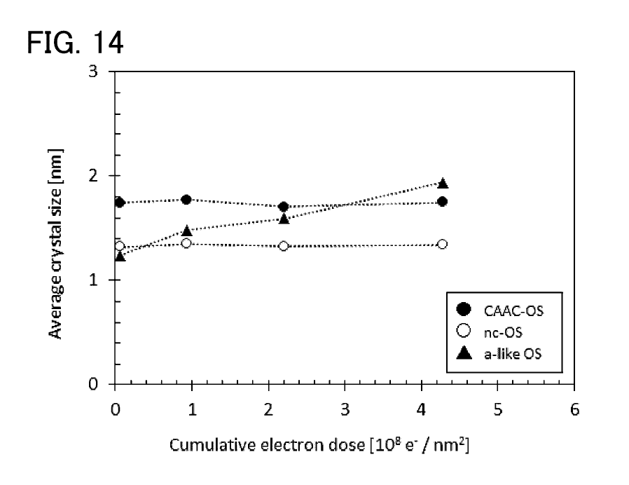

FIG. 14 shows a change in the average size of crystal parts (at 22 to 30 points) in each sample. Note that the crystal part size corresponds to the length of a lattice fringe. FIG. 14 indicates that the crystal part size in the a-like OS increases with an increase in the cumulative electron dose in obtaining TEM images, for example. As shown in FIG. 14, a crystal part of approximately 1.2 nm (also referred to as an initial nucleus) at the start of TEM observation grows to a size of approximately 1.9 nm at a cumulative electron (e) dose of 4.2×10⁸ e⁻/nm². In contrast, the crystal part size in the nc-OS and the CAAC-OS shows little change from the start of electron irradiation to a cumulative electron dose of 4.2×10⁸ e⁻/nm². As shown in FIG. 14, the crystal part sizes in an nc-OS and a CAAC-OS are approximately 1.3 nm and approximately 1.8 nm, respectively, regardless of the cumulative electron dose. For the electron beam irradiation and TEM observation, a Hitachi H-9000NAR transmission electron microscope was used. The conditions of electron beam irradiation were as follows: the accelerating voltage was 300 kV; the current density was 6.7×10⁵ e⁻/(nm²·s); and the diameter of the irradiation region was 230 nm.

In this manner, growth of the crystal part in the a-like OS is induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it contains a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

As described above, in the case of an oxide semiconductor whose atomic ratio of In to Ga and Zn is 1:1:1, the density of single-crystal InGaZnO₄ is 6.357 g/cm³. Accordingly, in the case of the oxide semiconductor having an atomic ratio of In:Ga:Zn=1:1:1, for example, the density of the a-like OS is higher than or equal to 5.0 g/cm³ and lower than 5.9 g/cm³. Furthermore, for example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that in the case where an oxide semiconductor having a certain composition does not exist in a single crystal structure, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be estimated using a weighted average according to the combination ratio of the single crystal oxide semiconductors with different compositions. Note that it is preferable to use as few kinds of single crystal oxide semiconductors as possible to estimate the density.

As described above, oxide semiconductors have various structures and various properties. Note that an oxide semiconductor may be a stacked layer including two or more films of an amorphous oxide semiconductor, an a-like OS, an nc-OS, and a CAAC-OS, for example.

Note that the structure described in this embodiment can be used in appropriate combination with any of the structures described in the other embodiments or examples.

### Embodiment 2

In this embodiment, a transistor that can be used for a semiconductor device of one embodiment of the present invention will be described in detail.

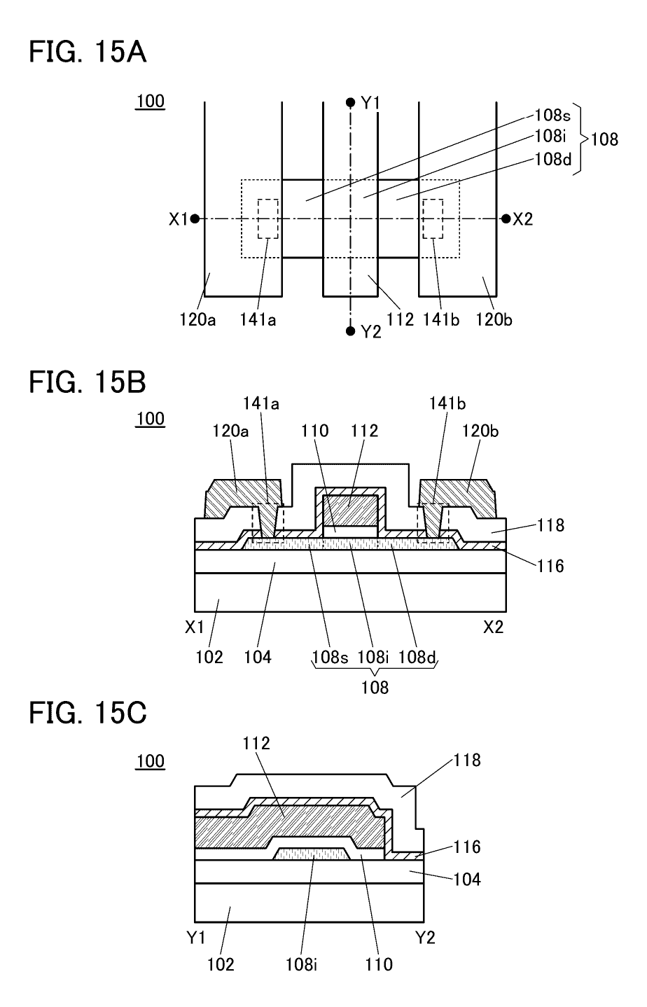

In this embodiment, a transistor with a top-gate structure is described with reference to FIGS. 15A to 15C, FIGS. 16A to 16C, FIGS. 17A and 17B, FIGS. 18A and 18B, FIGS. 19A and 19B, FIGS. 20A and 20B, FIGS. 21A and 21B, FIGS. 22A and 22B, FIGS. 23A and 23B, FIGS. 24A and 24B, FIGS. 25A and 25B, and FIGS. 26A to 26C.

### <2-1. Structure Example 1 of Transistor>

FIG. 15A is a top view of a transistor 100. FIG. 15B is a cross-sectional view taken along dashed-dotted line X1-X2 in FIG. 15A. FIG. 15C is a cross-sectional view taken along dashed-dotted line Y1-Y2 in FIG. 15A. For clarity, FIG. 15A does not illustrate some components such as an insulating film 110. As in FIG. 15A, some components might not be illustrated in some top views of transistors described below. Furthermore, the direction of dashed-dotted line X1-X2 may be referred to as a channel length (L) direction, and the direction of dashed-dotted line Y1-Y2 may be referred to as a channel width (W) direction.

The transistor 100 illustrated in FIGS. 15A to 15C includes an insulating film 104 over a substrate 102; an oxide semiconductor film 108 over the insulating film 104; an insulating film 110 over the oxide semiconductor film 108; a conductive film 112 over the insulating film 110; and an insulating film 116 over the insulating film 104, the oxide semiconductor film 108, and the conductive film 112. Note that the oxide semiconductor film 108 includes a channel region 108i overlapping with the conductive film 112, a source region 108s in contact with the insulating film 116, and a drain region 108d in contact with the insulating film 116.

Furthermore, the insulating film 116 contains nitrogen or hydrogen. The insulating film 116 is in contact with the source region 108s and the drain region 108d, so that nitrogen or hydrogen that is contained in the insulating film 116 is added to the source region 108s and the drain region 108d. The source region 108s and the drain region 108d each have a high carrier density when nitrogen or hydrogen is added thereto.

The transistor 100 may further include an insulating film 118 over the insulating film 116, a conductive film 120a electrically connected to the source region 108s through an opening 141a provided in the insulating films 116 and 118, and a conductive film 120b electrically connected to the drain region 108d through an opening 141b provided in the insulating films 116 and 118.

In this specification and the like, the insulating film 104 may be referred to as a first insulating film, the insulating film 110 may be referred to as a second insulating film, the insulating film 116 may be referred to as a third insulating film, and the insulating film 118 may be referred to as a fourth insulating film. The conductive film 112 functions as a gate electrode, the conductive film 120a functions as a source electrode, and the conductive film 120b functions as a drain electrode.

The insulating film 110 functions as a gate insulating film. The insulating film 110 includes an excess oxygen region. Since the insulating film 110 includes the excess oxygen region, excess oxygen can be supplied to the channel region 108i included in the oxide semiconductor film 108. As a result, oxygen vacancies that might be formed in the channel region 108i can be filled with excess oxygen, which can provide a highly reliable semiconductor device.

To supply excess oxygen to the oxide semiconductor film 108, excess oxygen may be supplied to the insulating film 104 that is formed under the oxide semiconductor film 108. However, in that case, excess oxygen contained in the insulating film 104 might also be supplied to the source region 108s and the drain region 108d included in the oxide semiconductor film 108. When excess oxygen is supplied to the source region 108s and the drain region 108d, the resistance of the source region 108s and the drain region 108d might be increased.

In contrast, in the structure in which the insulating film 110 formed over the oxide semiconductor film 108 contains excess oxygen, excess oxygen can be selectively supplied only to the channel region 108i. Alternatively, the carrier density of the source and drain regions 108s and 108d can be selectively increased after excess oxygen is supplied to the channel region 108i and the source and drain regions 108s and 108d, in which case an increase in the resistance of the source and drain regions 108s and 108d can be prevented.

Furthermore, each of the source region 108s and the drain region 108d included in the oxide semiconductor film 108 preferably contains an element that forms an oxygen vacancy or an element that is bonded to an oxygen vacancy. Typical examples of the element that forms an oxygen vacancy or the element that is bonded to an oxygen vacancy include hydrogen, boron, carbon, nitrogen, fluorine, phosphorus, sulfur, chlorine, titanium, and a rare gas. Typical examples of the rare gas element are helium, neon, argon, krypton, and xenon. The element that forms an oxygen vacancy is diffused from the insulating film 116 to the source region 108s and the drain region 108d in the case where the insulating film 116 contains one or more such elements. In addition or alternatively, the element that forms an oxygen vacancy is added to the source region 108s and the drain region 108d by impurity addition treatment.

An impurity element added to the oxide semiconductor film cuts a bond between a metal element and oxygen in the oxide semiconductor film, so that an oxygen vacancy is formed. Alternatively, when the impurity element is added to the oxide semiconductor film, oxygen bonded to a metal element in the oxide semiconductor film is bonded to the impurity element, and the oxygen is released from the metal element, whereby an oxygen vacancy is formed. As a result, the oxide semiconductor film has a higher carrier density and thus the conductivity thereof becomes higher.

Next, details of other components included in the semiconductor device illustrated in FIGS. 15A to 15C are described.

### [Substrate]

A material having heat resistance high enough to withstand heat treatment in the manufacturing process can be used for the substrate 102.

Specifically, non-alkali glass, soda-lime glass, potash glass, crystal glass, quartz, sapphire, or the like can be used. Alternatively, an inorganic insulating film may be used. Examples of the inorganic insulating film include a silicon oxide film, a silicon nitride film, a silicon oxynitride film, and an aluminum oxide film.

The non-alkali glass preferably has a thickness greater than or equal to 0.2 mm and less than or equal to 0.7 mm, for example. The non-alkali glass may be polished to obtain the above thickness.

Using the non-alkali glass, a large-sized glass substrate having any of the following sizes can be used: the 6th generation (1500 mm×1850 mm), the 7th generation (1870 mm×2200 mm), the 8th generation (2200 mm×2400 mm), the 9th generation (2400 mm×2800 mm), and the 10th generation (2950 mm×3400 mm). Thus, a large-sized display device can be manufactured.

Alternatively, as the substrate 102, a single-crystal semiconductor substrate or a polycrystalline semiconductor substrate made of silicon or silicon carbide, a compound semiconductor substrate made of silicon germanium or the like, an SOI substrate, or the like may be used.

Alternatively, an inorganic material such as metal may be used as the substrate 102. Examples of the inorganic material such as a metal include stainless steel or aluminum.

Alternatively, for the substrate 102, an organic material such as a resin, a resin film, or plastic may be used. Examples of the resin film include polyester, polyolefin, polyamide (e.g., nylon or aramid), polyimide, polycarbonate, polyurethane, an acrylic resin, an epoxy resin, polyethylene terephthalate (PET), polyethylene naphthalate (PEN), polyether sulfone (PES), and a resin having a siloxane bond.

Alternatively, for the substrate 102, a composite material of a combination of an inorganic material and an organic material may be used. Examples of the composite material include a resin film to which a metal plate or a thin glass plate is bonded, a resin film into which a fibrous or particulate metal or a fibrous or particulate glass is dispersed, and an inorganic material into which a fibrous or particulate resin is dispersed.

Note that the substrate 102 may be formed using one or more of an insulating film, a semiconductor film, and a conductive film as long as it can at least support a film or a layer formed thereover and thereunder.

### [First Insulating Film]

The insulating film 104 can be formed by a sputtering method, a CVD method, an evaporation method, a pulsed laser deposition (PLD) method, a printing method, a coating method, or the like as appropriate. For example, the insulating film 104 can be formed to have a single-layer structure or stacked-layer structure including an oxide insulating film and/or a nitride insulating film. To improve the properties of the interface with the oxide semiconductor film 108, at least a region of the insulating film 104 which is in contact with the oxide semiconductor film 108 is preferably formed using an oxide insulating film. When the insulating film 104 is formed using an oxide insulating film from which oxygen is released by heating, oxygen contained in the insulating film 104 can be moved to the oxide semiconductor film 108 by heat treatment.

The thickness of the insulating film 104 can be greater than or equal to 50 nm, greater than or equal to 100 nm and less than or equal to 3000 nm, or greater than or equal to 200 nm and less than or equal to 1000 nm. By increasing the thickness of the insulating film 104, the amount of oxygen released from the insulating film 104 can be increased, and interface states at the interface between the insulating film 104 and the oxide semiconductor film 108 and oxygen vacancies included in the channel region 108i of the oxide semiconductor film 108 can be reduced.

For example, the insulating film 104 can be formed to have a single-layer structure or stacked-layer structure including silicon oxide, silicon oxynitride, silicon nitride oxide, silicon nitride, aluminum oxide, hafnium oxide, gallium oxide, a Ga—Zn oxide, or the like. In this embodiment, the insulating film 104 has a stacked-layer structure including a silicon nitride film and a silicon oxynitride film. With the insulating film 104 having such a stack-layer structure including a silicon nitride film as a lower layer and a silicon oxynitride film as an upper layer, oxygen can be efficiently introduced into the oxide semiconductor film 108.

### [Oxide Semiconductor Film]

As the oxide semiconductor film 108, the oxide semiconductor film described in Embodiment 1 can be used.

It is preferable that the oxide semiconductor film 108 be formed by a sputtering method because the film density can be high. In the case where the oxide semiconductor film 108 is formed by a sputtering method, a rare gas (typically argon), oxygen, or a mixed gas of a rare gas and oxygen is used as a sputtering gas, as appropriate. In addition, increasing the purity of a sputtering gas is necessary. For example, as an oxygen gas or an argon gas used for a sputtering gas, a gas that is highly purified to have a dew point of −60° C. or lower, preferably −100° C. or lower, is used, whereby entry of moisture or the like into the oxide semiconductor film 108 can be minimized.

When the oxide semiconductor film 108 is formed by a sputtering method, each chamber of a sputtering apparatus is preferably evacuated to a high vacuum (to the degree of approximately 5×10⁻⁷ Pa to 1×10⁻⁴ Pa) by an adsorption vacuum pump such as a cryopump so that water and the like acting as impurities for the oxide semiconductor film 108 are removed as much as possible. The partial pressure of gas molecules corresponding to H₂O (corresponding to molecules with a m/z of 18) in the chamber is particularly set to be lower than or equal to 1×10⁻⁴ Pa, further preferably, lower than or equal to 5×10⁻⁵ Pa in a standby state of the sputtering apparatus.

### [Second Insulating Film]

The insulating film 110 functions as a gate insulating film of the transistor 100. In addition, the insulating film 110 has a function of supplying oxygen to the oxide semiconductor film 108, particularly to the channel region 108i. The insulating film 110 can be formed to have a single-layer structure or a stacked-layer structure of an oxide insulating film or a nitride insulating film, for example. To improve the interface properties with the oxide semiconductor film 108, a region which is in the insulating film 110 and in contact with the oxide semiconductor film 108 is preferably formed using at least an oxide insulating film. For example, silicon oxide, silicon oxynitride, silicon nitride oxide, or silicon nitride may be used for the insulating film 110.

The thickness of the insulating film 110 can be greater than or equal to 5 nm and less than or equal to 400 nm, greater than or equal to 5 nm and less than or equal to 300 nm, or greater than or equal to 10 nm and less than or equal to 250 nm.

It is preferable that the insulating film 110 have few defects and typically have as few signals observed by electron spin resonance (ESR) spectroscopy as possible. Examples of the signals include a signal due to an E′ center observed at a g-factor of 2.001. Note that the E′ center is due to the dangling bond of silicon. As the insulating film 110, a silicon oxide film or a silicon oxynitride film whose spin density of a signal due to the E′ center is lower than or equal to 3×10¹⁷ spins/cm³ and preferably lower than or equal to 5×10¹⁶ spins/cm³ may be used.

In addition to the above-described signal, a signal due to nitrogen dioxide (NO₂) might be observed in the insulating film 110. The signal is split into three signals according to nuclear spin of N; a first signal, a second signal, and a third signal. The first signal is observed at a g-factor of greater than or equal to 2.037 and less than or equal to 2.039. The second signal is observed at a g-factor of greater than or equal to 2.001 and less than or equal to 2.003. The third signal is observed at a g-factor of greater than or equal to 1.964 and less than or equal to 1.966.

It is suitable to use an insulating film whose spin density due to nitrogen dioxide (NO₂) is higher than or equal to 1×10¹⁷ spins/cm³ and lower than 1×10¹⁸ spins/cm³ as the insulating film 110, for example.

Note that a nitrogen oxide (NOₓ) such as a nitrogen dioxide (NO₂) forms a level in the insulating film 110. The level is positioned in the energy gap of the oxide semiconductor film 108. Thus, when nitrogen oxide (NOₓ) is diffused to the interface between the insulating film 110 and the oxide semiconductor film 108, an electron might be trapped by the level on the insulating film 110 side. As a result, the trapped electron remains in the vicinity of the interface between the insulating film 110 and the oxide semiconductor film 108; thus, the threshold voltage of the transistor is shifted in the positive direction. Accordingly, the use of a film with a low nitrogen oxide content as the insulating film 110 can reduce a shift of the threshold voltage of the transistor.

As an insulating film that releases a small amount of nitrogen oxide (NOₓ), for example, a silicon oxynitride film can be used. The silicon oxynitride film releases more ammonia than nitrogen oxide (NOₓ) in thermal desorption spectroscopy (TDS); the typical released amount of ammonia is greater than or equal to 1×10¹⁸ cm⁻³ and less than or equal to 5×10¹⁹ cm⁻³. Note that the released amount of ammonia is the total amount of ammonia released by heat treatment in a range from 50° C. to 650° C. or a range from 50° C. to 550° C. in TDS.

Since nitrogen oxide (NOₓ) reacts with ammonia and oxygen in heat treatment, the use of an insulating film that releases a large amount of ammonia reduces nitrogen oxide (NOₓ).

Note that in the case where the insulating film 110 is analyzed by SIMS, the nitrogen concentration in the film is preferably lower than or equal to 6×10²⁰ atoms/cm³.

The insulating film 110 may be formed using a high-k material such as hafnium silicate (HfSiOₓ), hafnium silicate to which nitrogen is added (HfSiₓO_{y}N_{z}), hafnium aluminate to which nitrogen is added (HfAlₓO_{y}N_{z}), or hafnium oxide. The use of such a high-k material enables a reduction in gate leakage current of a transistor.

### [Third Insulating Film]

The insulating film 116 contains nitrogen or hydrogen. The insulating film 116 may contain fluorine. The insulating film 116 is a nitride insulating film, for example. The nitride insulating film can be formed using silicon nitride, silicon nitride oxide, silicon oxynitride, silicon nitride fluoride, silicon fluoronitride, or the like. The hydrogen concentration in the insulating film 116 is preferably higher than or equal to 1×10²² atoms/cm³. Furthermore, the insulating film 116 is in contact with the source region 108s and the drain region 108d of the oxide semiconductor film 108. Thus, the concentration of an impurity (nitrogen or hydrogen) in the source region 108s and the drain region 108d in contact with the insulating film 116 is increased, leading to an increase in the carrier density of the source region 108s and the drain region 108d.

### [Fourth Insulating Film]

As the insulating film 118, an oxide insulating film can be used. Alternatively, a stack including an oxide insulating film and a nitride insulating film can be used as the insulating film 118. The insulating film 118 can be formed using, for example, silicon oxide, silicon oxynitride, silicon nitride oxide, aluminum oxide, hafnium oxide, gallium oxide, or Ga—Zn oxide.

Furthermore, the insulating film 118 preferably functions as a barrier film against hydrogen, water, and the like from the outside.

The thickness of the insulating film 118 can be greater than or equal to 30 nm and less than or equal to 500 nm, or greater than or equal to 100 nm and less than or equal to 400 nm.

### [Conductive Film]

The conductive films 112, 120a, and 120b can be formed by a sputtering method, a vacuum evaporation method, a pulsed laser deposition (PLD) method, a thermal CVD method, or the like. Furthermore, as the conductive films 112, 120a, and 120b, a conductive metal film, a conductive film that has a function of reflecting visible light, or a conductive film having a function of transmitting visible light may be used.

A material containing a metal element selected from aluminum, gold, platinum, silver, copper, chromium, tantalum, titanium, molybdenum, tungsten, nickel, iron, cobalt, palladium, and manganese can be used for the metal film having conductivity. Alternatively, an alloy containing any of the above metal elements may be used.

For the metal film having conductivity, specifically a two-layer structure in which a copper film is stacked over a titanium film, a two-layer structure in which a copper film is stacked over a titanium nitride film, a two-layer structure in which a copper film is stacked over a tantalum nitride film, or a three-layer structure in which a titanium film, a copper film, and a titanium film are stacked in this order may be used. In particular, a conductive film containing a copper element is preferably used because the resistance can be reduced. As an example of the conductive film containing a copper element, an alloy film containing copper and manganese is given. The alloy film is preferable because it can be processed by a wet etching method.

A tantalum nitride film is preferably used as each of the conductive films 112, 120a, and 120b. Such a tantalum nitride film has conductivity and a high barrier property against copper or hydrogen. The tantalum nitride film can be used most preferably as a metal film in contact with the oxide semiconductor film 108 or a metal film in the vicinity of the oxide semiconductor film 108 because the amount of hydrogen released from the tantalum nitride film is small.

As the conductive film having conductivity, a conductive macromolecule or a conductive polymer may be used.

For the conductive film having a function of reflecting visible light, a material containing a metal element selected from gold, silver, copper, and palladium can be used. In particular, a conductive film containing a silver element is preferably used because reflectance of visible light can be improved.

For the conductive film having a function of transmitting visible light, a material containing an element selected from indium, tin, zinc, gallium, and silicon can be used. Specifically, an In oxide, a Zn oxide, an In—Sn oxide (also referred to as ITO), an In—Sn—Si oxide (also referred to as ITSO), an In—Zn oxide, an In—Ga—Zn oxide, or the like can be used.

As the conductive film having a function of transmitting visible light, a film containing graphene or graphite may be used. The film containing graphene can be formed in the following manner: a film containing graphene oxide is formed and is reduced. As a reducing method, a method with application of heat, a method using a reducing agent, or the like can be employed.

The conductive films 112, 120a, and 120b can be formed by electroless plating. As a material formed by the electroless plating, one or more of Cu, Ni, Al, Au, Sn, Co, Ag, and Pd can be used. Particularly, Cu or Ag is preferable because the resistance of the conductive film can be low.

In the case where the conductive film is formed by electroless plating, a diffusion prevention film may be formed below the conductive film so as to prevent diffusion of constituent elements of the conductive film into the outside. In addition, a seed layer that enables the conductive film to grow may be formed between the diffusion prevention film and the conductive film. The diffusion prevention film can be formed by, for example, a sputtering method. As the diffusion prevention film, for example, a tantalum nitride film or a titanium nitride film can be used. The seed layer can be formed by an electroless plating method. Alternatively, the seed layer can be formed using a material the same as a material of the conductive film that can be formed by an electroless plating method.

Note that an oxide semiconductor typified by an In—Ga—Zn oxide may be used for the conductive film 112. The oxide semiconductor can have a high carrier density when nitrogen or hydrogen is supplied from the insulating film 116. In other words, the oxide semiconductor functions as an oxide conductor (OC). Accordingly, the oxide semiconductor can be used for a gate electrode.

The conductive film 112 can have, for example, a single-layer structure of an oxide conductor (OC), a single-layer structure of a metal film, or a stacked-layer structure of an oxide conductor (OC) and a metal film.

Note that it is suitable that the conductive film 112 has a single-layer structure of a light-shielding metal film or a stacked-layer structure of an oxide conductor (OC) and a light-shielding metal film because the channel region 108i formed under the conductive film 112 can be shielded from light. In the case where the conductive film 112 has a stacked-layer structure of an oxide semiconductor or an oxide conductor (OC) and a light-shielding metal film, formation of a metal film (e.g., a titanium film or a tungsten film) over the oxide semiconductor or the oxide conductor (OC) produces any of the following effects: the resistance of the oxide semiconductor or the oxide conductor (OC) is reduced by the diffusion of the constituent element of the metal film to the oxide semiconductor or oxide conductor (OC) side, the resistance is reduced by damage (e.g., sputtering damage) during the deposition of the metal film, and the resistance is reduced when oxygen vacancies are formed by the diffusion of oxygen in the oxide semiconductor or the oxide conductor (OC) to the metal film.

The thickness of the conductive films 112, 120a, and 120b can be greater than or equal to 30 nm and less than or equal to 500 nm, or greater than or equal to 100 nm and less than or equal to 400 nm.

### <2-2. Structure Example 2 of Transistor>

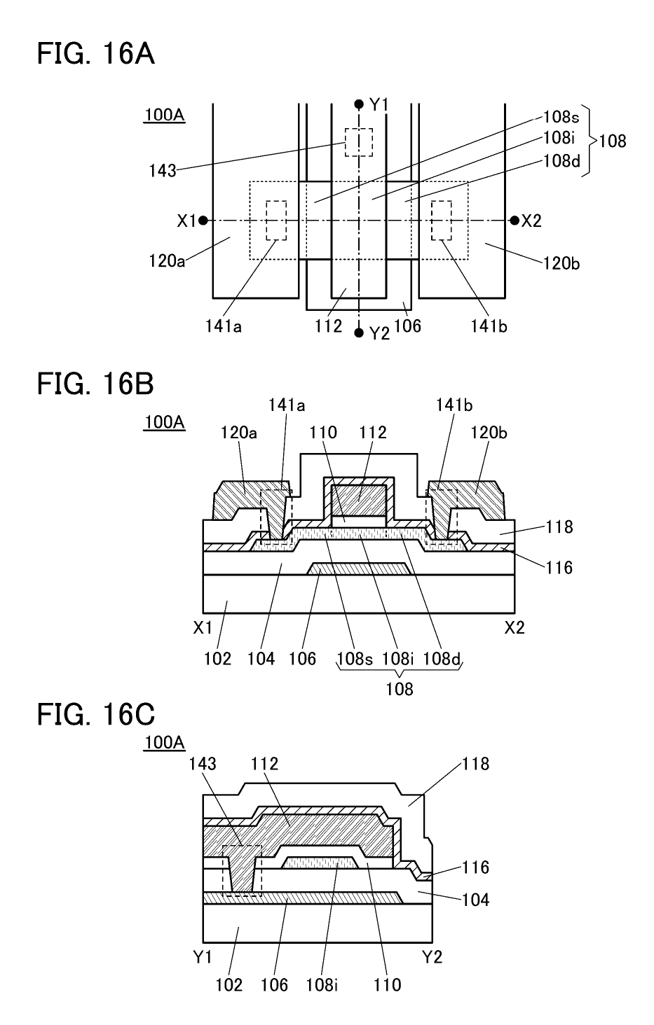

A structural example which is different from the transistor illustrated in FIGS. 15A to 15C will be described with reference to FIGS. 16A to 16C.

FIG. 16A is a top view of a transistor 100A. FIG. 16B is a cross-sectional view taken along dashed-dotted line X1-X2 in FIG. 16A. FIG. 16C is a cross-sectional view taken along dashed-dotted line Y1-Y2 in FIG. 16A.

The transistor 100A illustrated in FIGS. 16A to 16C includes a conductive film 106 over the substrate 102; the insulating film 104 over the conductive film 106; the oxide semiconductor film 108 over the insulating film 104; the insulating film 110 over the oxide semiconductor film 108; the conductive film 112 over the insulating film 110; and the insulating film 116 over the insulating film 104, the oxide semiconductor film 108, and the conductive film 112. Note that the oxide semiconductor film 108 includes a channel region 108i overlapping with the conductive film 112, a source region 108s in contact with the insulating film 116, and a drain region 108d in contact with the insulating film 116.

The transistor 100A includes the conductive film 106 and an opening 143 in addition to the components of the transistor 100 described above.

Note that the opening 143 is provided in the insulating films 104 and 110. The conductive film 106 is electrically connected to the conductive film 112 through the opening 143. Thus, the same potential is applied to the conductive film 106 and the conductive film 112. Note that different potentials may be applied to the conductive film 106 and the conductive film 112 without providing the opening 143. Alternatively, the conductive film 106 may be used as a light-shielding film without providing the opening 143. When the conductive film 106 is formed using a light-shielding material, for example, light irradiating the channel region 108i from the bottom can be reduced.

In the case of using the transistor 100A, the conductive film 106 functions as a first gate electrode (also referred to as bottom gate electrode), and the conductive film 112 functions as a second gate electrode (also referred to as top gate electrode). The insulating film 104 functions as a first gate insulating film, and the insulating film 110 functions as a second gate insulating film.

The conductive film 106 can be formed using a material similar to the above-described materials of the conductive films 112, 120a, and 120b. It is particularly suitable to use a material containing copper for the conductive film 106 because the resistance can be reduced. It is suitable that, for example, each of the conductive films 106, 120a, and 120b has a stacked-layer structure in which a copper film is over a titanium nitride film, a tantalum nitride film, or a tungsten film. In that case, when the transistor 100A is used as a pixel transistor and/or a driving transistor of a display device, parasitic capacitance generated between the conductive films 106 and 120a and between the conductive films 106 and 120b can be reduced. Thus, the conductive films 106, 120a, and 120b can be used not only as the first gate electrode, the source electrode, and the drain electrode of the transistor 100A, but also as power source supply wirings, signal supply wirings, connection wirings, or the like of the display device.

In this manner, the transistor 100A illustrated in FIGS. 16A to 16C is different from the transistor 100 described above and has a structure in which the conductive films functioning as the gate electrodes are provided over and under the oxide semiconductor film 108. As in the transistor 100A, the semiconductor device of one embodiment of the present invention may have a plurality of gate electrodes.

As illustrated in FIGS. 16B and 16C, the oxide semiconductor film 108 positioned to face the conductive film 106 functioning as the first gate electrode and the conductive film 112 functioning as the second gate electrode and is interposed between the two conductive films which function as gate electrodes.

Furthermore, the length of the conductive film 112 in the channel width direction is larger than the length of the oxide semiconductor film 108 in the channel width direction. In the channel width direction, the whole oxide semiconductor film 108 is covered with the conductive film 112 with the insulating film 110 interposed therebetween. Since the conductive film 112 is connected to the conductive film 106 through the opening 143 provided in the insulating films 104 and 110, a side surface of the oxide semiconductor film 108 in the channel width direction faces the conductive film 112 with the insulating film 110 interposed therebetween.

In other words, in the channel width direction of the transistor 100A, the conductive films 106 and 112 are connected to each other through the opening 143 provided in the insulating films 104 and 110, and the conductive films 106 and 112 surround the oxide semiconductor film 108 with the insulating films 104 and 110 interposed therebetween.

Such a structure enables the oxide semiconductor film 108 included in the transistor 100A to be electrically surrounded by electric fields of the conductive film 106 functioning as the first gate electrode and the conductive film 112 functioning as the second gate electrode. A device structure of a transistor, like that of the transistor 100A, in which electric fields of the first gate electrode and the second gate electrode electrically surround the oxide semiconductor film 108 in which a channel region is formed can be referred to as a surrounded channel (s-channel) structure.

Since the transistor 100A has the s-channel structure, an electric field for inducing a channel can be effectively applied to the oxide semiconductor film 108 by the conductive film 106 or the conductive film 112; thus, the current drive capability of the transistor 100A can be improved and high on-state current characteristics can be obtained. Since the on-state current can be increased, it is possible to reduce the size of the transistor 100A. Furthermore, since the transistor 100A has a structure in which the oxide semiconductor film 108 is surrounded by the conductive film 106 and the conductive film 112, the mechanical strength of the transistor 100A can be increased.

When seen in the channel width direction of the transistor 100A, an opening different from the opening 143 may be formed on the side of the oxide semiconductor film 108 on which the opening 143 is not formed.

When a transistor has a pair of gate electrodes between which a semiconductor film is interposed as in the case of the transistor 100A, a signal A may be applied to one gate electrode and a fixed potential V_{b} may be applied to the other gate electrode. Alternatively, one of the gate electrodes may be supplied with the signal A, and the other gate electrode may be supplied with a signal B. Alternatively, one of the gate electrodes may be supplied with a fixed potential Vₐ, and the other gate electrode may be supplied with the fixed potential V_{b}.

The signal A is, for example, a signal for controlling the on/off state. The signal A may be a digital signal with two kinds of potentials, a potential V₁ and a potential V₂ (V₁>V₂). For example, the potential V₁ can be a high power supply potential, and the potential V₂ can be a low power supply potential. The signal A may be an analog signal.

The fixed potential V_{b} is, for example, a potential for controlling a threshold voltage V_{thA} of the transistor. The fixed potential V_{b} may be the potential V₁ or the potential V₂. In that case, a potential generator circuit for generating the fixed potential V_{b} is not necessary, which is preferable. The fixed potential V_{b} may be different from the potential V₁ or the potential V₂. When the fixed potential V_{b} is low, the threshold voltage V_{thA} can be high in some cases. As a result, the drain current flowing when the gate-source voltage V_{gs} is 0 V can be reduced, and leakage current in a circuit including the transistor can be reduced in some cases. The fixed potential V_{b} may be, for example, lower than the low power supply potential. On the other hand, in some cases, the threshold voltage V_{thA} can be low by setting the fixed potential V_{b} high. As a result, drain current generated when the gate-source voltage V_{gs} is a high power supply potential can be increased and the operating speed of the circuit including the transistor can be improved in some cases. The fixed potential V_{b} may be, for example, higher than the low power supply potential.

The signal B is, for example, a signal for controlling the on/off state. The signal B may be a digital signal with two kinds of potentials, a potential V₃ and a potential V₄ (V₃>V₄). For example, the potential V₃ can be a high power supply potential, and the potential V₄ can be a low power supply potential. The signal B may be an analog signal.

When both the signal A and the signal B are digital signals, the signal B may have the same digital value as the signal A. In this case, it may be possible to increase the on-state current of the transistor and the operating speed of the circuit including the transistor. Here, the potential V₁ and the potential V₂ of the signal A may be different from the potential V₃ and the potential V₄ of the signal B. For example, if a gate insulating film for the gate to which the signal B is input is thicker than a gate insulating film for the gate to which the signal A is input, the potential amplitude of the signal B (V₃−V₄) may be larger than the potential amplitude of the signal A (V₁−V₂). In this manner, the influence of the signal A and that of the signal B on the on/off state of the transistor can be substantially the same in some cases.

When both the signal A and the signal B are digital signals, the signal B may have a digital value different from that of the signal A. In this case, the signal A and the signal B can separately control the transistor, and thus, higher performance can be achieved. The transistor which is, for example, an n-channel transistor can function by itself as a NAND circuit, a NOR circuit, or the like in the following case: the transistor is turned on only when the signal A has the potential V₁ and the signal B has the potential V₃, or the transistor is turned off only when the signal A has the potential V₂ and the signal B has the potential V₄. The signal B may be a signal for controlling the threshold voltage V_{thA}. For example, the potential of the signal B in a period in which the circuit including the transistor operates may be different from the potential of the signal B in a period in which the circuit does not operate. The potential of the signal B may vary depending on the operation mode of the circuit. In this case, the potential of the signal B is not necessarily changed as frequently as the potential of the signal A.

When both the signal A and the signal B are analog signals, the signal B may be an analog signal having the same potential as the signal A, an analog signal whose potential is a constant times the potential of the signal A, an analog signal whose potential is higher or lower than the potential of the signal A by a constant, or the like. In this case, it may be possible to increase the on-state current of the transistor and the operating speed of the circuit including the transistor. The signal B may be an analog signal different from the signal A. In this case, the signal A and the signal B can separately control the transistor, and thus, higher performance can be achieved.

The signal A may be a digital signal, and the signal B may be an analog signal. Alternatively, the signal A may be an analog signal, and the signal B may be a digital signal.

When both of the gate electrodes of the transistor are supplied with the fixed potentials, the transistor can function as an element equivalent to a resistor in some cases. For example, in the case where the transistor is an n-channel transistor, the effective resistance of the transistor can be sometimes low (high) when the fixed potential Vₐ or the fixed potential V_{b} is high (low). When both the fixed potential Vₐ and the fixed potential V_{b} are high (low), the effective resistance can be lower (higher) than that of a transistor with only one gate in some cases.

Note that the other components of the transistor 100A are similar to those of the transistor 100 described above, and an effect similar to that of the transistor 100A can be obtained.

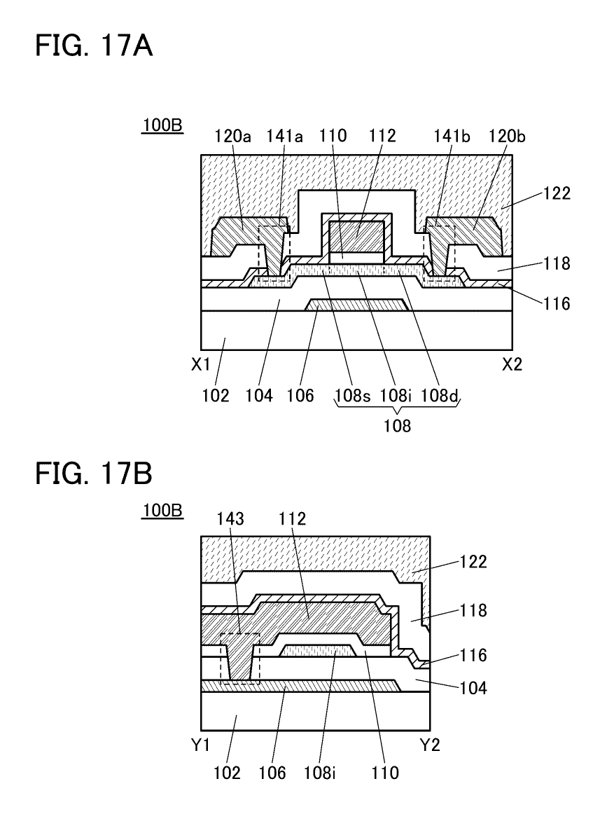

In addition, an insulating film may be formed over the transistor 100A. FIGS. 17A and 17B illustrate an example in this case. FIGS. 17A and 17B are cross-sectional views of a transistor 100B. A top view of the transistor 100B is the same as the transistor 100A illustrated in FIG. 16A; thus, the description of the top view is omitted.

The transistor 100B illustrated in FIGS. 17A and 17B includes an insulating film 122 over the conductive films 120a, 120b, and 118. The other components of the transistor 100B are similar to those of the transistor 100A described above and have similar effects.

The insulating film 122 has a function of covering unevenness and the like caused by the transistor or the like. The insulating film 122 has an insulating property and is formed using an inorganic material or an organic material. Examples of the inorganic material include a silicon oxide film, a silicon oxynitride film, a silicon nitride oxide film, a silicon nitride film, an aluminum oxide film, and an aluminum nitride film. Examples of the organic material include photosensitive resin materials such as an acrylic resin and a polyimide resin.

### <2-3. Structure Example 3 of Transistor>

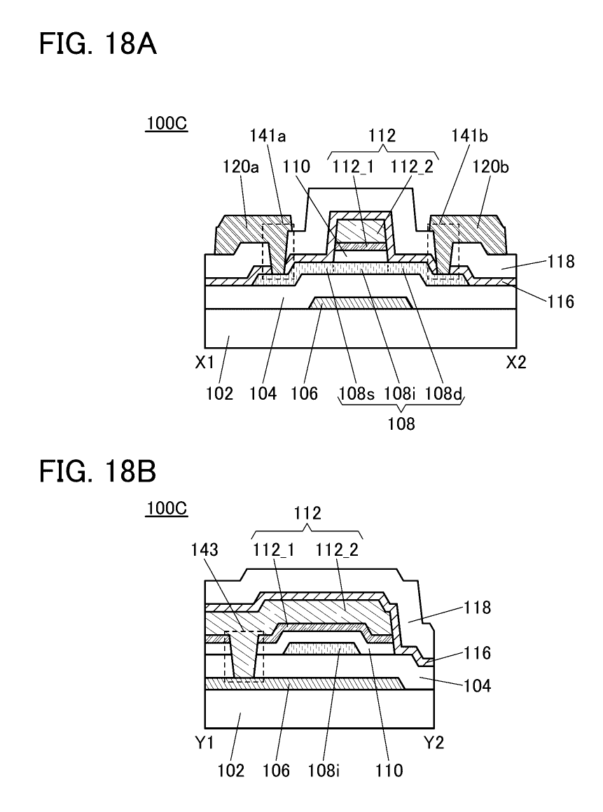

Next, structures of a transistor different from that in FIGS. 16A to 16C will be described with reference to FIGS. 18A and 18B, FIGS. 19A and 19B, and FIGS. 20A and 20B.

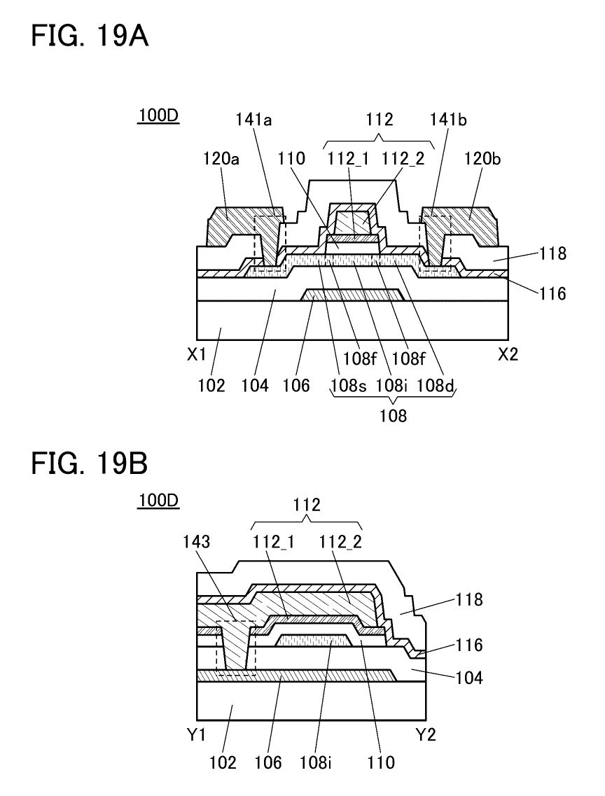

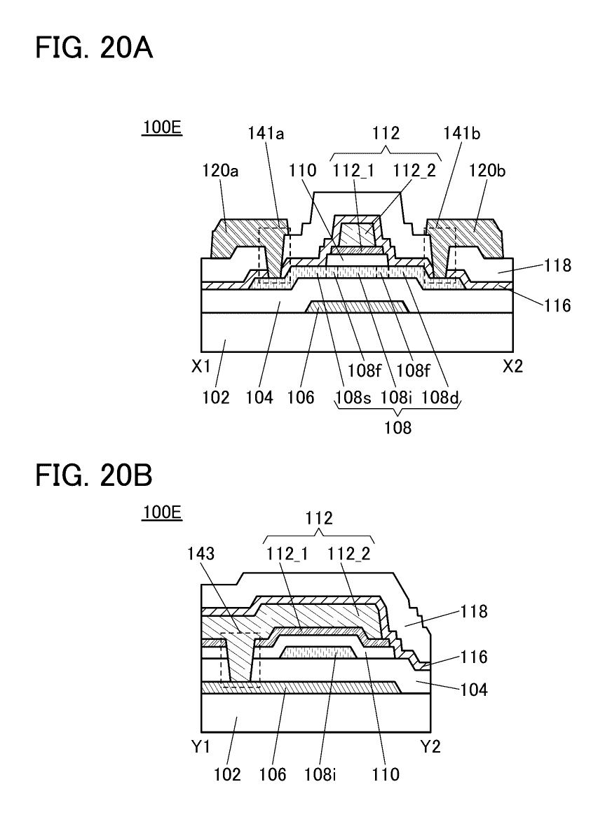

FIGS. 18A and 18B are cross-sectional views of a transistor 100C, FIGS. 19A and 19B are cross-sectional views of a transistor 100D, FIGS. 20A and 20B are cross-sectional views of a transistor 100E. Note that top views of the transistor 100C, the transistor 100D, and the transistor 100E are similar to that of the transistor 100A illustrated in FIG. 16A and thus are not described here.

The transistor 100C in FIGS. 18A and 18B is different from the transistor 100A in a stacked-layer structure of the conductive film 112, a shape of the conductive film 112, and a shape of the insulating film 110.

The conductive film 112 in the transistor 100C includes a conductive film 112_1 over the insulating film 110 and a conductive film 112_2 over the conductive film 112_1. For example, with use of an oxide conductive film as the conductive film 112_1, excess oxygen can be added to the insulating film 110. The oxide conductive film can be formed by a sputtering method in an atmosphere containing an oxygen gas. Furthermore, the oxide conductive film can be formed using, for example, an oxide including indium and tin, an oxide including tungsten and indium, an oxide including tungsten, indium, and zinc, an oxide including titanium and indium, an oxide including titanium, indium, and tin, an oxide including indium and zinc, an oxide including silicon, indium, and tin, an oxide including indium, gallium, and zinc, and the like.

As illustrated in FIG. 18B, the conductive film 1122 and the conductive film 106 are connected to each other in the opening 143. After a conductive film that is to be the conductive film 112_1 is formed, the opening 143 is formed, whereby a shape illustrated in FIG. 18B can be obtained. In the case where an oxide conductive film is used for the conductive film 112_1, the conductive film 112_2 and the conductive film 106 are formed to be connected to each other, so that the contact resistance between the conductive film 112 and the conductive film 106 can be lowered.

Each of the conductive film 112 and the insulating film 110 of the transistor 100C has a tapered shape. More specifically, the lower end portion of the conductive film 112 is located outward from the upper end portion of the conductive film 112. More specifically, the lower end portion of the conductive film 110 is located outward from the upper end portion of the insulating film 110. The lower end portion of the conductive film 112 is substantially aligned with the upper end portion of the insulating film 110.

It is preferable that the conductive film 112 and the insulating film 110 of the transistor 100C are formed to have tapered shapes because the coverage with the insulating film 116 can be improved as compared with the case where each of the conductive film 112 and the insulating film 110 of the transistor 100A has a rectangular shape.

The other components of the transistor 100C are similar to those of the transistor 100A described above and have similar effects.

The transistor 100D illustrated in FIGS. 19A and 19B is different from the transistor 100A in a stacked-layer structure of the conductive film 112, a shape of the conductive film 112, and a shape of the insulating film 110.

The conductive film 112 in the transistor 100D includes the conductive film 112_1 over the insulating film 110 and the conductive film 112_2 over the conductive film 112_1. The lower end portion of the conductive film 112_1 is located outward from the upper end portion of the conductive film 112_2. For example, the conductive film 112_1, the conductive film 112_2, and the insulating film 110 are processed with one mask, the conductive film 112_2 is processed by a wet etching method, and each of the conductive film 112_1 and the insulating film 110 is processed by a dry etching method, whereby the above-described structure can be obtained.

With the structure of the transistor 100D, regions 108f are formed in the oxide semiconductor film 108 in some cases. The regions 108f are formed between the channel region 108i and the source region 108s and between the channel region 108i and the drain region 108d.

The regions 108f function as high-resistance regions or low-resistance regions. The high-resistance regions have the same level of resistance as the channel region 108i and do not overlap with the conductive film 112 functioning as a gate electrode. In the case where the regions 108f are high-resistance regions, the regions 108f function as offset regions. To suppress a decrease in the on-state current of the transistor 100D, the regions 108f functioning as offset regions may each have a length of 1 μm or less in the channel length (L) direction.

The low-resistance regions have a resistance that is lower than that of the channel region 108i and higher than that of the source region 108s and the drain region 108d. In the case where the regions 108f are low-resistance regions, the regions 108f function as lightly doped drain (LDD) regions. The regions 108f functioning as LDD regions can relieve an electric field in the drain region, thereby reducing a change in the threshold voltage of the transistor due to the electric field in the drain region.

Note that when the regions 108f are LDD regions, for example, one or more of nitrogen, hydrogen, and fluorine is supplied to the regions 108f from the insulating film 116; accordingly the LDD regions can be formed. Alternatively, an impurity element is added to the regions 108f from above the conductive film 112_1 with use of the insulating film 110 and the conductive film 112_1 as masks, so that the impurity is added to the oxide semiconductor film 108 through the conductive film 112_1 and the insulating film 110; accordingly the LDD regions can be formed.

As illustrated in FIG. 19B, the conductive film 1122 and the conductive film 106 are connected to each other in the opening 143.

Note that the other components of the transistor 100D are similar to those of the transistor 100A described above, and an effect similar to that of the transistor 100A can be obtained.

The transistor 100E illustrated in FIGS. 20A and 20B is different from the transistor 100A in a stacked-layer structure of the conductive film 112, a shape of the conductive film 112, and a shape of the insulating film 110.

The conductive film 112 in the transistor 100E includes the conductive film 112_1 over the insulating film 110 and the conductive film 112_2 over the conductive film 112_1. The lower end portion of the conductive film 112_1 is located outward from the lower end portion of the conductive film 112_2. The lower end portion of the insulating film 110 is located outward from the lower end portion of the conductive film 112_1. For example, the conductive film 112_1, the conductive film 112_2, and the insulating film 110 are processed with one mask, each of the conductive film 112_1 and the conductive film 112_2 is processed by a wet etching method, and the insulating film 110 is processed by a dry etching method, whereby the above-described structure can be obtained.

As like the transistor 100D, the transistor 100E includes the regions 108f that are formed in the oxide semiconductor film 108. The regions 108f are formed between the channel region 108i and the source region 108s and between the channel region 108i and the drain region 108d.

As illustrated in FIG. 20B, the conductive film 112_2 and the conductive film 106 are connected to each other in the opening 143.

Note that the other components of the transistor 100E are similar to those of the transistor 100A described above, and an effect similar to that of the transistor 100A can be obtained.

### <2-4. Structure Example 4 of Transistor>

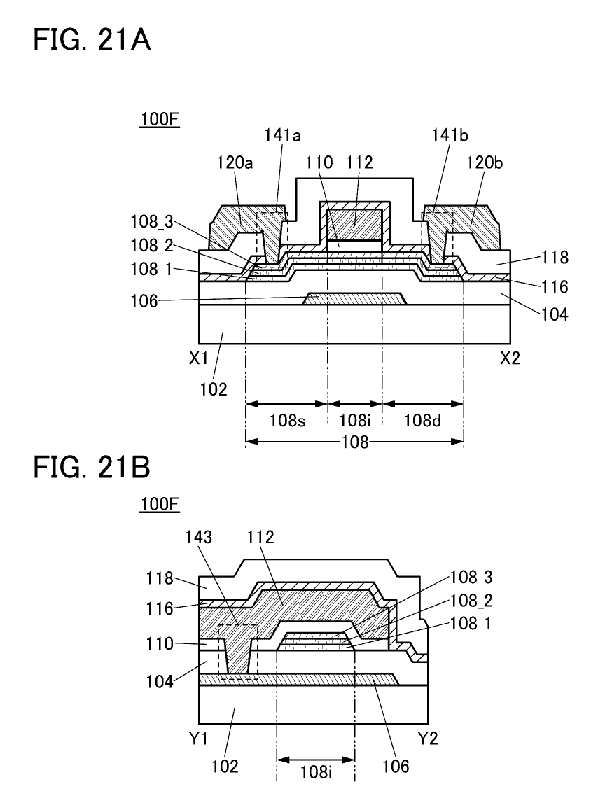

Next, structures of a transistor different from that of the transistor 100A in FIGS. 16A to 16C will be described with reference to FIGS. 21A and 21B, FIGS. 22A and 22B, FIGS. 23A and 23B, FIGS. 24A and 24B, and FIGS. 25A to 25C.

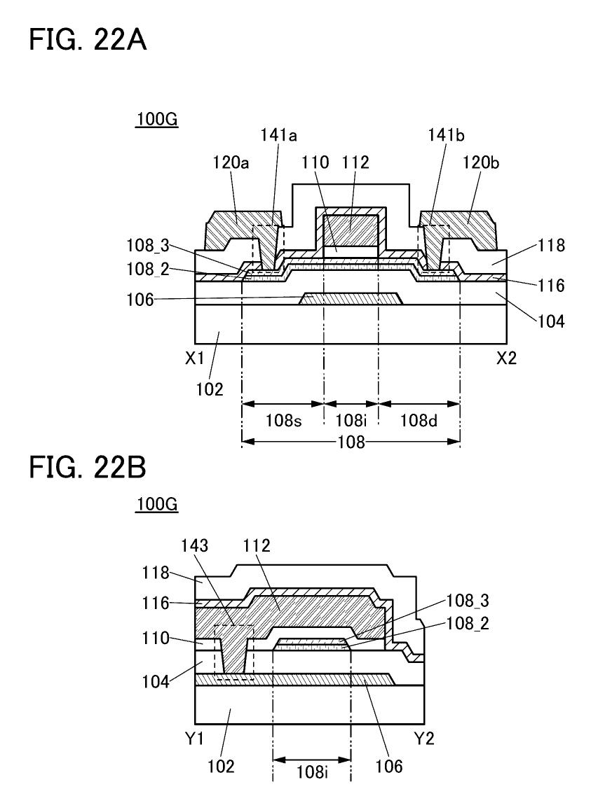

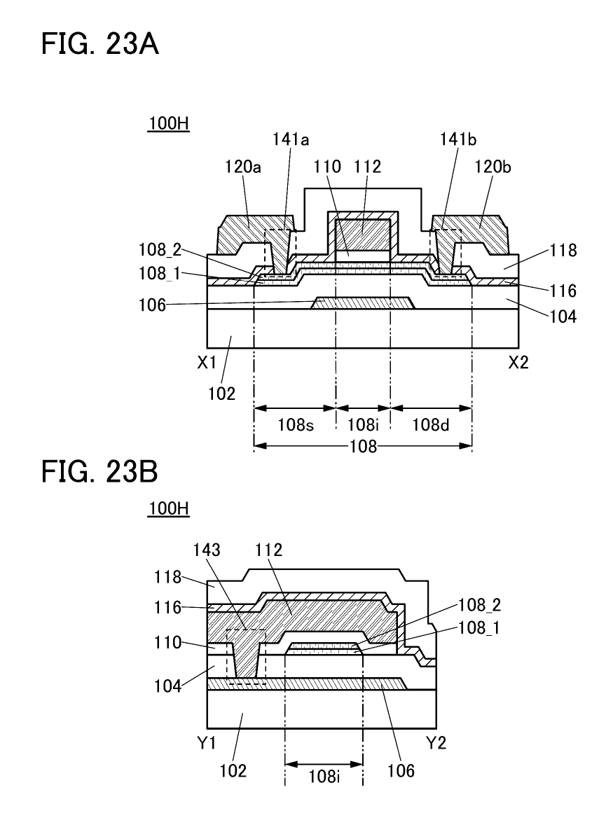

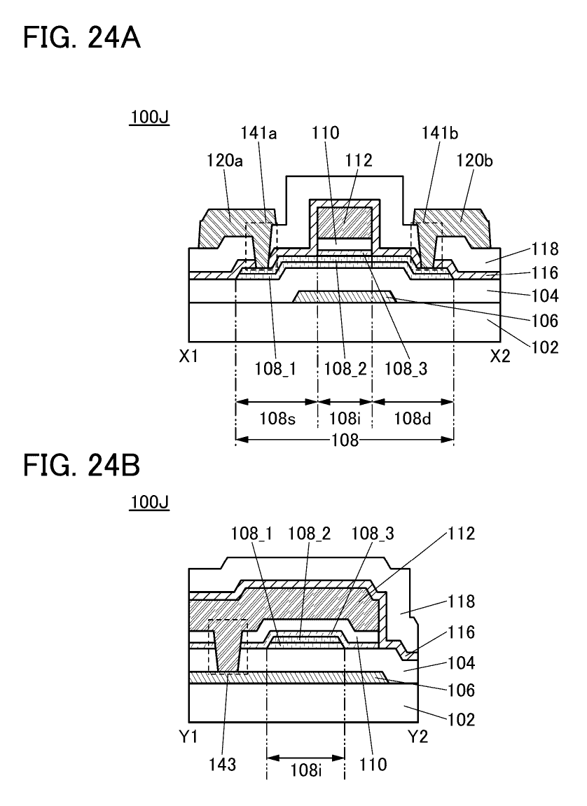

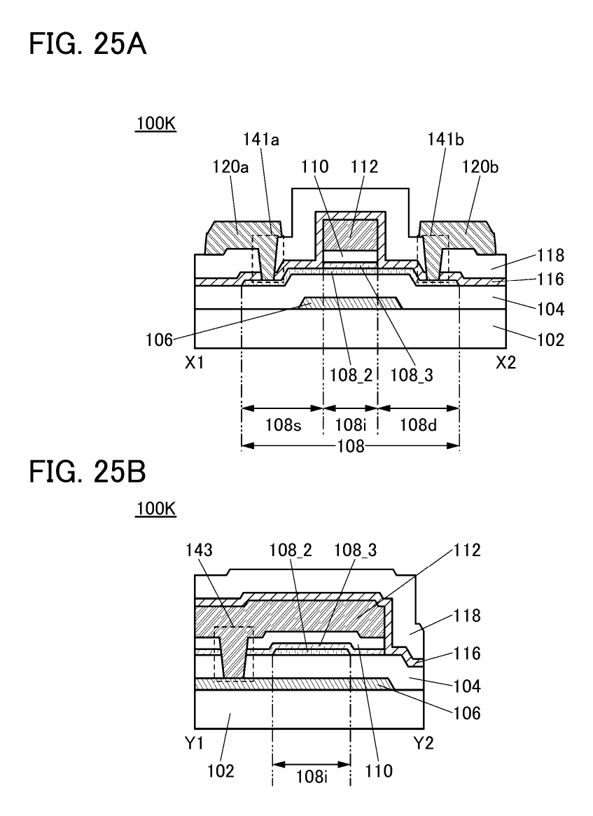

FIGS. 21A and 21B are cross-sectional views of a transistor 100F, FIGS. 22A and 22B are cross-sectional views of a transistor 100G, FIGS. 23A and 23B are cross-sectional views of a transistor 100H, FIGS. 24A and 24B are cross-sectional views of a transistor 100J, and FIGS. 25A and 25B are cross-sectional views of a transistor 100K. Note that top views of the transistor 100F, the transistor 100G, the transistor 100H, the transistor 100J, and the transistor 100K are similar to that of the transistor 100A illustrated in FIG. 16A and thus are not described here.

The transistors 100F, 100G, 100H, 100J, and 100K are different from the above-described transistor 100A in the structure of the oxide semiconductor film 108. Note that the other components of the transistors are similar to those of the transistor 100A described above, and an effect similar to that of the transistor 100A can be obtained.

The oxide semiconductor film 108 of the transistor 100F illustrated in FIGS. 21A and 21B includes an oxide semiconductor film 108_1 over the insulating film 104, an oxide semiconductor film 108_2 over the oxide semiconductor film 108_1, and an oxide semiconductor film 108_3 over the oxide semiconductor film 108_2. The channel region 108i, the source region 108s, and the drain region 108d each have a three-layer structure of the oxide semiconductor films 108_1, 108_2, and 108_3.

The oxide semiconductor film 108 of the transistor 100G illustrated in FIGS. 22A and 22B includes the oxide semiconductor film 108_2 over the insulating film 104, and the oxide semiconductor film 108_3 over the oxide semiconductor film 108_2. The channel region 108i, the source region 108s, and the drain region 108d each have a two-layer structure of the oxide semiconductor films 108_2 and 108_3.

The oxide semiconductor film 108 of the transistor 100H illustrated in FIGS. 23A and 23B includes the oxide semiconductor film 108_1 over the insulating film 104, and the oxide semiconductor film 108_2 over the oxide semiconductor film 108_1. The channel region 108i, the source region 108s, and the drain region 108d each have a two-layer structure of the oxide semiconductor film 108_1 and the oxide semiconductor film 108_2.

The oxide semiconductor film 108 of the transistor 100J illustrated in FIGS. 24A and 24B includes the oxide semiconductor film 108_1 over the insulating film 104, the oxide semiconductor film 108_2 over the oxide semiconductor film 108_1, and the oxide semiconductor film 108_3 over the oxide semiconductor film 108_2. The channel region 108i has a three-layer structure of the oxide semiconductor film 108_1, the oxide semiconductor film 108_2, and the oxide semiconductor film 108_3. The source region 108s and the drain region 108d each have a two-layer structure of the oxide semiconductor film 108_1 and the oxide semiconductor film 108_2. Note that in the cross section of the transistor 100J in the channel width (W) direction, the oxide semiconductor film 108_3 covers side surfaces of the oxide semiconductor film 108_1 and the oxide semiconductor film 108_2.

The oxide semiconductor film 108 of the transistor 100K illustrated in FIGS. 25A and 25B includes the oxide semiconductor film 108_2 over the insulating film 104, and the oxide semiconductor film 108_3 over the oxide semiconductor film 108_2. The channel region 108i has a two-layer structure of the oxide semiconductor film 108_2 and the oxide semiconductor film 108_3. The source region 108s and the drain region 108d each have a single-layer structure of the oxide semiconductor film 108_2. Note that in the cross section of the transistor 100K in the channel width (W) direction, the oxide semiconductor film 108_3 covers side surfaces of the oxide semiconductor film 108_2.

A side surface of the channel region 108i in the channel width (W) direction or a region in the vicinity of the side surface is easily damaged by processing, resulting in a defect (e.g., oxygen vacancy), or easily contaminated by an impurity attached thereto. Therefore, even when the channel region 108i is substantially intrinsic, stress such as an electric field applied thereto activates the side surface of the channel region 108i in the channel width (W) direction or the region in the vicinity of the side surface and turns it into a low-resistance (n-type) region easily. Moreover, if the side surface of the channel region 108i in the channel width (W) direction or the region in the vicinity of the side surface is an n-type region, a parasitic channel may be formed because the n-type region serves as a carrier path.

Thus, in the transistor 100J and the transistor 100K, the channel region 108i has a stacked-layer structure and side surfaces of the channel region 108i in the channel width (W) direction are covered with one layer of the stacked layers. With such a structure, defects on or in the vicinity of the side surfaces of the channel region 108i can be suppressed or adhesion of an impurity to the side surfaces of the channel region 108i or to regions in the vicinity of the side surfaces can be reduced.

### <2-5. Band Structure>

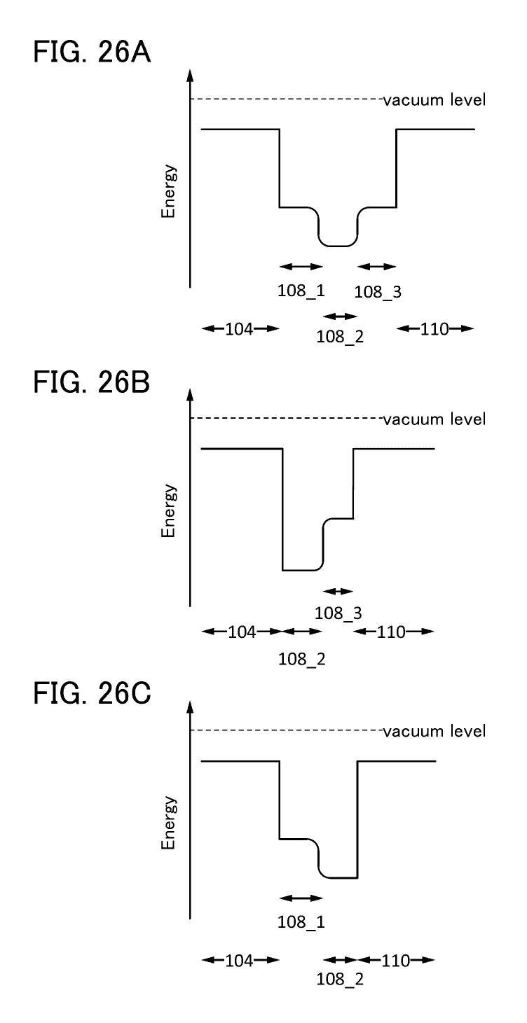

Here, a band structure of the insulating film 104, the oxide semiconductor films 108_1, 108_2, and 108_3, and the insulating film 110, a band structure of the insulating film 104, the oxide semiconductor films 108_2 and 108_3, and the insulating film 110, and a band structure of the insulating film 104, the oxide semiconductor films 108_1 and 108_2, and the insulating film 110 will be described with reference to FIGS. 26A to 26C. Note that FIGS. 26A to 26C are each a band structure of the channel region 108i.

FIG. 26A shows an example of a band structure in the thickness direction of a stack including the insulating film 104, the oxide semiconductor films 108_1, 108_2, and 108_3, and the insulating film 110. FIG. 26B shows an example of a band structure in the thickness direction of a stack including the insulating film 104, the oxide semiconductor films 108_2 and 108_3, and the insulating film 110. FIG. 26C shows an example of a band structure in the thickness direction of a stack including the insulating film 104, the oxide semiconductor films 108_1 and 108_2, and the insulating film 110. For easy understanding, the band structure shows energy level of the conduction band minimum (Ec) of each of the insulating film 104, the oxide semiconductor films 108_1, 108_2, and 108_3, and the insulating film 110.

In the band structure of FIG. 26A, a silicon oxide film is used as each of the insulating films 104 and 110; an oxide semiconductor film formed using a metal oxide target whose atomic ratio of In to Ga and Zn is 1:3:2 is used as the oxide semiconductor film 108_1; and an oxide semiconductor film formed using a metal oxide target whose atomic ratio of In to Ga and Zn is 4:2:4.1 is used as the oxide semiconductor film 108_2; and an oxide semiconductor film formed using a metal oxide target whose atomic ratio of In to Ga and Zn is 1:3:2 is used as the oxide semiconductor film 108_3.

In the band structure of FIG. 26B, a silicon oxide film is used as each of the insulating films 104 and 110, the oxide semiconductor film formed using a metal oxide target having an atomic ratio of metal elements of In:Ga:Zn=4:2:4.1 is used as the oxide semiconductor film 108_2, and the oxide semiconductor film formed using a metal oxide target having an atomic ratio of metal elements of In:Ga:Zn=1:3:2 is used as the oxide semiconductor film 108_3.

In the band structure of FIG. 26C, a silicon oxide film is used as each of the insulating films 104 and 110, an oxide semiconductor film formed using a metal oxide target whose atomic ratio of In to Ga and Zn is 1:3:2 is used as the oxide semiconductor film 108_1, and an oxide semiconductor film formed using a metal oxide target whose atomic ratio of In to Ga and Zn is 4:2:4.1 is used as the oxide semiconductor film 108_2.

As illustrated in FIG. 26A, the energy level of the conduction band minimum gradually varies between the oxide semiconductor films 108_1, 108_2, and 108_3. As illustrated in FIG. 26B, the energy level of the conduction band minimum gradually varies between the oxide semiconductor films 108_2 and 108_3. As illustrated in FIG. 26C, the conduction band minimum gradually varies between the oxide semiconductor films 108_1 and 108_2. In other words, the energy level of the conduction band minimum is continuously varied or continuously connected. To obtain such a band structure, there exists no impurity, which forms a defect state such as a trap center or a recombination center, at the interface between the oxide semiconductor films 108_1 and 108_2 and the interface between the oxide semiconductor films 108_2 and 108_3.

To form a continuous junction between the oxide semiconductor films 108_1, 108_2, and 108_3, it is necessary to form the films successively without exposure to the air by using a multi-chamber deposition apparatus (sputtering apparatus) provided with a load lock chamber.

With the band structure of FIGS. 26A to 26C, the oxide semiconductor film 108_2 serves as a well, and a channel region is formed in the oxide semiconductor film 108_2 in the transistor with the stacked-layer structure.

By providing the oxide semiconductor films 108_1 and 108_3, the oxide semiconductor film 108_2 can be distanced away from defect states that may be formed in the oxide semiconductor film 108_2.

In addition, the defect states might be more distant from the vacuum level than the conduction band minimum (E_{c}) of the oxide semiconductor film 108_2 functioning as a channel region, so that electrons are likely to be accumulated in the defect states. When the electrons are accumulated in the defect states, the electrons become negative fixed electric charge, so that the threshold voltage of the transistor is shifted in the positive direction. Therefore, it is preferable that the defect states be closer to the vacuum level than the conduction band minimum (E_{c}) of the oxide semiconductor film 108_2. Such a structure inhibits accumulation of electrons in the defect states. As a result, the on-state current and the field-effect mobility of the transistor can be increased.

The energy level of the conduction band minimum of each of the oxide semiconductor films 108_1 and 108_3 is closer to the vacuum level than that of the oxide semiconductor film 108_2. Typically, a difference in energy level between the conduction band minimum of the oxide semiconductor film 108_2 and the conduction band minimum of each of the oxide semiconductor films 108_1 and 108_3 is 0.15 eV or more or 0.5 eV or more and 2 eV or less or 1 eV or less. That is, the electron affinity of the oxide semiconductor film 108_2 is higher than those of the oxide semiconductor films 108_1 and 108_3. The difference between the electron affinity of each of the oxide semiconductor films 108_1 and 108_3 and the electron affinity of the oxide semiconductor film 108_2 is 0.15 eV or more or 0.5 eV or more and 2 eV or less or 1 eV or less.

In such a structure, the oxide semiconductor film 108_2 serves as a main current path. In other words, the oxide semiconductor film 108_2 functions as a channel region, and the oxide semiconductor films 108_1 and 108_3 function as oxide insulating films. The oxide semiconductor films 108_1 and 108_3 are each preferably formed using an oxide semiconductor film containing one or more metal elements constituting the oxide semiconductor film 108_2 in which a channel region is formed. In such a structure, interface scattering hardly occurs at the interface between the oxide semiconductor films 108_1 and 108_2 and the interface between the oxide semiconductor films 108_2 and 108_3. Thus, the transistor can have high field-effect mobility because the transfer of carriers is not hindered at the interface.

To prevent each of the oxide semiconductor films 108_1 and 108_3 from functioning as part of a channel region, a material having sufficiently low conductivity is used for the oxide semiconductor films 108_1 and 108_3. Thus, each of the oxide semiconductor films 108_1 and 108_3 can also be referred to as “oxide insulating film” owing to its physical property and/or function. Alternatively, a material which has a smaller electron affinity (a difference in energy level between the vacuum level and the conduction band minimum) than the oxide semiconductor film 108_2 and has a difference in energy level in the conduction band minimum from the oxide semiconductor film 108_2 (band offset) is used for the oxide semiconductor films 108_1 and 108_3. Furthermore, to inhibit generation of a difference between threshold voltages due to the value of the drain voltage, it is preferable to form the oxide semiconductor films 108_1 and 108_3 using a material whose energy level of the conduction band minimum is closer to the vacuum level than that of the oxide semiconductor film 108_2. For example, a difference between the energy level of the conduction band minimum of the oxide semiconductor film 108_2 and the energy level of the conduction band minimum of each of the oxide semiconductor films 108_1 and 108_3 is preferably 0.2 eV or more and further preferably 0.5 eV or more.

It is preferable that the oxide semiconductor films 108_1 and 108_3 not have a spinel crystal structure. This is because if the oxide semiconductor films 108_1 and 108_3 have a spinel crystal structure, constituent elements of the conductive films 120a and 120b might be diffused to the oxide semiconductor film 108_2 at the interface between the spinel crystal structure and another region. Note that each of the oxide semiconductor films 108_1 and 108_3 is preferably a CAAC-OS described later, in which case a higher blocking property against constituent elements of the conductive films 120a and 120b, for example, copper elements, can be obtained.

Although the example where an oxide semiconductor film formed using a metal oxide target whose atomic ratio of In to Ga and Zn is 1:3:2, is used as each of the oxide semiconductor films 108_1 and 108_3 is described in this embodiment, one embodiment of the present invention is not limited thereto. For example, an oxide semiconductor film formed using a metal oxide target whose atomic ratio of In to Ga and Zn is 1:1:1, 1:1:1.2, 1:3:4, 1:3:6, 1:4:5, 1:5:6, or 1:10:1 may be used as each of the oxide semiconductor films 108_1 and 108_3. Alternatively, oxide semiconductor films formed using a metal oxide target whose atomic ratio of Ga to Zn is 10:1 may be used as the oxide semiconductor films 108_1 and 108_3. In that case, it is suitable that an oxide semiconductor film formed using a metal oxide target whose atomic ratio of In to Ga and Zn is 1:1:1 is used as the oxide semiconductor film 108_2 and that an oxide semiconductor film formed using a metal oxide target whose atomic ratio of Ga to Zn is 10:1 is used as each of the oxide semiconductor films 108_1 and 108_3. This is because the difference between the conduction band minimum of the oxide semiconductor film 108_2 and the conduction band minimum of the oxide semiconductor film 108_1 or 108_3 can be 0.6 eV or more.

When the oxide semiconductor films 108_1 and 108_3 are formed using a metal oxide target having an atomic ratio of In:Ga:Zn=1:1:1, the oxide semiconductor films 108_1 and 108_3 have an atomic ratio of In:Ga:Zn=1:β1 (0<β1≦2):β2 (0<β2≦2) in some cases. When the oxide semiconductor films 108_1 and 108_3 are formed using a metal oxide target having an atomic ratio of In:Ga:Zn=1:3:4, the oxide semiconductor films 108_1 and 108_3 have an atomic ratio of In:Ga:Zn=1:β3 (1≦β3≦5):β4 (2≦β4≦6) in some cases. When the oxide semiconductor films 108_1 and 108_3 are formed using a metal oxide target having an atomic ratio of In:Ga:Zn=1:3:6, the oxide semiconductor films 108_1 and 108_3 have an atomic ratio of In:Ga:Zn=1:β5 (1≦β5≦5):β6 (4≦β6≦8) in some cases.

The structure described in this embodiment can be used in appropriate combination with the structure described in any of the other embodiments.

### Embodiment 3

In this embodiment, a transistor that can be used for the semiconductor device of one embodiment of the present invention is described in detail.

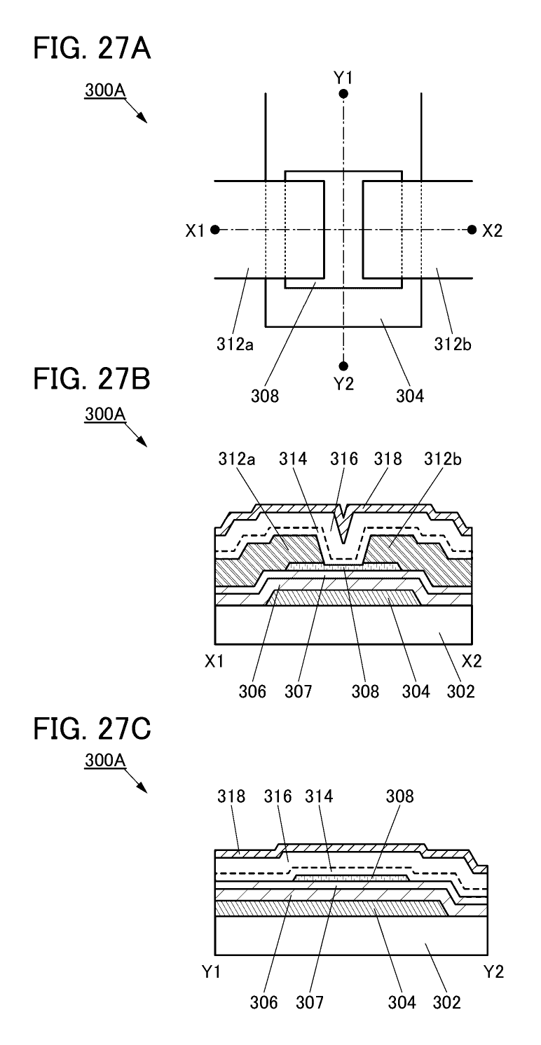

In this embodiment, bottom-gate transistors are described with reference FIGS. 27A to 27C, FIGS. 28A to 28C, FIGS. 29A to 29C, FIGS. 30A to 30C, FIGS. 31A and 31B, FIGS. 32A and 32B, and FIGS. 33A to 33C.

### <3-1. Structure Example 1 of Transistor>

FIG. 27A is a top view of the transistor 300A. FIG. 27B is a cross-sectional view taken along the dashed-dotted line X1-X2 in FIG. 27A. FIG. 27C is a cross-sectional view taken along the dashed-dotted line Y1-Y2 in FIG. 27A. Note that in FIG. 27A, some components of the transistor 300A (e.g., an insulating film functioning as a gate insulating film) are not illustrated to avoid complexity. The direction of the dashed-dotted line X1-X2 may be called a channel length direction, and the direction of the dashed-dotted line Y1-Y2 may be called a channel width direction. As in FIG. 27A, some components are not illustrated in some cases in top views of transistors described below.

The transistor 300A illustrated in FIGS. 27A to 27C includes a conductive film 304 over a substrate 302, an insulating film 306 over the substrate 302 and the conductive film 304, an insulating film 307 over the insulating film 306, an oxide semiconductor film 308 over the insulating film 307, a conductive film 312a over the oxide semiconductor film 308, and a conductive film 312b over the oxide semiconductor film 308. Over the transistor 300A, specifically, over the conductive films 312a and 312b and the oxide semiconductor film 308, an insulating film 314, an insulating film 316, and an insulating film 318 are provided.

In the transistor 300A, the insulating films 306 and 307 each function as a gate insulating film of the transistor 300A, and the insulating films 314, 316, and 318 each function as a protective insulating film of the transistor 300A. Moreover, in the transistor 300A, the conductive film 304 functions as a gate electrode, the conductive film 312a functions as a source electrode, and the conductive film 312b functions as a drain electrode.

In this specification and the like, the insulating films 306 and 307 may be referred to as a first insulating film, the insulating films 314 and 316 may be referred to as a second insulating film, and the insulating film 318 may be referred to as a third insulating film.

The transistor 300A illustrated in FIGS. 27A to 27C is a channel-etched transistor. The oxide semiconductor film of one embodiment of the present invention can be used suitably for the channel-etched transistor.

### <3-2. Structure Example 2 of Transistor>

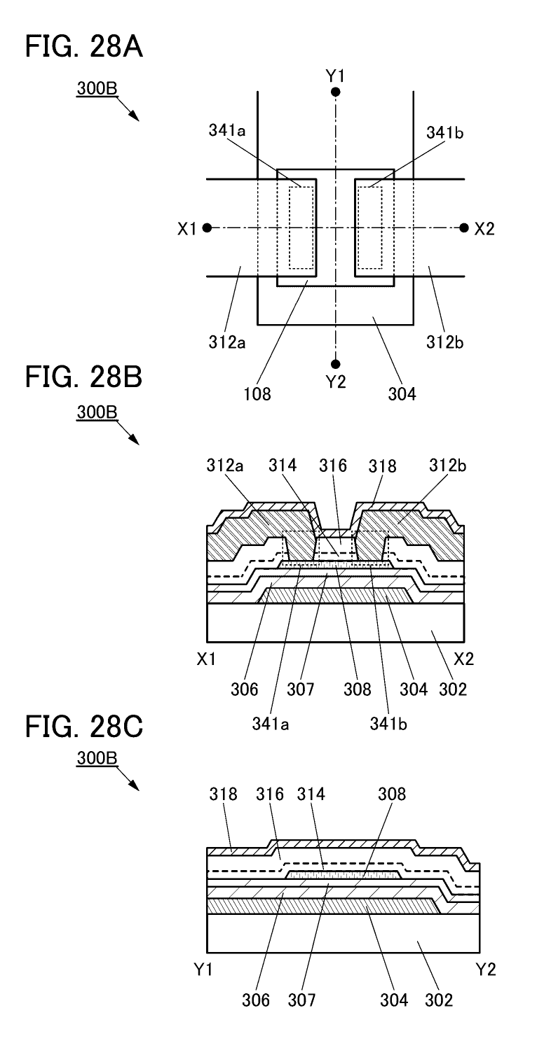

FIG. 28A is a top view of a transistor 300B. FIG. 28B is a cross-sectional view taken along dashed-dotted line X1-X2 in FIG. 28A. FIG. 28C is a cross-sectional view taken along dashed-dotted line Y1-Y2 in FIG. 28A.

The transistor 300B illustrated in FIGS. 28A to 28C includes the conductive film 304 over the substrate 302, the insulating film 306 over the substrate 302 and the conductive film 304, the insulating film 307 over the insulating film 306, the oxide semiconductor film 308 over the insulating film 307, the insulating film 314 over the oxide semiconductor film 308, the insulating film 316 over the insulating film 314, the conductive film 312a electrically connected to the oxide semiconductor film 308 through an opening 341a provided in the insulating films 314 and 316, and the conductive film 312b electrically connected to the oxide semiconductor film 308 through an opening 341b provided in the insulating films 314 and 316. Over the transistor 300B, more specifically, over the conductive films 312a and 312b and the insulating film 316, the insulating film 318 is provided.

In the transistor 300B, the insulating films 306 and 307 each function as a gate insulating film of the transistor 300B, the insulating films 314 and 316 each function as a protective insulating film of the oxide semiconductor film 308, and the insulating film 318 functions as a protective insulating film of the transistor 300B. Moreover, in the transistor 300B, the conductive film 304 functions as a gate electrode, the conductive film 312a functions as a source electrode, and the conductive film 312b functions as a drain electrode.

The transistor 300B in FIGS. 28A to 28C has a channel-protective structure, whereas the transistor 300A in FIGS. 27A to 27C has a channel-etched structure. The oxide semiconductor of one embodiment of the present invention can be used suitably for the channel-protective transistor.

### <3-3. Structure Example 3 of Transistor>

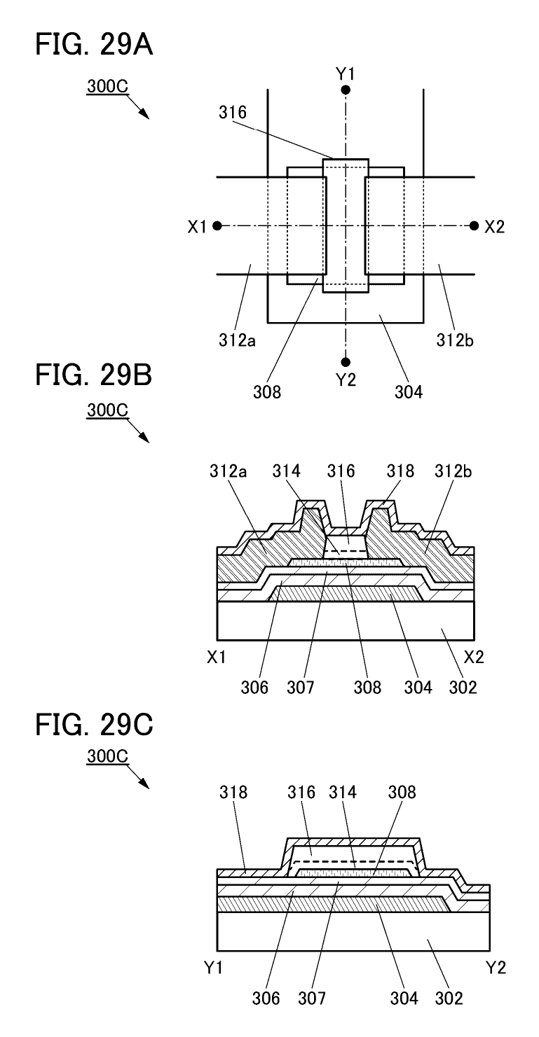

FIG. 29A is a top view of a transistor 300C. FIG. 29B is a cross-sectional view taken along dashed-dotted line X1-X2 in FIG. 29A. FIG. 29C is a cross-sectional view taken along dashed-dotted line Y1-Y2 in FIG. 29A.

The transistor 300C in FIGS. 29A to 29C is different from the transistor 300B in FIGS. 28A to 28C in the shapes of the insulating films 314 and 316. Specifically, the insulating films 314 and 316 of the transistor 300C have island shapes and are provided over a channel region of the oxide semiconductor film 308. Other components are similar to those of the transistor 300B.

### <3-4. Structure Example 4 of Transistor>

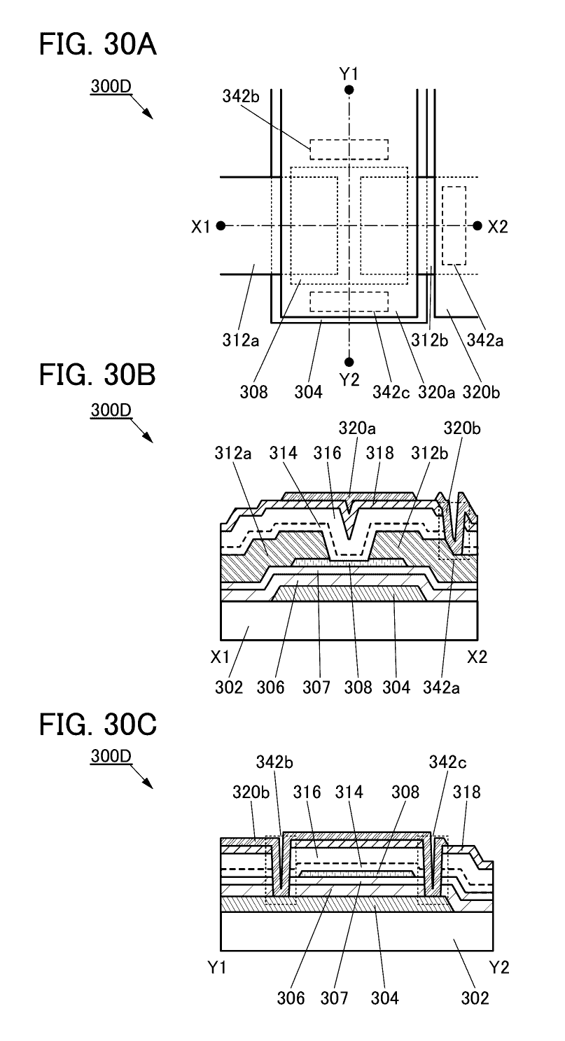

FIG. 30A is a top view of a transistor 300D. FIG. 30B is a cross-sectional view taken along dashed-dotted line X1-X2 in FIG. 30A. FIG. 30C is a cross-sectional view taken along dashed-dotted line Y1-Y2 in FIG. 30A.

The transistor 300D in FIGS. 30A to 30C includes the conductive film 304 over the substrate 302, the insulating film 306 over the substrate 302 and the conductive film 304, the insulating film 307 over the insulating film 306, the oxide semiconductor film 308 over the insulating film 307, the conductive film 312a over the oxide semiconductor film 308, the conductive film 312b over the oxide semiconductor film 308, the insulating film 314 over the oxide semiconductor film 308 and the conductive film 312a and 312b, the insulating film 316 over the insulating film 314, the insulating film 318 over the insulating film 316, and conductive films 320a and 320b over the insulating film 318.

In the transistor 300D, the insulating films 306 and 307 each function as a first gate insulating film of the transistor 300D, and the insulating films 314, 316, and 318 each function as a second gate insulating film of the transistor 300D. Moreover, in the transistor 300D, the conductive film 304 functions as a first gate electrode, the conductive film 320a functions as a second gate electrode, and the conductive film 320b functions as a pixel electrode used for a display device. The conductive film 312a and the conductive film 312b function as a source electrode and a drain electrode, respectively.

As illustrated in FIG. 30C, the conductive film 320b is connected to the conductive film 304 in an opening 342b and an opening 342c provided in the insulating films 306, 307, 314, 316, and 318. Thus, the same potential is applied to the conductive film 320b and the conductive film 304.

The structure of the transistor 300D is not limited to that described above, in which the openings 342b and 342c are provided so that the conductive film 320b is connected to the conductive film 304. For example, a structure in which only one of the openings 342b and 342c is provided so that the conductive film 320b is connected to the conductive film 304, or a structure in which the openings 342b and 342c are not provided and the conductive film 320b is not connected to the conductive film 304 may be employed. Note that in the case where the conductive film 320b is not connected to the conductive film 304, it is possible to apply different potentials to the conductive film 320b and the conductive film 304.

The conductive film 320b is connected to the conductive film 312b through an opening 342a provided in the insulating films 314, 316, and 318.

Note that the transistor 300D has the s-channel structure described above.

### <3-5. Structure Example 5 of Transistor>

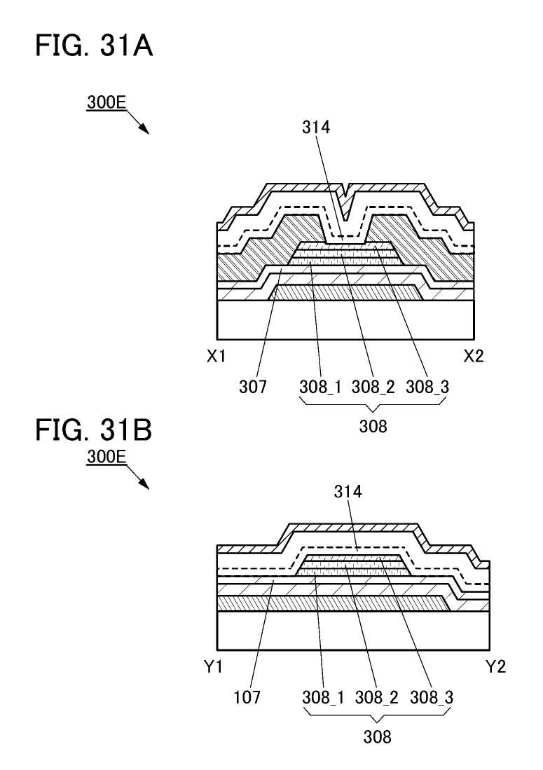

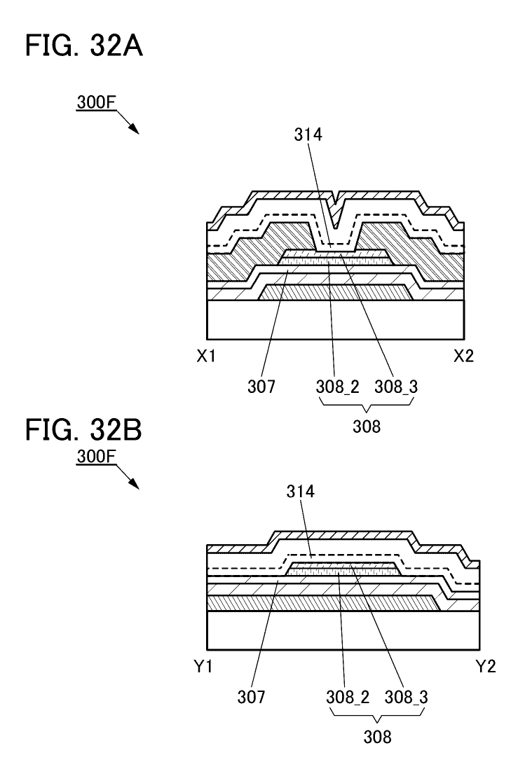

The oxide semiconductor film 308 included in the transistor 300A in FIGS. 27A to 27C may have a stacked-layer structure. Examples thereof are illustrated in FIGS. 31A and 31B and FIGS. 32A and 32B.

FIGS. 31A and 31B are cross-sectional views of a transistor 300E, and FIGS. 32A and 32B are cross-sectional views of a transistor 300F. The top views of the transistors 300E and 300F are similar to that of the transistor 300A illustrated in FIG. 27A.

The oxide semiconductor film 308 of the transistor 300E illustrated in FIGS. 31A and 31B includes an oxide semiconductor film 308_1, an oxide semiconductor film 308_2, and an oxide semiconductor film 308_3. The oxide semiconductor film 308 of the transistor 300F illustrated in FIGS. 32A and 32B includes the oxide semiconductor film 308_2 and the oxide semiconductor film 308_3.

Note that the conductive film 304, the insulating film 306, the insulating film 307, the oxide semiconductor film 308, the oxide semiconductor film 308_1, the oxide semiconductor film 308_2, the oxide semiconductor film 308_3, the conductive film 312a, the conductive film 312b, the insulating film 314, the insulating film 316, the insulating film 318, and the conductive films 320a and 320b can be formed using the materials and formation methods of the conductive film 106, the insulating film 116, the insulating film 114, the oxide semiconductor film 108, the oxide semiconductor film 108_1, the oxide semiconductor film 108_2, the oxide semiconductor film 108_3, the conductive film 120a, the conductive film 120b, the insulating film 104, the insulating film 118, the insulating film 116, and the conductive film 112 described in the above embodiment.

### <3-6. Structure Example 6 of Transistor>

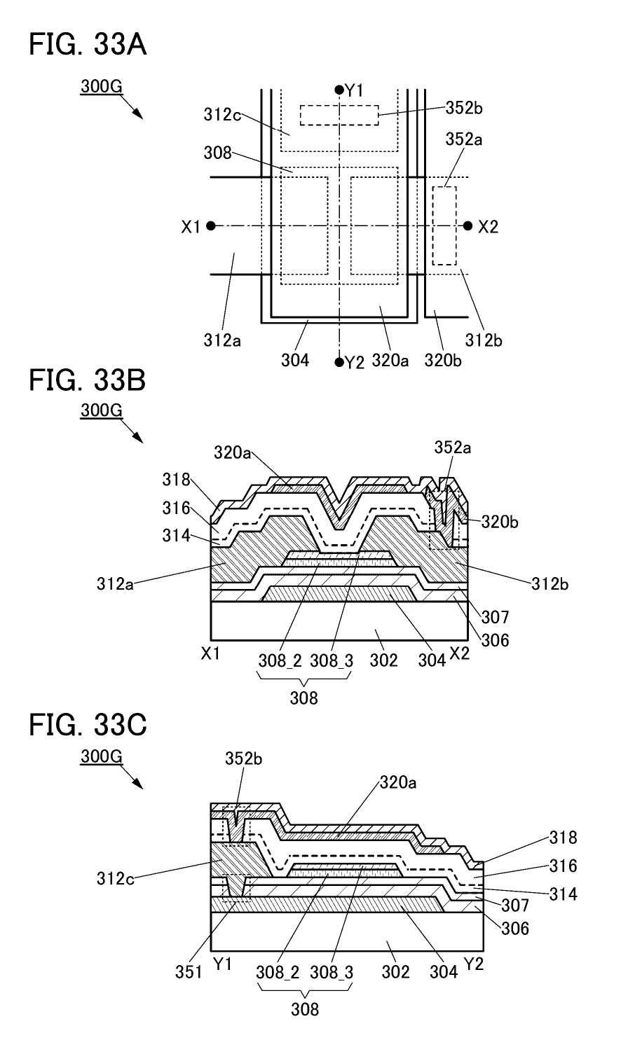

FIG. 33A is a top view of a transistor 300G. FIG. 33B is a cross-sectional view taken along dashed-dotted line X1-X2 in FIG. 33A. FIG. 33C is a cross-sectional view taken along dashed-dotted line Y1-Y2 in FIG. 33A.

The transistor 300G in FIGS. 33A to 33C includes the conductive film 304 over the substrate 302, the insulating film 306 over the substrate 302 and the conductive film 304, the insulating film 307 over the insulating film 306, the oxide semiconductor film 308 over the insulating film 307, the conductive film 312a over the oxide semiconductor film 308, the conductive film 312b over the oxide semiconductor film 308, the insulating film 314 over the oxide semiconductor film 308, the conductive film 312a, and the conductive film 312b, the insulating film 316 over the insulating film 314, the conductive film 320a over the insulating film, 316, and the conductive film 320b over the insulating film 316.

The insulating film 306 and the insulating film 307 has an opening 351, and a conductive film 312c electrically connected to the conductive film 304 through the opening 351 is provided over the insulating film 306 and the insulating film 307. The insulating films 314 and 316 have an opening 352a reaching the conductive film 312b and an opening 352b reaching the conductive film 312c.

Note that the oxide semiconductor film 308 includes the oxide semiconductor film 308_2 that is on the conductive film 304 side and the oxide semiconductor film 308_3 over the oxide semiconductor film 308_2.

The insulating film 318 is provided over the transistor 300G. The insulating film 318 is formed to cover the insulating film 316, the conductive film 320a, and the conductive film 320b.

In the transistor 300G, the insulating films 306 and 307 each function as a first gate insulating film of the transistor 300G, the insulating films 314 and 316 each function as a second gate insulating film of the transistor 300G, and the insulating film 318 functions as a protective insulating film of the transistor 300G. In the transistor 300G, the conductive film 304 functions as a first gate electrode, the conductive film 320a functions as a second gate electrode, and the conductive film 320b functions as a pixel electrode used for a display device. Furthermore, in the transistor 300G, the conductive film 312a functions as a source electrode, and the conductive film 312b functions as a drain electrode. Moreover, in the transistor 300G, the conductive film 312c functions as a connection electrode.

The transistor 300G has the s-channel structure described above.

The structures of the transistors 300A to 300G can be freely combined with each other.

The structure described in this embodiment can be used in appropriate combination with the structure described in any of the other embodiments.

### Embodiment 4

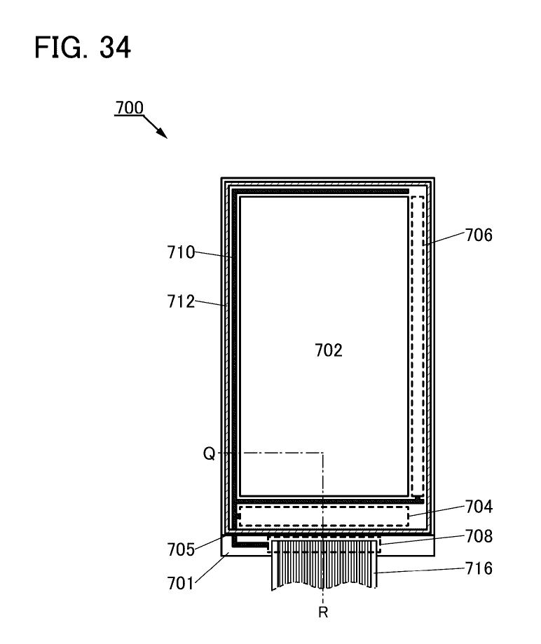

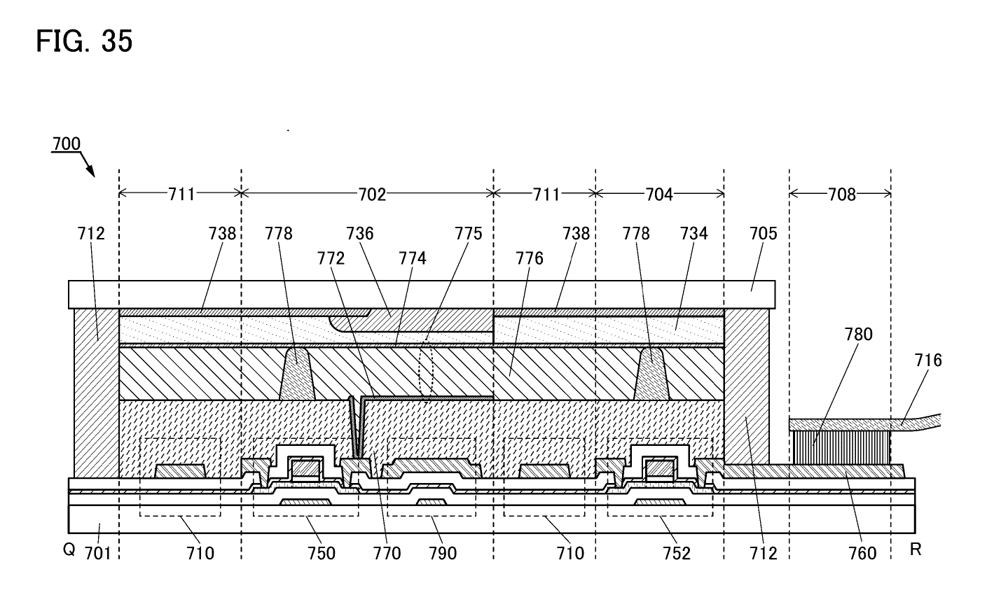

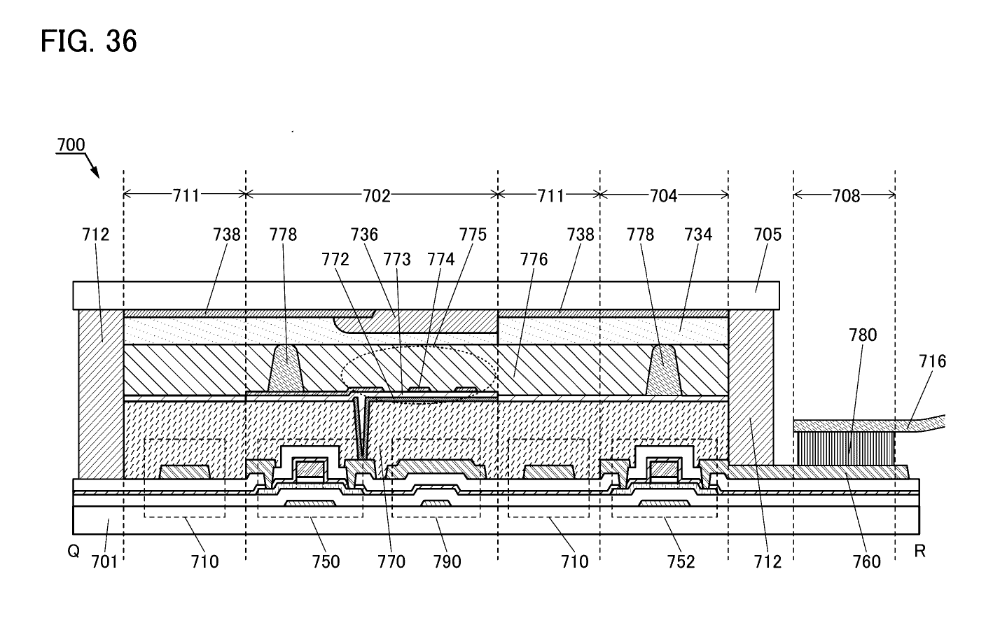

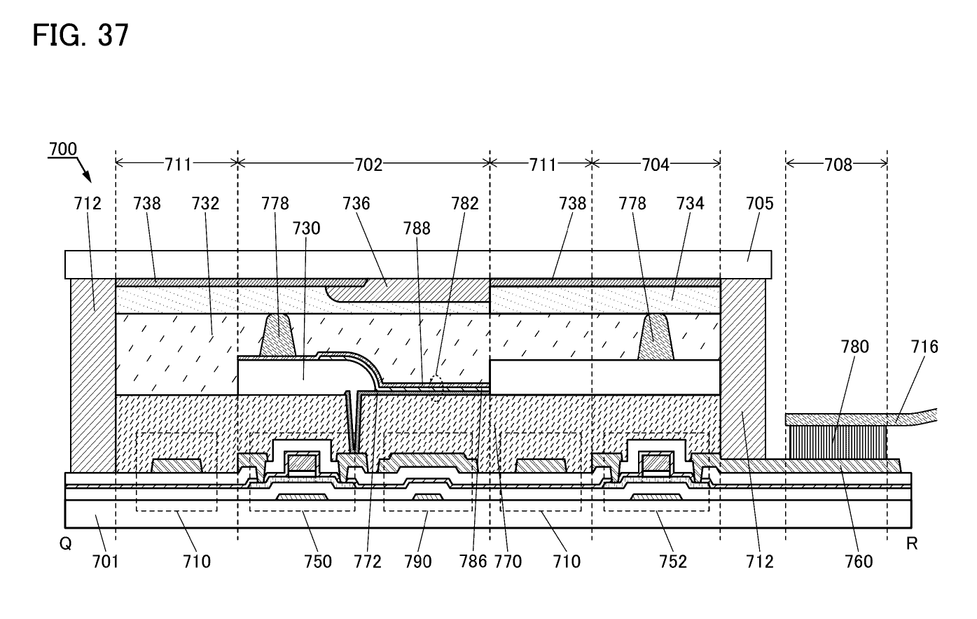

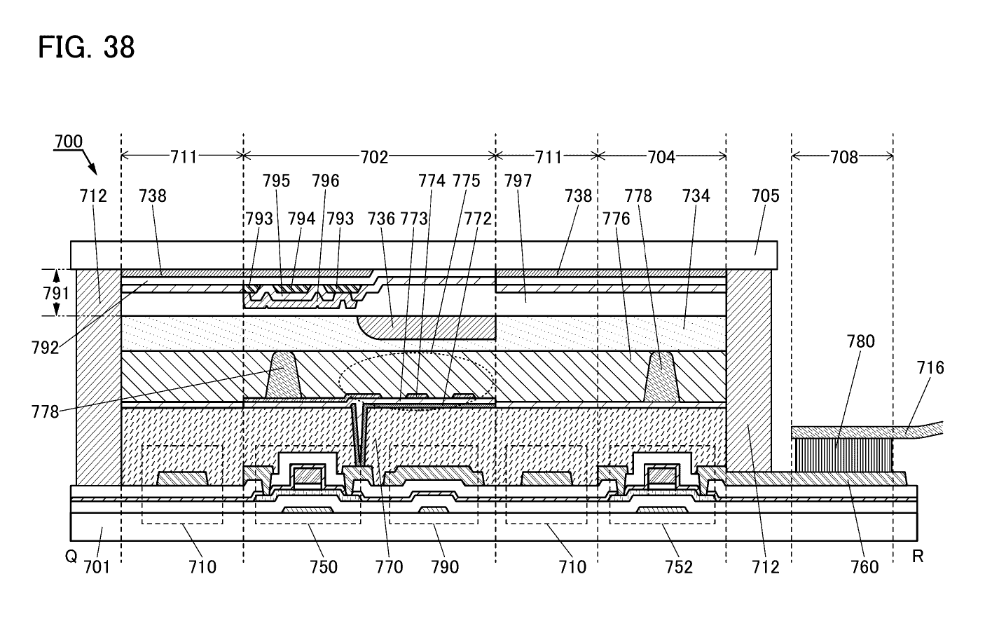

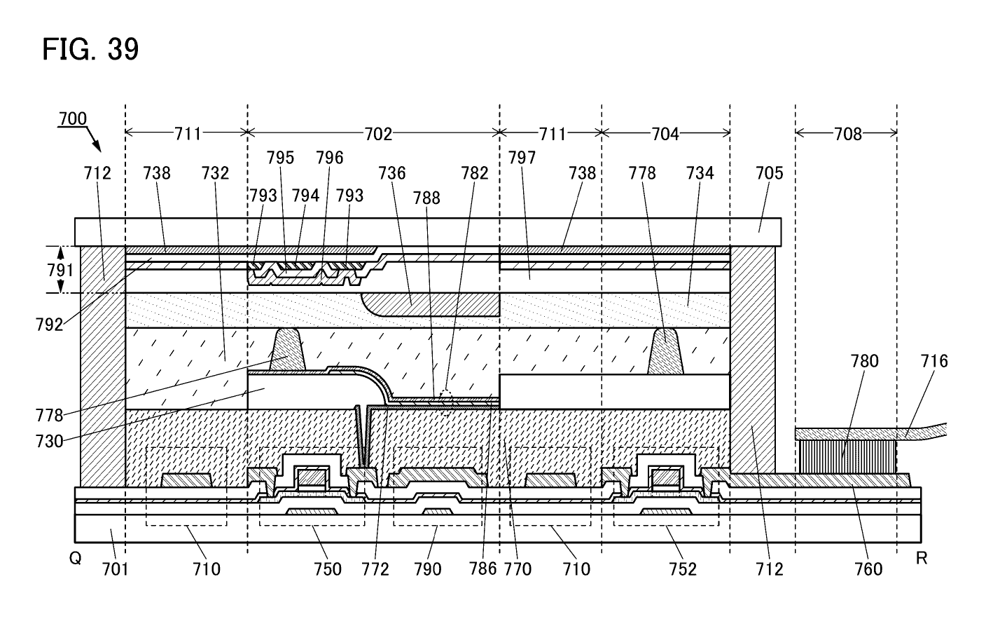

In this embodiment, an example of a display device that includes any of the transistors described in the embodiment above is described below with reference to FIG. 34, FIG. 35, FIG. 36, FIG. 37, FIG. 38, and FIG. 39.

FIG. 34 is a top view of an example of a display device. A display device 700 illustrated in FIG. 34 includes a pixel portion 702 provided over a first substrate 701; a source driver circuit portion 704 and a gate driver circuit portion 706 provided over the first substrate 701; a sealant 712 provided to surround the pixel portion 702, the source driver circuit portion 704, and the gate driver circuit portion 706; and a second substrate 705 provided to face the first substrate 701. The first substrate 701 and the second substrate 705 are sealed with the sealant 712. That is, the pixel portion 702, the source driver circuit portion 704, and the gate driver circuit portion 706 are sealed with the first substrate 701, the sealant 712, and the second substrate 705. Although not illustrated in FIG. 34, a display element is provided between the first substrate 701 and the second substrate 705.

In the display device 700, a flexible printed circuit (FPC) terminal portion 708 electrically connected to the pixel portion 702, the source driver circuit portion 704, and the gate driver circuit portion 706 is provided in a region different from the region which is surrounded by the sealant 712 and positioned over the first substrate 701. Furthermore, an FPC 716 is connected to the FPC terminal portion 708, and a variety of signals and the like are supplied to the pixel portion 702, the source driver circuit portion 704, and the gate driver circuit portion 706 through the FPC 716. Furthermore, a signal line 710 is connected to the pixel portion 702, the source driver circuit portion 704, the gate driver circuit portion 706, and the FPC terminal portion 708. The variety of signals and the like are applied to the pixel portion 702, the source driver circuit portion 704, the gate driver circuit portion 706, and the FPC terminal portion 708 via the signal line 710 from the FPC 716.

A plurality of gate driver circuit portions 706 may be provided in the display device 700. An example of the display device 700 in which the source driver circuit portion 704 and the gate driver circuit portion 706 are formed over the first substrate 701 where the pixel portion 702 is also formed is described; however, the structure is not limited thereto. For example, only the gate driver circuit portion 706 may be formed over the first substrate 701 or only the source driver circuit portion 704 may be formed over the first substrate 701. In this case, a substrate over which a source driver circuit, a gate driver circuit, or the like is formed (e.g., a driver circuit board formed using a single-crystal semiconductor film or a polycrystalline semiconductor film) may be formed on the first substrate 701. Note that there is no particular limitation on the method of connecting a separately prepared driver circuit substrate, and a chip on glass (COG) method, a wire bonding method, or the like can be used.

The pixel portion 702, the source driver circuit portion 704, and the gate driver circuit portion 706 included in the display device 700 include a plurality of transistors.

The display device 700 can include any of a variety of elements. As examples of the elements, electroluminescent (EL) element (e.g., an EL element containing organic and inorganic materials, an organic EL element, an inorganic EL element, or an LED), a light-emitting transistor element (a transistor which emits light depending on current), an electron emitter, a liquid crystal element, an electronic ink display, an electrophoretic element, an electrowetting element, a plasma display panel (PDP), a micro electro mechanical systems (MEMS) display (e.g., a grating light valve (GLV), a digital micromirror device (DMD), a digital micro shutter (DMS) element, or an interferometric modulator display (IMOD) element), and a piezoelectric ceramic display can be given.

An example of a display device including an EL element is an EL display. Examples of display devices including electron emitters are a field emission display (FED) and an SED-type flat panel display (SED: surface-conduction electron-emitter display). Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). Display devices having electronic ink or electrophoretic elements include electronic paper and the like. In the case of a transflective liquid crystal display or a reflective liquid crystal display, some of or all of pixel electrodes function as reflective electrodes. For example, some or all of pixel electrodes are formed to contain aluminum, silver, or the like. In such a case, a memory circuit such as an SRAM can be provided under the reflective electrodes. Thus, the power consumption can be further reduced.

As a display method in the display device 700, a progressive method, an interlace method, or the like can be employed. Furthermore, color elements controlled in a pixel at the time of color display are not limited to three colors: R, G, and B (R, G, and B correspond to red, green, and blue, respectively). For example, four pixels of the R pixel, the G pixel, the B pixel, and a W (white) pixel may be included. Alternatively, a color element may be composed of two colors among R, G, and B as in PenTile layout. The two colors may differ among color elements. Alternatively, one or more colors of yellow, cyan, magenta, and the like may be added to RGB. Furthermore, the size of a display region may be different depending on respective dots of the color components. Embodiments of the disclosed invention are not limited to a display device for color display; the disclosed invention can also be applied to a display device for monochrome display.

A coloring layer (also referred to as a color filter) may be used to obtain a full-color display device in which white light (W) is used for a backlight (e.g., an organic EL element, an inorganic EL element, an LED, or a fluorescent lamp). As the coloring layer, red (R), green (G), blue (B), yellow (Y), or the like may be combined as appropriate, for example. With the use of the coloring layer, higher color reproducibility can be obtained than in the case without the coloring layer. In this case, by providing a region with the coloring layer and a region without the coloring layer, white light in the region without the coloring layer may be directly utilized for display. By partly providing the region without the coloring layer, a decrease in luminance due to the coloring layer can be suppressed, and 20% to 30% of power consumption can be reduced in some cases when an image is displayed brightly. Note that in the case where full-color display is performed using a self-luminous element such as an organic EL element or an inorganic EL element, elements may emit light of their respective colors R, G, B, Y, and W. By using a self-luminous element, power consumption can be further reduced as compared to the case of using the coloring layer in some cases.

As a coloring system, any of the following systems may be used: the above-described color filter system in which part of white light is converted into red light, green light, and blue light through color filters; a three-color system in which red light, green light, and blue light are used; and a color conversion system or a quantum dot system in which part of blue light is converted into red light or green light.

In this embodiment, a structure including a liquid crystal element and an EL element as display elements is described with reference to FIG. 35, FIG. 36, and FIG. 37. Each of FIG. 35 and FIG. 36 is a cross-sectional view taken along dashed-dotted line Q-R in FIG. 34, which shows a structure including a liquid crystal element as a display element. FIG. 37 is a cross-sectional view taken along dashed-dotted line Q-R in FIG. 34, which shows a structure including an EL element as a display element.

Common portions between FIG. 35, FIG. 36, and FIG. 37 are described first, and then different portions are described.

### <4-1. Portions Common to Display Devices>

The display device 700 illustrated in each of FIG. 35, FIG. 36, and FIG. 37 includes a lead wiring portion 711, the pixel portion 702, the source driver circuit portion 704, and the FPC terminal portion 708. Note that the lead wiring portion 711 includes the signal line 710. The pixel portion 702 includes a transistor 750 and a capacitor 790. The source driver circuit portion 704 includes a transistor 752.

The transistors 750 and 752 each have a structure similar to that of the transistor 100B described above. Note that the transistor 750 and the transistor 752 may each have the structure of any of the other transistors described in the above embodiments.

The transistors used in this embodiment each include an oxide semiconductor film which is highly purified and in which formation of oxygen vacancies is suppressed. The transistor can have low off-state current. Accordingly, an electrical signal such as an image signal can be held for a longer period, and a writing interval can be set longer in an on state. Accordingly, the frequency of refresh operation can be reduced, which leads to an effect of suppressing power consumption.

In addition, the transistor used in this embodiment can have relatively high field-effect mobility and thus is capable of high-speed operation. For example, with such a transistor which can operate at high speed used for a liquid crystal display device, a switching transistor in a pixel portion and a driver transistor in a driver circuit portion can be formed over one substrate. That is, a semiconductor device formed using a silicon wafer or the like is not additionally needed as a driver circuit, by which the number of components of the semiconductor device can be reduced. In addition, the transistor which can operate at high speed can be used also in the pixel portion, whereby a high-quality image can be provided.

A capacitor 790 includes a lower electrode that is formed through a step of processing the same conductive film as a conductive film functioning as a first gate electrode of the transistor 750 and an upper electrode that is formed through a step of processing the same conductive film as a conductive film functioning as a source electrode or a drain electrode of the transistor 750. Furthermore, between the lower electrode and the upper electrode, an insulating film that is formed through a step of forming the same insulating film as an insulating film functioning as a first gate insulating film of the transistor 750 and an insulating film that is formed through a step of forming the same insulating film as an insulating film functioning as a protective insulating film of the transistor 750 are provided. That is, the capacitor 790 has a stacked-layer structure in which the insulating films functioning as a dielectric film are positioned between a pair of electrodes.

In each of FIG. 35, FIG. 36, and FIG. 37, a planarization insulating film 770 is provided over the transistor 750, the transistor 752, and the capacitor 790.

Although FIG. 35, FIG. 36, and FIG. 37 each illustrate an example in which the transistor 750 included in the pixel portion 702 and the transistor 752 included in the source driver circuit portion 704 have the same structure, one embodiment of the present invention is not limited thereto. For example, the pixel portion 702 and the source driver circuit portion 704 may include different transistors. Specifically, a structure in which a top-gate transistor is used in the pixel portion 702 and a bottom-gate transistor is used in the source driver circuit portion 704, or a structure in which a bottom-gate transistor is used in the pixel portion 702 and a top-gate transistor is used in the source driver circuit portion 704 may be employed. Note that the term “source driver circuit portion 704” can be replaced by the term “gate driver circuit portion”.

The signal line 710 is formed through the same process as the conductive films functioning as source electrodes and drain electrodes of the transistors 750 and 752. In the case where the signal line 710 is formed using a material including a copper element, signal delay or the like due to wiring resistance is reduced, which enables display on a large screen.

The FPC terminal portion 708 includes a connection electrode 760, an anisotropic conductive film 780, and the FPC 716. Note that the connection electrode 760 is formed through the same process as the conductive films functioning as source electrodes and drain electrodes of the transistors 750 and 752. The connection electrode 760 is electrically connected to a terminal included in the FPC 716 through the anisotropic conductive film 780.

For example, a glass substrate can be used as the first substrate 701 and the second substrate 705. A flexible substrate may be used as the first substrate 701 and the second substrate 705. Examples of the flexible substrate include a plastic substrate.

A structure body 778 is provided between the first substrate 701 and the second substrate 705. The structure body 778 is a columnar spacer obtained by selective etching of an insulating film and provided to control the distance (cell gap) between the first substrate 701 and the second substrate 705. Note that a spherical spacer may be used as the structure body 778.

Furthermore, a light-blocking film 738 functioning as a black matrix, a coloring film 736 functioning as a color filter, and an insulating film 734 in contact with the light-blocking film 738 and the coloring film 736 are provided on the second substrate 705 side.

### <4-2. Structure Example of Display Device Including Liquid Crystal Element>

The display device 700 illustrated in FIG. 35 includes a liquid crystal element 775. The liquid crystal element 775 includes a conductive film 772, a conductive film 774, and a liquid crystal layer 776. The conductive film 774 is provided on the second substrate 705 side and functions as a counter electrode. The display device 700 in FIG. 35 is capable of displaying an image in such a manner that transmission or non-transmission is controlled by change in the alignment state of the liquid crystal layer 776 depending on a voltage applied to the conductive film 772 and the conductive film 774.

The conductive film 772 is electrically connected to the conductive film functioning as a source electrode or a drain electrode included in the transistor 750. The conductive film 772 is formed over the planarization insulating film 770 to function as a pixel electrode, i.e., one electrode of the display element.

A conductive film that transmits visible light or a conductive film that reflects visible light can be used for the conductive film 772. For example, a material including one kind selected from indium (In), zinc (Zn), and tin (Sn) is preferably used for the conductive film that transmits visible light. For example, a material including aluminum or silver may be used for the conductive film that reflects visible light.

In the case where a conductive film that reflects visible light is used for the conductive film 772, the display device 700 is a reflective-type liquid crystal display device. Alternatively, a conductive film that transmits visible light is used for the conductive film 772, the display device 700 is a transmissive liquid crystal display device.

When a structure over the conductive film 772 is changed, a driving method of a liquid crystal element can vary. An example of this case is illustrated in FIG. 36. The display device 700 illustrated in FIG. 36 is an example of employing a transverse electric field mode (e.g., an FFS mode) as a driving mode of the liquid crystal element. In the structure illustrated in FIG. 36, an insulating film 773 is provided over the conductive film 772, and the conductive film 774 is provided over the insulating film 773. In such a structure, the conductive film 774 functions as a common electrode, and an electric field generated between the conductive film 772 and the conductive film 774 through the insulating film 773 can control the alignment state in the liquid crystal layer 776.

Although not illustrated in FIG. 35 and FIG. 36, the conductive film 772 and/or the conductive film 774 may be provided with an alignment film on a side in contact with the liquid crystal layer 776. Although not illustrated in FIG. 35 and FIG. 36, an optical member (optical substrate) or the like, such as a polarizing member, a retardation member, or an anti-reflection member, may be provided as appropriate. For example, circular polarization may be employed by using a polarizing substrate and a retardation substrate. In addition, a backlight, a side light, or the like may be used as a light source.

In the case where a liquid crystal element is used as the display element, a thermotropic liquid crystal, a low-molecular liquid crystal, a high-molecular liquid crystal, a polymer-dispersed liquid crystal, a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

Alternatively, in the case of employing a horizontal electric field mode, a liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase appears only in a narrow temperature range, a liquid crystal composition in which several weight percent or more of a chiral material is mixed is used for the liquid crystal layer in order to improve the temperature range. The liquid crystal composition which includes liquid crystal exhibiting a blue phase and a chiral material has a short response time and optical isotropy, which makes the alignment process unneeded. An alignment film does not need to be provided and rubbing treatment is thus not necessary; accordingly, electrostatic discharge damage caused by the rubbing treatment can be prevented and defects and damage of the liquid crystal display device in the manufacturing process can be reduced. Moreover, the liquid crystal material which exhibits a blue phase has a small viewing angle dependence.

In the case where a liquid crystal element is used as the display element, a twisted nematic (TN) mode, an in-plane-switching (IPS) mode, a fringe field switching (FFS) mode, an axially symmetric aligned micro-cell (ASM) mode, an optically compensated birefringence (OCB) mode, a ferroelectric liquid crystal (FLC) mode, an antiferroelectric liquid crystal (AFLC) mode, or the like can be used.

Furthermore, a normally black liquid crystal display device such as a transmissive liquid crystal display device utilizing a vertical alignment (VA) mode may also be used for the display device 700. There are some examples of a vertical alignment mode; for example, a multi-domain vertical alignment (MVA) mode, a patterned vertical alignment (PVA) mode, an ASV mode, or the like can be employed.

### <4-3. Display Device Including Light-Emitting Element>

The display device 700 illustrated in FIG. 37 includes a light-emitting element 782. The light-emitting element 782 includes a conductive film 772, an EL layer 786, and a conductive film 788. The display device 700 in FIG. 37 is capable of displaying an image by light emission from the EL layer 786 included in the light-emitting element 782. Note that the EL layer 786 contains an organic compound or an inorganic compound such as a quantum dot.

Examples of materials that can be used for an organic compound include a fluorescent material and a phosphorescent material. Examples of materials that can be used for a quantum dot include a colloidal quantum dot material, an alloyed quantum dot material, a core-shell quantum dot material, and a core quantum dot material. The quantum dot containing elements belonging to Groups 12 and 16, elements belonging to Groups 13 and 15, or elements belonging to Groups 14 and 16, may be used. Alternatively, a quantum dot material containing an element such as cadmium (Cd), selenium (Se), zinc (Zn), sulfur (S), phosphorus (P), indium (In), tellurium (Te), lead (Pb), gallium (Ga), arsenic (As), or aluminum (Al) may be used.

In the display device 700 shown in FIG. 37, an insulating film 730 is provided over the planarization insulating film 770 and the conductive film 772. The insulating film 730 covers part of the conductive film 772. Note that the light-emitting element 782 has a top emission structure. Therefore, the conductive film 788 has a light-transmitting property and transmits light emitted from the EL layer 786. Although the top-emission structure is described as an example in this embodiment, one embodiment of the present invention is not limited thereto. A bottom-emission structure in which light is emitted to the conductive film 772 side, or a dual-emission structure in which light is emitted to both the conductive film 772 side and the conductive film 788 side may be employed.

The coloring film 736 is provided to overlap with the light-emitting element 782, and the light-blocking film 738 is provided to overlap with the insulating film 730 and to be included in the lead wiring portion 711 and in the source driver circuit portion 704. The coloring film 736 and the light-blocking film 738 are covered with the insulating film 734. A space between the light-emitting element 782 and the insulating film 734 is filled with a sealing film 732. Although a structure with the coloring film 736 is described as the display device 700 in FIG. 37, the structure is not limited thereto. In the case where the EL layer 786 is formed by a separate coloring method, the coloring film 736 is not necessarily provided.

<4-4. Structure Example of Display Device Provided with Input/Output Device>

An input/output device may be provided in the display device 700 illustrated in FIG. 36 and FIG. 37. As an example of the input/output device, a touch panel or the like can be given.

FIG. 38 shows a structure in which a touch panel 791 is provided in the display device 700 in FIG. 36, and FIG. 39 shows a structure in which the touch panel 791 is provided in the display device 700 in FIG. 37.

FIG. 38 is a cross-sectional view of the structure in which the touch panel 791 is provided in the display device 700 illustrated in FIG. 36, and FIG. 39 is a cross-sectional view of the structure in which the touch panel 791 is provided in the display device 700 illustrated in FIG. 37.

First, the touch panel 791 illustrated in FIG. 38 and FIG. 39 is described below.

The touch panel 791 illustrated in FIG. 38 and FIG. 39 is what is called an in-cell touch panel provided between the second substrate 705 and the coloring film 736. The touch panel 791 is formed on the second substrate 705 side before the light-blocking film 738 and the coloring film 736 are formed.

Note that the touch panel 791 includes the light-blocking film 738, an insulating film 792, an electrode 793, an electrode 794, an insulating film 795, an electrode 796, and an insulating film 797. Changes in the mutual capacitance in the electrodes 793 and 794 can be detected when an object such as a finger or a stylus approaches, for example.

A portion in which the electrode 793 intersects with the electrode 794 is illustrated in the upper portion of the transistor 750 illustrated in FIG. 38 and FIG. 39. The electrode 796 is electrically connected to the two electrodes 793 between which the electrode 794 is sandwiched through openings provided in the insulating film 795. Note that a structure in which a region where the electrode 796 is provided is provided in the pixel portion 702 is illustrated in FIG. 38 and FIG. 39 as an example; however, one embodiment of the present invention is not limited thereto. For example, the region where the electrode 796 is provided may be provided in the source driver circuit portion 704.

The electrode 793 and the electrode 794 are provided in a region overlapping with the light-blocking film 738. As illustrated in FIG. 38, it is preferable that the electrode 793 do not overlap with the liquid crystal element 775. As illustrated in FIG. 39, it is preferable that the electrode 793 do not overlap with the light-emitting element 782. In other words, the electrode 793 has an opening in a region overlapping with the light-emitting element 782 and the liquid crystal element 775. That is, the electrode 793 has a mesh shape. With this structure, the electrode 793 does not block light emitted from the light-emitting element 782. Alternatively, the electrode 793 can have a structure in which light transmitted through the liquid crystal element 775 is not blocked. Thus, since luminance is hardly reduced even when the touch panel 791 is provided, a display device with high visibility and low power consumption can be obtained. Note that the electrode 794 can have a structure similar to that of the electrode 793.

In addition, since the electrodes 793 and 794 do not overlap with the light-emitting element 782, the electrodes 793 and 794 can be formed using a metal material with low visible light transmittance. In the case where the electrode 793 and the electrode 794 do not overlap with the liquid crystal element 775, a metal material having low transmittance with respect to visible light can be used for the electrode 793 and the electrode 794.

Thus, as compared with the case of using an oxide material whose transmittance of visible light is high, resistance of the electrodes 793 and 794 can be reduced, whereby sensitivity of the sensor of the touch panel can be increased.

For example, a conductive nanowire may be used for the electrodes 793, 794, and 796. The nanowires may have a mean diameter greater than or equal to 1 nm and less than or equal to 100 nm, preferably greater than or equal to 5 nm and less than or equal to 50 nm, further preferably greater than or equal to 5 nm and less than or equal to 25 nm. As the nanowire, a carbon nanotube or a metal nanowire such as an Ag nanowire, a Cu nanowire, or an Al nanowire may be used. For example, in the case where an Ag nanowire is used for any one of or all of the electrodes 793, 794, and 796, the transmittance of visible light can be greater than or equal to 89% and the sheet resistance can be greater than or equal to 40 Ω/square and less than or equal to 100 Ω/square.

Although the structure of the in-cell touch panel is illustrated in FIG. 38 and FIG. 39, one embodiment of the present invention is not limited thereto. For example, a touch panel formed over the display device 700, what is called an on-cell touch panel, or a touch panel attached to the display device 700, what is called an out-cell touch panel may be used.

In this manner, the display device of one embodiment of the present invention can be combined with various types of touch panels.

The structure described in this embodiment can be used in appropriate combination with the structure described in any of the other embodiments.

### Embodiment 5

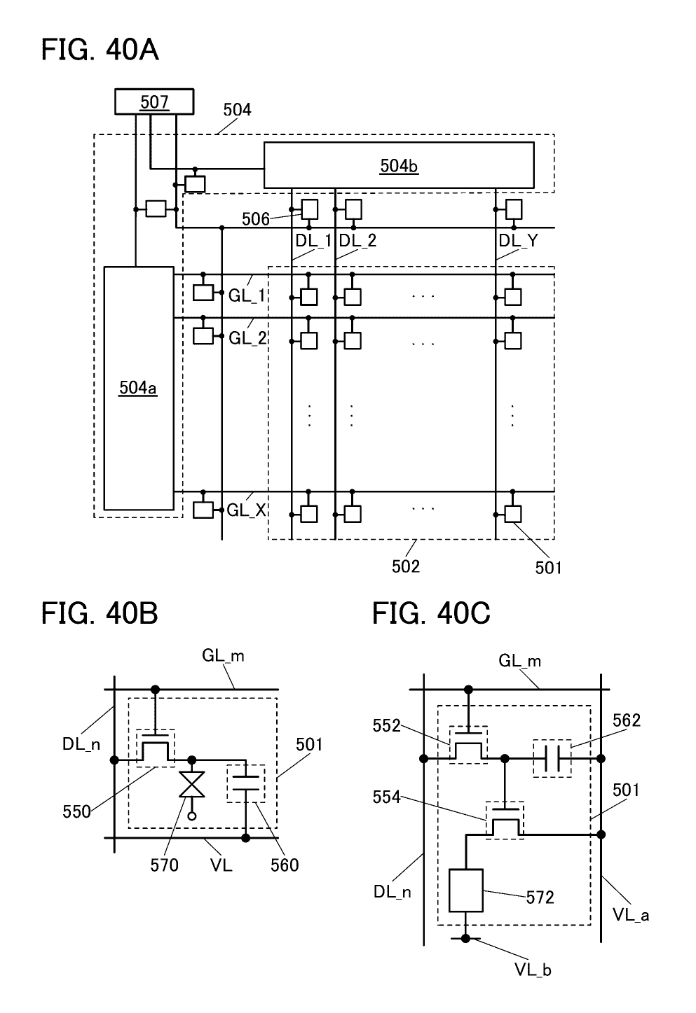

In this embodiment, a display device including a semiconductor device of one embodiment of the present invention will be described with reference to FIGS. 40A to 40C.

### <5. Circuit Configuration of Display Device>

The display device illustrated in FIG. 40A includes a region including pixels of display elements (hereinafter the region is referred to as a pixel portion 502), a circuit portion being provided outside the pixel portion 502 and including a circuit for driving the pixels (hereinafter the portion is referred to as a driver circuit portion 504), circuits each having a function of protecting an element (hereinafter the circuits are referred to as protection circuits 506), and a terminal portion 507. Note that the protection circuits 506 are not necessarily provided.

Part or the whole of the driver circuit portion 504 is preferably formed over a substrate over which the pixel portion 502 is formed. Thus, the number of components and the number of terminals can be reduced. When part or the whole of the driver circuit portion 504 is not formed over the substrate over which the pixel portion 502 is formed, the part or the whole of the driver circuit portion 504 can be mounted by COG or tape automated bonding (TAB).

The pixel portion 502 includes a plurality of circuits for driving display elements arranged in X rows (X is a natural number of 2 or more) and Y columns (Y is a natural number of 2 or more) (hereinafter, such circuits are referred to as pixel circuits 501). The driver circuit portion 504 includes driver circuits such as a circuit for supplying a signal (scan signal) to select a pixel (hereinafter, the circuit is referred to as a gate driver 504a) and a circuit for supplying a signal (data signal) to drive a display element in a pixel (hereinafter, the circuit is referred to as a source driver 504b).

The gate driver 504a includes a shift register or the like. The gate driver 504a receives a signal for driving the shift register through the terminal portion 507 and outputs a signal. For example, the gate driver 504a receives a start pulse signal, a clock signal, or the like and outputs a pulse signal. The gate driver 504a has a function of controlling the potentials of wirings supplied with scan signals (hereinafter, such wirings are referred to as scan lines GL_1 to GL_X). Note that a plurality of gate drivers 504a may be provided to control the scan lines GL_1 to GL_X separately. Alternatively, the gate driver 504a has a function of supplying an initialization signal. Without being limited thereto, the gate driver 504a can supply another signal.

The source driver 504b includes a shift register or the like. The source driver 504b receives a signal (image signal) from which a data signal is derived, as well as a signal for driving the shift register, through the terminal portion 507. The source driver 504b has a function of generating a data signal to be written to the pixel circuit 501 which is based on the image signal. In addition, the source driver 504b has a function of controlling output of a data signal in response to a pulse signal produced by input of a start pulse signal, a clock signal, or the like. Furthermore, the source driver 504b has a function of controlling the potentials of wirings supplied with data signals (hereinafter such wirings are referred to as data lines DL_1 to DL_Y). Alternatively, the source driver 504b has a function of supplying an initialization signal. Without being limited thereto, the source driver 504b can supply another signal.

The source driver 504b includes a plurality of analog switches, for example. The source driver 504b can output, as the data signals, signals obtained by time-dividing the image signal by sequentially turning on the plurality of analog switches. The source driver 504b may include a shift register or the like.

A pulse signal and a data signal are input to each of the plurality of pixel circuits 501 through one of the plurality of scan lines GL supplied with scan signals and one of the plurality of data lines DL supplied with data signals, respectively. Writing and holding of the data signal to and in each of the plurality of pixel circuits 501 are controlled by the gate driver 504a. For example, to the pixel circuit 501 in the m-th row and the n-th column (m is a natural number of less than or equal to X, and n is a natural number of less than or equal to Y), a pulse signal is input from the gate driver 504a through the scan line GL_m, and a data signal is input from the source driver 504b through the data line DL_n in accordance with the potential of the scan line GL_m.

The protection circuit 506 illustrated in FIG. 40A is connected to, for example, the scan line GL between the gate driver 504a and the pixel circuit 501. Alternatively, the protection circuit 506 is connected to the data line DL between the source driver 504b and the pixel circuit 501. Alternatively, the protection circuit 506 can be connected to a wiring between the gate driver 504a and the terminal portion 507. Alternatively, the protection circuit 506 can be connected to a wiring between the source driver 504b and the terminal portion 507. Note that the terminal portion 507 means a portion having terminals for inputting power, control signals, and image signals to the display device from external circuits.

The protection circuit 506 is a circuit that electrically connects a wiring connected to the protection circuit to another wiring when a potential out of a certain range is applied to the wiring connected to the protection circuit.

As shown in FIG. 40A, the protection circuit portions 506 are provided for the pixel portion 502 and the driver circuit portion 504, so that the resistance of the display device to overcurrent generated by electrostatic discharge (ESD) or the like can be improved. Note that the configuration of the protection circuits 506 is not limited to that, and for example, the protection circuit 506 may be configured to be connected to the gate driver 504a or the protection circuit 506 may be configured to be connected to the source driver 504b. Alternatively, the protection circuit 506 may be configured to be connected to the terminal portion 507.

In FIG. 40A, an example in which the driver circuit portion 504 includes the gate driver 504a and the source driver 504b is shown; however, the structure is not limited thereto. For example, only the gate driver 504a may be formed and a separately prepared substrate where a source driver circuit is formed (e.g., a driver circuit substrate formed with a single crystal semiconductor film or a polycrystalline semiconductor film) may be mounted.

Each of the plurality of pixel circuits 501 in FIG. 40A can have the structure illustrated in FIG. 40B, for example.

The pixel circuit 501 illustrated in FIG. 40B includes a liquid crystal element 570, a transistor 550, and a capacitor 560. As the transistor 550, any of the transistors described in the above embodiment, for example, can be used.

The potential of one of a pair of electrodes of the liquid crystal element 570 is set in accordance with the specifications of the pixel circuit 501 as appropriate. The alignment state of the liquid crystal element 570 depends on written data. A common potential may be supplied to one of the pair of electrodes of the liquid crystal element 570 included in each of the plurality of pixel circuits 501. The potential supplied to the one of the pair of electrodes of the liquid crystal element 570 in the pixel circuit 501 may differ between rows.

As examples of a driving method of the display device including the liquid crystal element 570, any of the following modes can be given: a TN mode, an STN mode, a VA mode, an axially symmetric aligned micro-cell (ASM) mode, an optically compensated birefringence (OCB) mode, a ferroelectric liquid crystal (FLC) mode, an antiferroelectric liquid crystal (AFLC) mode, an MVA mode, a patterned vertical alignment (PVA) mode, an IPS mode, an FFS mode, a transverse bend alignment (TBA) mode, and the like. Other examples of the method of driving the display device include an electrically controlled birefringence (ECB) mode, a polymer-dispersed liquid crystal (PDLC) mode, a polymer network liquid crystal (PNLC) mode, and a guest-host mode. A variety of liquid crystal elements and the driving methods thereof can be used.

In the pixel circuit 501 in the m-th row and the n-th column, one of a source electrode and a drain electrode of the transistor 550 is electrically connected to the data line DL_n, and the other is electrically connected to the other of the pair of electrodes of the liquid crystal element 570. A gate electrode of the transistor 550 is electrically connected to the scan line GL_m. The transistor 550 has a function of controlling whether to write a data signal by being turned on or off.

One of a pair of electrodes of the capacitor 560 is electrically connected to a wiring to which a potential is supplied (hereinafter referred to as a potential supply line VL), and the other is electrically connected to the other of the pair of electrodes of the liquid crystal element 570. The potential of the potential supply line VL is set in accordance with the specifications of the pixel circuit 501 as appropriate. The capacitor 560 functions as a storage capacitor for storing written data.

For example, in the display device including the pixel circuit 501 in FIG. 40B, the pixel circuits 501 are sequentially selected row by row by the gate driver 504a illustrated in FIG. 40A, whereby the transistors 550 are turned on and a data signal is written.

When the transistors 550 are turned off, the pixel circuits 501 in which the data has been written are brought into a holding state. This operation is sequentially performed row by row; thus, an image is displayed.

Alternatively, each of the plurality of pixel circuits 501 in FIG. 40A can have the structure illustrated in FIG. 40C, for example.

The pixel circuit 501 illustrated in FIG. 40C includes transistors 552 and 554, a capacitor 562, and a light-emitting element 572. Any of the transistors described in the above embodiment, for example, can be used as one or both of the transistors 552 and 554.

One of a source electrode and a drain electrode of the transistor 552 is electrically connected to a wiring to which a data signal is supplied (hereinafter referred to as a data line DL_n). A gate electrode of the transistor 552 is electrically connected to a wiring to which a gate signal is supplied (hereinafter referred to as a scan line GL_m).

The transistor 552 has a function of controlling whether to write a data signal by being turned on or off

One of a pair of electrodes of the capacitor 562 is electrically connected to a wiring to which a potential is supplied (hereinafter referred to as a potential supply line VL_a), and the other is electrically connected to the other of the source electrode and the drain electrode of the transistor 552.

The capacitor 562 functions as a storage capacitor for storing written data.

One of a source electrode and a drain electrode of the transistor 554 is electrically connected to the potential supply line VL_a. Furthermore, a gate electrode of the transistor 554 is electrically connected to the other of the source electrode and the drain electrode of the transistor 552.

One of an anode and a cathode of the light-emitting element 572 is electrically connected to a potential supply line VL_b, and the other is electrically connected to the other of the source electrode and the drain electrode of the transistor 554.

As the light-emitting element 572, an organic electroluminescent element (also referred to as an organic EL element) can be used, for example. Note that the light-emitting element 572 is not limited to an organic EL element; an inorganic EL element including an inorganic material may be used.

Note that a high power supply potential V_{DD} is supplied to one of the potential supply line VL_a and the potential supply line VL_b, and a low power supply potential V_{SS} is supplied to the other.

For example, in the display device including the pixel circuit 501 in FIG. 40C, the pixel circuits 501 are sequentially selected row by row by the gate driver 504a illustrated in FIG. 40A, whereby the transistors 552 are turned on and a data signal is written.

When the transistors 552 are turned off, the pixel circuits 501 in which the data has been written are brought into a holding state. Furthermore, the amount of current flowing between the source electrode and the drain electrode of the transistor 554 is controlled in accordance with the potential of the written data signal. The light-emitting element 572 emits light with luminance corresponding to the amount of flowing current. This operation is sequentially performed row by row; thus, an image is displayed.

The structure described in this embodiment can be used in appropriate combination with the structure described in any of the other embodiments.

### Embodiment 6

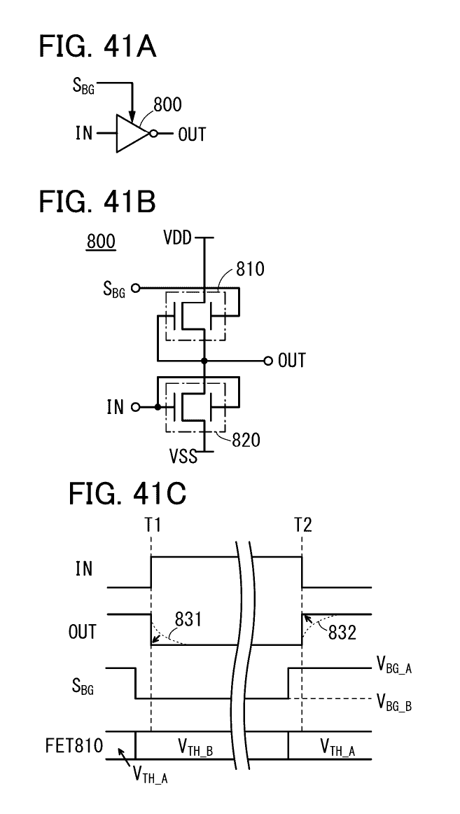

In this embodiment, circuit configuration examples to which the transistors described in the above embodiments can be applied will be described with reference to FIGS. 41A to 41C, FIGS. 42A to 42C, FIGS. 43A and 43B, and FIGS. 44A and 44B.

Note that in this embodiment, the transistor including an oxide semiconductor described in the above embodiment is referred to as an OS transistor in the following description.

### <6. Configuration Example of Inverter Circuit>

FIG. 41A is a circuit diagram of an inverter which can be used for a shift register, a buffer, or the like included in the driver circuit. An inverter 800 outputs a signal whose logic is inverted from the logic of a signal supplied to an input terminal IN to an output terminal OUT. The inverter 800 includes a plurality of OS transistors. A signal S_{BG} can switch electrical characteristics of the OS transistors.

FIG. 41B illustrates an example of the inverter 800. The inverter 800 includes OS transistors 810 and 820. The inverter 800 can be formed using only n-channel transistors; thus, the inverter 800 can be formed at lower cost than an inverter formed using a complementary metal oxide semiconductor (i.e., a CMOS inverter).

Note that the inverter 800 including the OS transistors can be provided over a CMOS circuit including Si transistors. Since the inverter 800 can be provided so as to overlap with the CMOS circuit, no additional area is required for the inverter 800, and thus, an increase in the circuit area can be suppressed.

Each of the OS transistors 810 and 820 includes a first gate functioning as a front gate, a second gate functioning as a back gate, a first terminal functioning as one of a source and a drain, and a second terminal functioning as the other of the source and the drain.

The first gate of the OS transistor 810 is connected to its second terminal. The second gate of the OS transistor 810 is connected to a wiring that supplies the signal S_{BG}. The first terminal of the OS transistor 810 is connected to a wiring which supplies a voltage V_{DD}. The second terminal of the OS transistor 810 is connected to the output terminal OUT.

The first gate of the OS transistor 820 is connected to the input terminal IN. The second gate of the OS transistor 820 is connected to the input terminal IN. The first terminal of the OS transistor 820 is connected to the output terminal OUT. The second terminal of the OS transistor 820 is connected to a wiring which supplies a voltage V_{SS}.

FIG. 41C is a timing chart illustrating the operation of the inverter 800. The timing chart in FIG. 41C illustrates changes of a signal waveform of the input terminal IN, a signal waveform of the output terminal OUT, a signal waveform of the signal S_{BG}, and the threshold voltage of the OS transistor 810.

The signal S_{BG} can be supplied to the second gate of the OS transistor 810 to control the threshold voltage of the OS transistor 810.

The signal S_{BG} includes a voltage V_{BG}_{_}_{A} for shifting the threshold voltage in the negative direction and a voltage V_{BG}_{_}_{B} for shifting the threshold voltage in the positive direction. The threshold voltage of the OS transistor 810 can be shifted in the negative direction to be a threshold voltage V_{TH}_{_}_{A} when the voltage V_{BG}_{_}_{A} is applied to the second gate. The threshold voltage of the OS transistor 810 can be shifted in the positive direction to be a threshold voltage V_{TH}_{_}_{B} when the voltage V_{BG}_{_}_{B} is applied to the second gate.

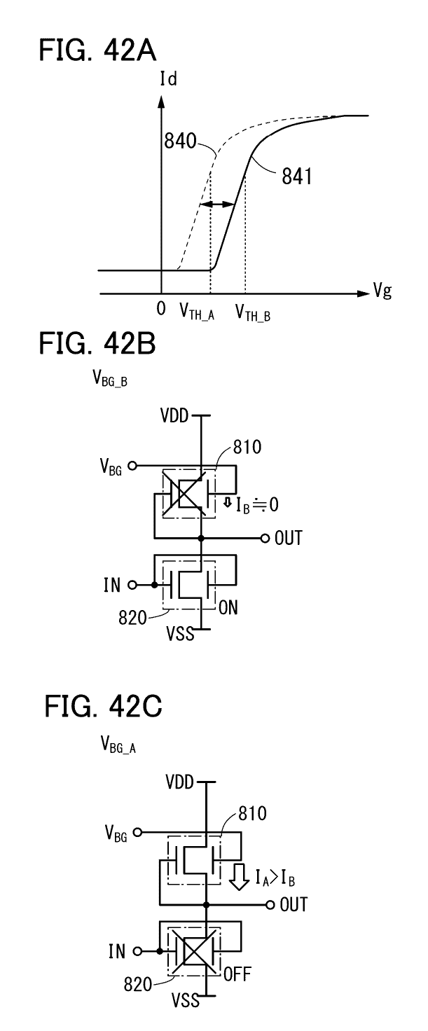

To visualize the above description, FIG. 42A shows an I_{d}-V_{g} curve, which is one of the electrical characteristics of a transistor.

When a high voltage such as the voltage V_{BG}_{_}_{A} is applied to the second gate, the electrical characteristics of the OS transistor 810 can be shifted to match a curve shown by a dashed line 840 in FIG. 42A. When a low voltage such as the voltage V_{BG}_{_}_{B} is applied to the second gate, the electrical characteristics of the OS transistor 810 can be shifted to match a curve shown by a solid line 841 in FIG. 42A. As shown in FIG. 42A, switching the signal S_{BG} between the voltage V_{BG}_{_}_{A} and the voltage V_{BG}_{_}_{B} enables the threshold voltage of the OS transistor 810 to be shifted in the positive direction or the negative direction.

The shift of the threshold voltage in the positive direction toward the threshold voltage V_{TH}_{_}_{B} can make current less likely to flow in the OS transistor 810. FIG. 42B visualizes the state.

As illustrated in FIG. 42B, a current I_{B} that flows in the OS transistor 810 can be extremely low. Thus, when a signal supplied to the input terminal IN is at a high level and the OS transistor 820 is on (ON), the voltage of the output terminal OUT can drop sharply.

Since a state in which current is less likely to flow in the OS transistor 810 as illustrated in FIG. 42B can be obtained, a signal waveform 831 of the output terminal in the timing chart in FIG. 41C can be made steep. Shoot-through current between the wiring that supplies the voltage V_{DD} and the wiring that supplies the voltage V_{DD} can be low, leading to low-power operation.

The shift of the threshold voltage in the negative direction toward the threshold voltage V_{TH}_{_}_{A} can make current flow easily in the OS transistor 810. FIG. 42C visualizes the state. As illustrated in FIG. 42C, a current I_{A} flowing at this time can be higher than at least the current I_{B}. Thus, when a signal supplied to the input terminal IN is at a low level and the OS transistor 820 is off (OFF), the voltage of the output terminal OUT can be increased sharply. Since a state in which current is likely to flow in the OS transistor 810 as illustrated in FIG. 42C can be obtained, a signal waveform 832 of the output terminal in the timing chart in FIG. 41C can be made steep.

Note that the threshold voltage of the OS transistor 810 is preferably controlled by the signal S_{BG} before the state of the OS transistor 820 is switched, i.e., before time T1 or T2. For example, as in FIG. 41C, it is preferable that the threshold voltage of the OS transistor 810 be switched from the threshold voltage V_{TH}_{_}_{A} to the threshold voltage V_{TH}_{_}_{B} before time T1 at which the level of the signal supplied to the input terminal IN is switched to a high level. Moreover, as in FIG. 41C, it is preferable that the threshold voltage of the OS transistor 810 be switched from the threshold voltage V_{TH}_{_}_{B} to the threshold voltage V_{TH}_{_}_{A} before time T2 at which the level of the signal supplied to the input terminal IN is switched to a low level.

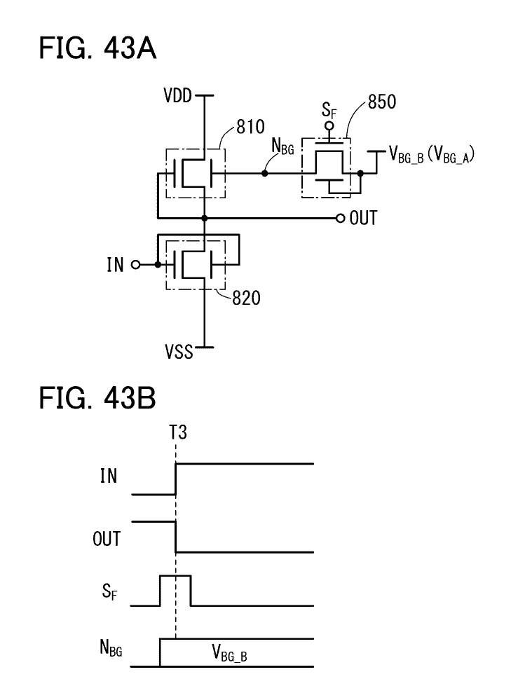

Although the timing chart in FIG. 41C illustrates the structure in which the level of the signal S_{BG} is switched in accordance with the signal supplied to the input terminal IN, a different structure may be employed in which voltage for controlling the threshold voltage is held by the second gate of the OS transistor 810 in a floating state, for example. This can be achieved with a circuit configuration in FIG. 43A which is illustrated as an example.

The circuit configuration in FIG. 43A is the same as that in FIG. 41B, except that an OS transistor 850 is added. A first terminal of the OS transistor 850 is connected to the second gate of the OS transistor 810. A second terminal of the OS transistor 850 is connected to a wiring which supplies the voltage V_{BG}_{_}_{B} (or the voltage V_{BG}_{_}_{A}). A first gate of the OS transistor 850 is connected to a wiring which supplies a signal S_{F}. A second gate of the OS transistor 850 is connected to the wiring which supplies the voltage V_{BG}_{_}_{B} (or the voltage V_{BG}_{_}_{A}).

The operation with the circuit configuration in FIG. 43A is described with reference to a timing chart in FIG. 43B.

The voltage for controlling the threshold voltage of the OS transistor 810 is supplied to the second gate of the OS transistor 810 before time T3 at which the level of the signal supplied to the input terminal IN is changed to a high level. The signal S_{F} is set to a high level and the OS transistor 850 is turned on, so that the voltage V_{BG}_{_}_{B} for controlling the threshold voltage is supplied to a node N_{BG}.

The OS transistor 850 is turned off after the voltage of the node N_{BG} becomes V_{BG}_{_}_{B}. The off-state current of the OS transistor 850 is extremely low and thus, when the OS transistor 850 is kept in an off-state, the voltage V_{BG}_{_}_{B} which is temporarily held in the node N_{BG} can be kept retained. Therefore, the number of times of operation of supplying the voltage V_{BG}_{_}_{B} to the second gate of the OS transistor 850 can be reduced and accordingly the power consumed to rewrite the voltage V_{BG}_{_}_{B} can be reduced.

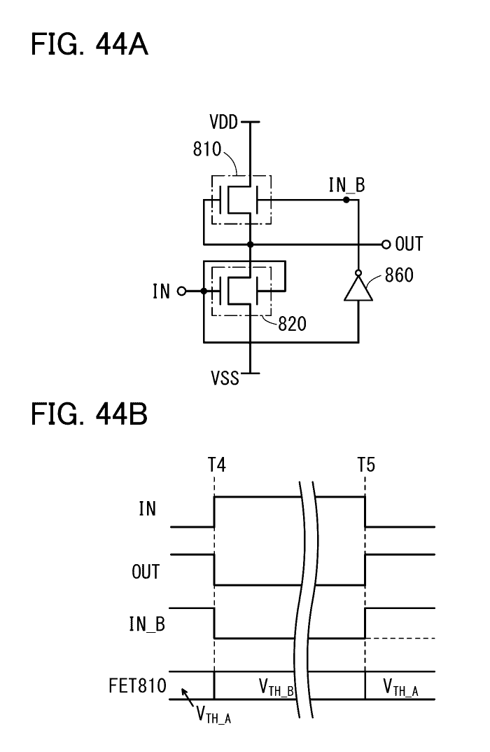

Although FIG. 41B and FIG. 43A each illustrate the case where the voltage is supplied to the second gate of the OS transistor 810 by control from the outside, a different structure may be employed in which voltage for controlling the threshold voltage is generated on the basis of the signal supplied to the input terminal IN and supplied to the second gate of the OS transistor 810, for example. FIG. 44A shows an example of such a circuit structure.

The circuit configuration in FIG. 44A is the same as that in FIG. 41B, except that a CMOS inverter 860 is provided between the input terminal IN and the second gate of the OS transistor 810. An input terminal of the CMOS inverter 860 is connected to the input terminal IN. An output terminal of the CMOS inverter 860 is connected to the second gate of the OS transistor 810.

The operation with the circuit configuration in FIG. 44A is described with reference to the timing chart in FIG. 44B. The timing chart in FIG. 44B illustrates changes of a signal waveform of the input terminal IN, a signal waveform of the output terminal OUT, an output waveform IN_B of the CMOS inverter 860, and a threshold voltage of the OS transistor 810.

The output waveform IN_B which corresponds to a signal whose logic is inverted from the logic of the signal supplied to the input terminal IN can be used as a signal that controls the threshold voltage of the OS transistor 810. Therefore, the threshold voltage of the OS transistor 810 can be controlled as described with reference to FIGS. 42A to 42C. For example, the signal supplied to the input terminal IN is at a high level and the OS transistor 820 is turned on at time T4 in FIG. 44B. At this time, the output waveform IN_B is at a low level. Accordingly, current can be made less likely to flow in the OS transistor 810; thus, the voltage of the output terminal OUT can be sharply decreased.

Moreover, the signal supplied to the input terminal IN is at a low level and the OS transistor 820 is turned off at time T5 in FIG. 44B. At this time, the output waveform IN_B is at a high level. Accordingly, current can easily flow in the OS transistor 810; thus, a rise in the voltage of the output terminal OUT can be made steep.

As described above, in the structure of the inverter including the OS transistor in this embodiment, the voltage of the back gate is switched in accordance with the logic of the signal supplied to the input terminal IN. In such a structure, the threshold voltage of the OS transistor can be controlled. The control of the threshold voltage of the OS transistor by the signal supplied to the input terminal IN can cause a steep change in the voltage of the output terminal OUT. Moreover, shoot-through current between the wirings that supply power supply voltages can be reduced. Thus, power consumption can be reduced.

The structure described in this embodiment can be used in appropriate combination with the structure described in any of the other embodiments.

### Embodiment 7

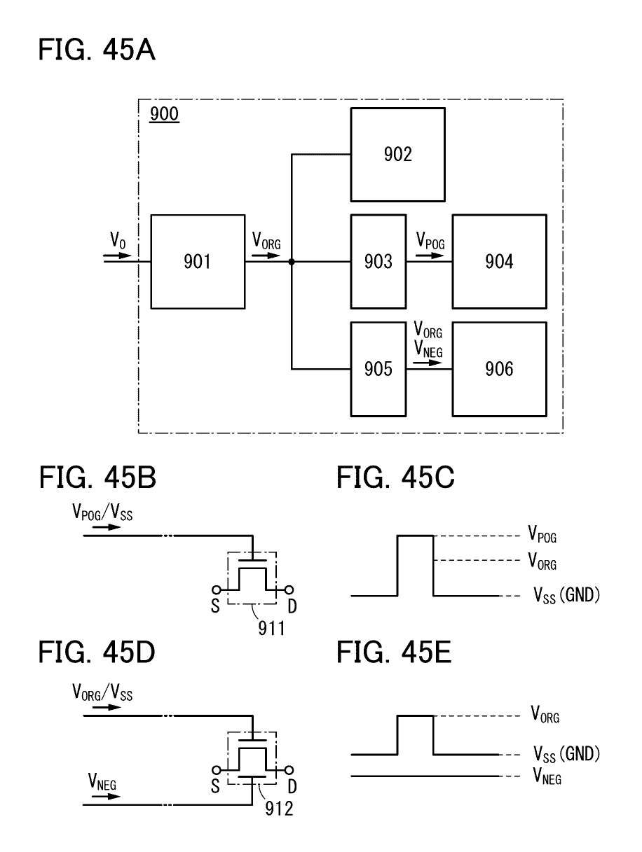

In this embodiment, examples of a semiconductor device in which the transistor including an oxide semiconductor (OS transistor) described in any of the above embodiments is used in a plurality of circuits will be described with reference to FIGS. 45A to 45E, FIGS. 46A and 46B, FIGS. 47A and 47B, and FIGS. 48A to 48C.

### <7. Circuit Configuration Example of Semiconductor Device>

FIG. 45A is a block diagram of a semiconductor device 900. The semiconductor device 900 includes a power supply circuit 901, a circuit 902, a voltage generation circuit 903, a circuit 904, a voltage generation circuit 905, and a circuit 906.

The power supply circuit 901 is a circuit that generates a voltage V_{ORG} used as a reference. The voltage V_{ORG} is not necessarily one voltage and can be a plurality of voltages. The voltage V_{ORG} can be generated on the basis of a voltage V₀ supplied from the outside of the semiconductor device 900. The semiconductor device 900 can generate the voltage V_{ORG} on the basis of one power supply voltage supplied from the outside. Thus, the semiconductor device 900 can operate without supply of a plurality of power supply voltages from the outside.

The circuits 902, 904, and 906 operate with different power supply voltages. For example, the power supply voltage of the circuit 902 is a voltage applied on the basis of the voltage V_{ORG} and the voltage V_{SS} (V_{ORG}>V_{SS}). For example, the power supply voltage of the circuit 904 is a voltage applied on the basis of a voltage V_{POG} and the voltage V_{SS} (V_{POG}>V_{ORG}). For example, the power supply voltages of the circuit 906 are voltages applied on the basis of the voltage V_{ORG}, the voltage V_{SS}, and a voltage V_{NEG} (V_{ORG}>V_{SS}>V_{NEG}). When the voltage V_{SS} is equal to a ground potential (GND), the kinds of voltages generated in the power supply circuit 901 can be reduced.

The voltage generation circuit 903 is a circuit that generates the voltage V_{POG}. The voltage generation circuit 903 can generate the voltage V_{POG} on the basis of the voltage V_{ORG} supplied from the power supply circuit 901. Thus, the semiconductor device 900 including the circuit 904 can operate on the basis of one power supply voltage supplied from the outside.

The voltage generation circuit 905 is a circuit that generates the voltage V_{NEG}. The voltage generation circuit 905 can generate the voltage V_{NEG} on the basis of the voltage V_{ORG} supplied from the power supply circuit 901. Thus, the semiconductor device 900 including the circuit 906 can operate on the basis of one power supply voltage supplied from the outside.

FIG. 45B shows an example of the circuit 904 that operates with the voltage V_{POG} and FIG. 45C illustrates an example of a waveform of a signal for operating the circuit 904.

FIG. 45B shows a transistor 911. A signal supplied to a gate of the transistor 911 is generated on the basis of, for example, the voltage V_{POG} and the voltage V_{SS}. The signal is generated on the basis of the voltage V_{POG} to turn on the transistor 911 and on the basis of the voltage V_{SS} to turn off the transistor 911. As shown in FIG. 45C, the voltage V_{POG} is higher than the voltage V_{ORG}. Therefore, an operation for bringing a source (S) and a drain (D) of the transistor 911 into a conduction state can be performed more surely. As a result, the frequency of malfunction of the circuit 904 can be reduced.

FIG. 45D shows an example of the circuit 906 that operates with the voltage V_{NEG} and FIG. 45E shows an example of a waveform of a signal for operating the circuit 906.

FIG. 45D shows a transistor 912 having a back gate. A signal supplied to a gate of the transistor 912 is generated on the basis of, for example, the voltage V_{ORG} and the voltage V_{SS}. The signal is generated on the basis of the voltage V_{ORG} to turn on the transistor 911 and on the basis of the voltage V_{SS} to turn off the transistor 911. A signal supplied to a back gate of the transistor 912 is generated on the basis of the voltage V_{NEG}. As shown in FIG. 45E, the voltage V_{NEG} is lower than the voltage V_{SS} (GND). Thus, the threshold voltage of the transistor 912 can be controlled to shift in the positive direction. Thus, the transistor 912 can be surely turned off and the amount of current flowing between the source (S) and the drain (D) can be small. As a result, the frequency of malfunction of the circuit 906 can be reduced and the power consumption thereof can be reduced.

The voltage V_{NEG} may be directly supplied to the back gate of the transistor 912. Alternatively, a signal supplied to the gate of the transistor 912 may be generated on the basis of the voltage V_{ORG} and the voltage V_{NEG} and the generated signal may also be supplied to the back gate of the transistor 912.

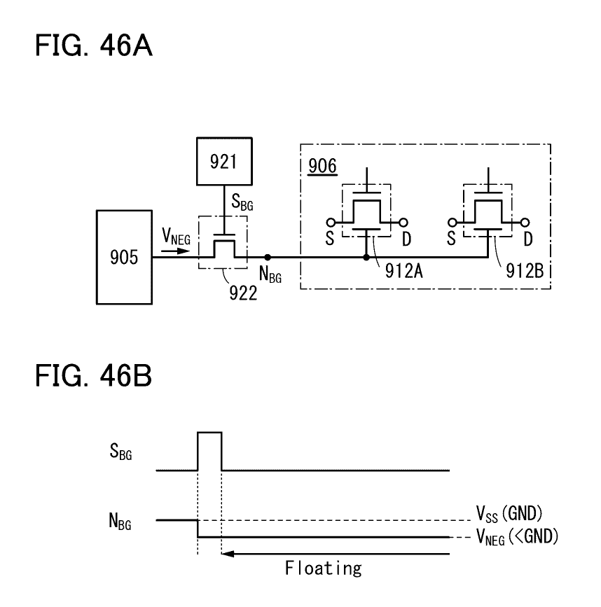

FIGS. 46A and 46B illustrate a modification example of FIGS. 45D and 45E.

In a circuit diagram illustrated in FIG. 46A, a transistor 922 whose conduction state can be controlled by a control circuit 921 is provided between the voltage generation circuit 905 and the circuit 906. The transistor 922 is an n-channel OS transistor. A control signal S_{BG} outputted from the control circuit 921 is a signal for controlling the conduction state of the transistor 922. Transistors 912A and 912B included in the circuit 906 are OS transistors like the transistor 922.

A timing chart in FIG. 46B shows changes in the potential of the control signal S_{BG} and the potential of a node N_{BG}. The potential of the node N_{BG} indicates the states of potentials of back gates of the transistors 912A and 912B. When the control signal S_{BG} is at a high level, the transistor 922 is turned on and the voltage of the node N_{BG} becomes the voltage V_{NEG}. Then, when the control signal S_{BG} is at a low level, the node N_{BG} is brought into an electrically floating state. Since the transistor 922 is an OS transistor, its off-state current is low. Accordingly, even when the node N_{BG} is in an electrically floating state, the voltage V_{NEG} which has been supplied can be held.

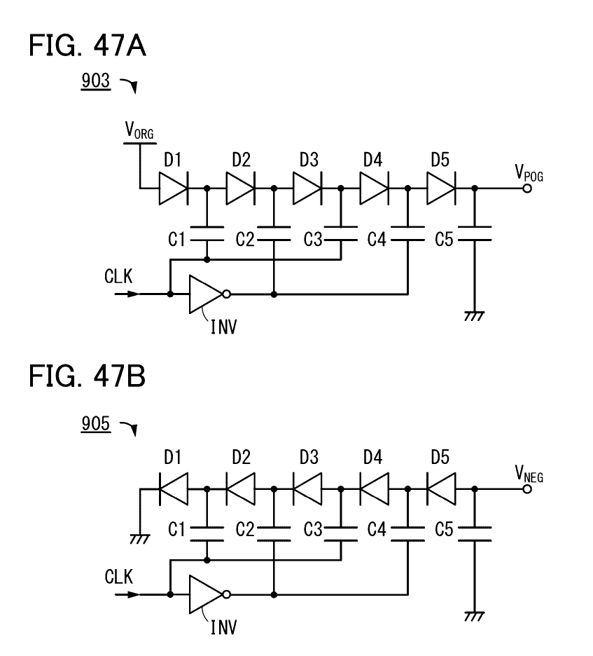

FIG. 47A shows an example of a circuit configuration applicable to the above-described voltage generation circuit 903. The voltage generation circuit 903 shown in FIG. 47A is a five-stage charge pump including diodes D1 to D5, capacitors C1 to C5, and an inverter INV. A clock signal CLK is supplied to the capacitors C1 to C5 directly or through the inverter INV. When a power supply voltage of the inverter INV is a voltage applied on the basis of the voltage V_{ORG} and the voltage V_{SS}, in response to the application of the clock signal CLK, the voltage V_{POG} can be obtained by increasing the voltage V_{ORG} by a voltage five times a potential difference between the voltage V_{ORG} and the voltage V_{SS}. Note that a forward voltage of the diodes D1 to D5 is 0 V. A desired voltage V_{POG} can be obtained when the number of stages of the charge pump is changed.

FIG. 47B illustrates an example of a circuit configuration applicable to the above-described voltage generation circuit 905. The voltage generation circuit 905 shown in FIG. 47B is a four-stage charge pump including the diodes D1 to D5, the capacitors C1 to C5, and the inverter INV. A clock signal CLK is supplied to the capacitors C1 to C5 directly or through the inverter INV. When a power supply voltage of the inverter INV is a voltage applied on the basis of the voltage V_{ORG} and the voltage V_{SS}, the voltage V_{NEG} can be obtained by decreasing the ground voltage, i.e., the voltage V_{SS} by a voltage four times the potential difference between the voltage V_{ORG} and the voltage V_{SS} with the application of the clock signal CLK. Note that a forward voltage of the diodes D1 to D5 is 0 V. A desired voltage V_{NEG} can be obtained when the number of stages of the charge pump is changed.

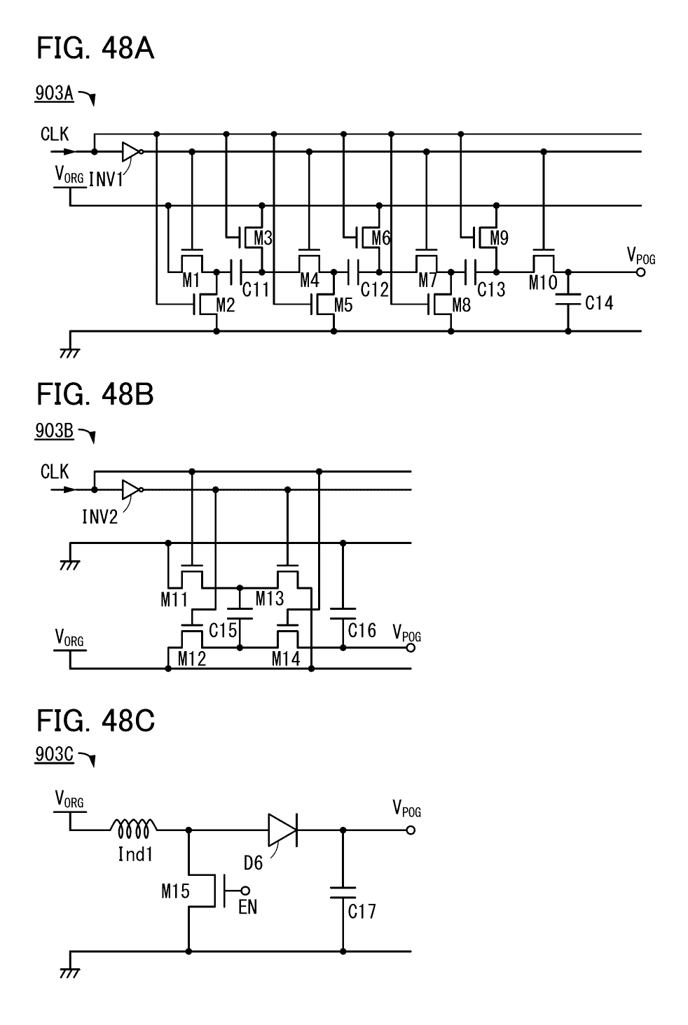

The circuit structure of the voltage generation circuit 903 is not limited to the structure of the circuit diagram shown in FIG. 47A. Modification examples of the voltage generation circuit 903 are shown in FIGS. 48A to 48C. Note that further modification examples of the voltage generation circuit 903 can be realized by changing voltages supplied to wirings or arrangement of elements in voltage generation circuits 903A to 903C shown in FIGS. 48A to 48C.

The voltage generation circuit 903A shown in FIG. 48A includes transistors M1 to M10, capacitors C11 to C14, and an inverter INV1. The clock signal CLK is supplied to gates of the transistors M1 to M10 directly or through the inverter INV1. The voltage V_{POG} can be obtained by increasing the voltage V_{ORG} by a voltage four times the potential difference between the voltage V_{ORG} and the voltage V_{SS} with the application of the clock signal CLK. A desired voltage V_{POG} can be obtained when the number of stages is changed. In the voltage generation circuit 903A in FIG. 48A, off-state current of each of the transistors M1 to M10 can be low when the transistors M1 to M10 are OS transistors, and leakage of charge held in the capacitors C11 to C14 can be suppressed. Accordingly, raising from the voltage V_{ORG} to the voltage V_{POG} can be efficiently performed.

The voltage generation circuit 903B shown in FIG. 48B includes transistors M11 to M14, capacitors C15 and C16, and an inverter INV2. The clock signal CLK is supplied to gates of the transistors M11 to M14 directly or through the inverter INV2. By application of the clock signal CLK, the voltage V_{POG}, which has been increased to a positive voltage having a positively doubled value of the voltage V_{ORG}, can be obtained. In the voltage generation circuit 903B in FIG. 48B, off-state current of each of the transistors M11 to M14 can be low when the transistors M11 to M14 are OS transistors, and leakage of charge held in the capacitors C15 and C16 can be suppressed. Accordingly, raising from the voltage V_{ORG} to the voltage V_{POG} can be efficiently performed.

A voltage generation circuit 903C shown in FIG. 48C includes an inductor Ind1, a transistor M15, a diode D6, and a capacitor C17. The conduction state of the transistor M15 is controlled by a control signal EN. Owing to the control signal EN, the voltage V_{POG} which is obtained by increasing the voltage V_{ORG} can be obtained. Since the voltage generation circuit 903C in FIG. 48C increases the voltage using the inductor Ind1, the voltage can be efficiently increased.

As described above, in any of the structures of this embodiment, a voltage required for circuits included in a semiconductor device can be internally generated. Thus, in the semiconductor device, the number of power supply voltages supplied from the outside can be reduced.

The structures and the like described in this embodiment can be combined as appropriate with any of the structures described in the other embodiments.

### Embodiment 8

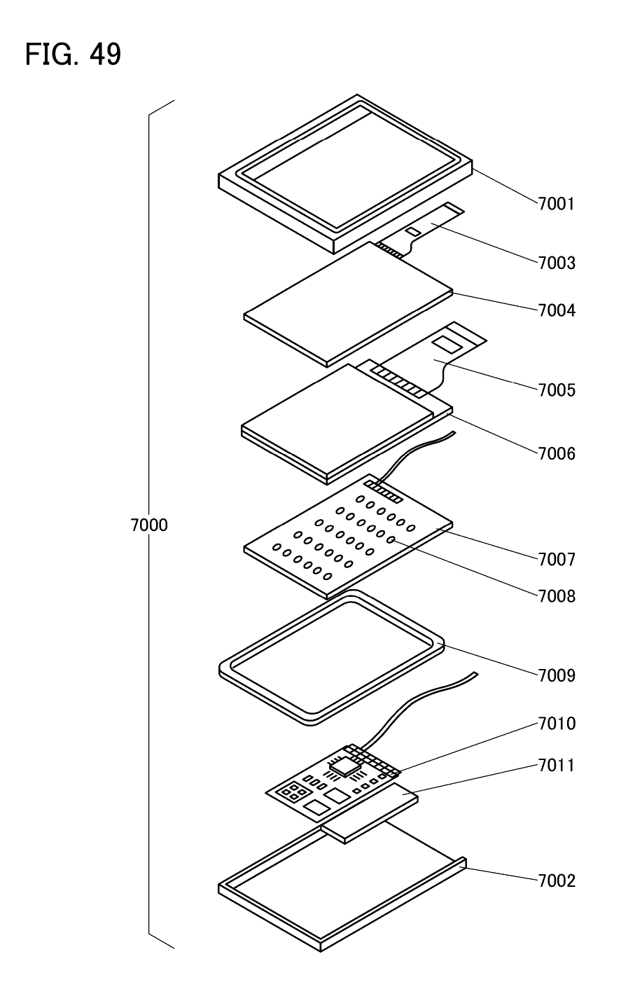

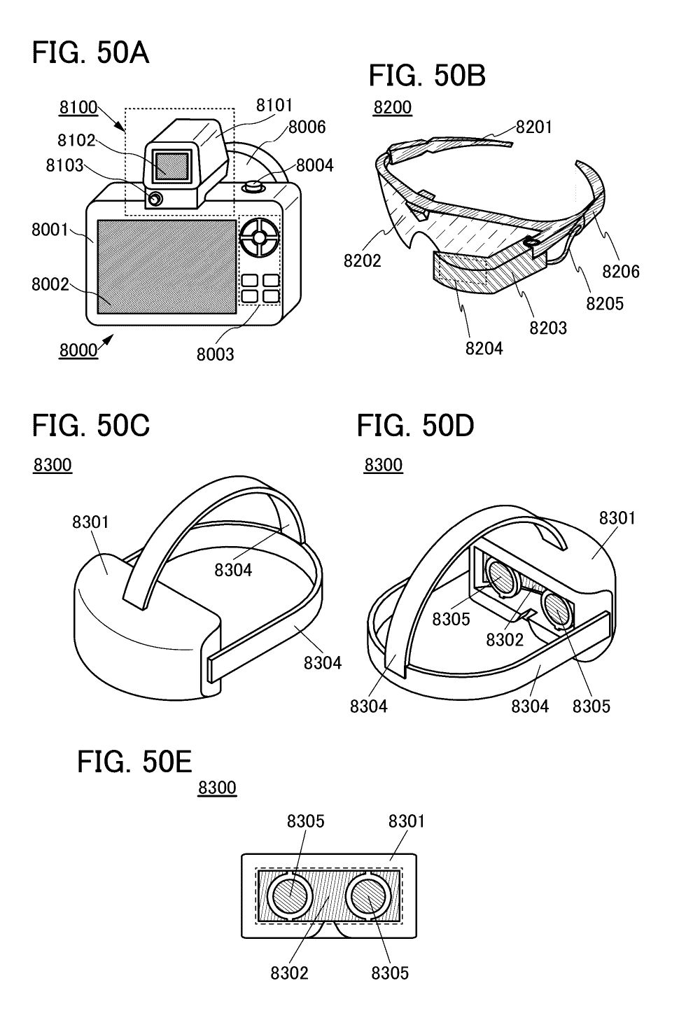

In this embodiment, a display module and electronic devices, each of which includes a semiconductor device of one embodiment of the present invention, will be described with reference to FIG. 49, FIGS. 50A to 50E, FIGS. 51A to 51G, and FIGS. 52A and 52B.

### <8-1. Display Module>

In a display module 7000 illustrated in FIG. 49, a touch panel 7004 connected to an FPC 7003, a display panel 7006 connected to an FPC 7005, a backlight 7007, a frame 7009, a printed board 7010, and a battery 7011 are provided between an upper cover 7001 and a lower cover 7002.

The semiconductor device of one embodiment of the present invention can be used for the display panel 7006, for example.

The shapes and sizes of the upper cover 7001 and the lower cover 7002 can be changed as appropriate in accordance with the sizes of the touch panel 7004 and the display panel 7006.

The touch panel 7004 can be a resistive touch panel or a capacitive touch panel and overlap with the display panel 7006. Alternatively, a counter substrate (sealing substrate) of the display panel 7006 can have a touch panel function. Alternatively, a photosensor may be provided in each pixel of the display panel 7006 to form an optical touch panel.

The backlight 7007 includes a light source 7008. One embodiment of the present invention is not limited to the structure in FIG. 49, in which the light source 7008 is provided over the backlight 7007. For example, a structure in which the light source 7008 is provided at an end portion of the backlight 7007 and a light diffusion plate is further provided may be employed. Note that the backlight 7007 need not be provided in the case where a self-luminous light-emitting element such as an organic EL element is used or in the case where a reflective panel or the like is employed.

The frame 7009 protects the display panel 7006 and functions as an electromagnetic shield for blocking electromagnetic waves generated by the operation of the printed board 7010. The frame 7009 may also function as a radiator plate.

The printed board 7010 includes a power supply circuit and a signal processing circuit for outputting a video signal and a clock signal. As a power source for supplying power to the power supply circuit, an external commercial power source or the separate battery 7011 may be used. The battery 7011 can be omitted in the case where a commercial power source is used.

The display module 7000 may be additionally provided with a member such as a polarizing plate, a retardation plate, or a prism sheet.

### <8-2. Electronic Device 1>

Next, FIGS. 50A to 50E illustrate examples of electronic devices.

FIG. 50A is an external view of a camera 8000 to which a finder 8100 is attached.

The camera 8000 includes a housing 8001, a display portion 8002, an operation button 8003, a shutter button 8004, and the like. Furthermore, an attachable lens 8006 is attached to the camera 8000.

Although the lens 8006 of the camera 8000 here is detachable from the housing 8001 for replacement, the lens 8006 may be included in the housing 8001.

Images can be taken with the camera 8000 at the press of the shutter button 8004. In addition, images can be taken at the touch of the display portion 8002 which serves as a touch panel.

The housing 8001 of the camera 8000 includes a mount including an electrode, so that the finder 8100, a stroboscope, or the like can be connected to the housing 8001.

The finder 8100 includes a housing 8101, a display portion 8102, a button 8103, and the like.

The housing 8101 includes a mount for engagement with the mount of the camera 8000 so that the finder 8100 can be connected to the camera 8000. The mount includes an electrode, and an image or the like received from the camera 8000 through the electrode can be displayed on the display portion 8102.

The button 8103 serves as a power button. The on/off state of the display portion 8102 can be turned on and off with the button 8103.

A display device of one embodiment of the present invention can be used in the display portion 8002 of the camera 8000 and the display portion 8102 of the finder 8100.

Although the camera 8000 and the finder 8100 are separate and detachable electronic devices in FIG. 50A, the housing 8001 of the camera 8000 may include a finder having a display device of one embodiment of the present invention.

FIG. 50B is an external view of a head-mounted display 8200.

The head-mounted display 8200 includes a mounting portion 8201, a lens 8202, a main body 8203, a display portion 8204, a cable 8205, and the like. The mounting portion 8201 includes a battery 8206.

Power is supplied from the battery 8206 to the main body 8203 through the cable 8205. The main body 8203 includes a wireless receiver or the like to receive video data, such as image data, and display it on the display portion 8204. The movement of the eyeball and the eyelid of a user is captured by a camera in the main body 8203 and then coordinates of the points the user looks at are calculated using the captured data to utilize the eye of the user as an input means.

The mounting portion 8201 may include a plurality of electrodes so as to be in contact with the user. The main body 8203 may be configured to sense current flowing through the electrodes with the movement of the user's eyeball to recognize the direction of his or her eyes. The main body 8203 may be configured to sense current flowing through the electrodes to monitor the user's pulse. The mounting portion 8201 may include sensors, such as a temperature sensor, a pressure sensor, or an acceleration sensor so that the user's biological information can be displayed on the display portion 8204. The main body 8203 may be configured to sense the movement of the user's head or the like to move an image displayed on the display portion 8204 in synchronization with the movement of the user's head or the like.

The display device of one embodiment of the present invention can be used in the display portion 8204.

FIGS. 50C to 50E are external views of a head-mounted display 8300. The head-mounted display 8300 includes a housing 8301, a display portion 8302, fixing bands 8304, and a pair of lenses 8305.

A user can see a display on the display portion 8302 through the lenses 8305. The display portion 8302 can be curved. With an arrangement of the curved display portion 8302, the user can feel a highly realistic sensation. Although a structure in which one display portion 8302 is provided is shown in this embodiment, the structure is not limited thereto, and two display portions 8302 may be provided, for example. In this case, if one display portion is assigned to one eye of the user, three-dimensional display utilizing parallax or the like can be achieved.

The display device of one embodiment of the present invention can be used in the display portion 8302. The display device including the semiconductor device of one embodiment of the present invention has an extremely high resolution; thus, even when an image displayed on the display portion 8302 is magnified using the lenses 8305 as illustrated in FIG. 50E, the user does not perceive pixels, and thus a more realistic image can be displayed.

### <8-3. Electronic Device 2>

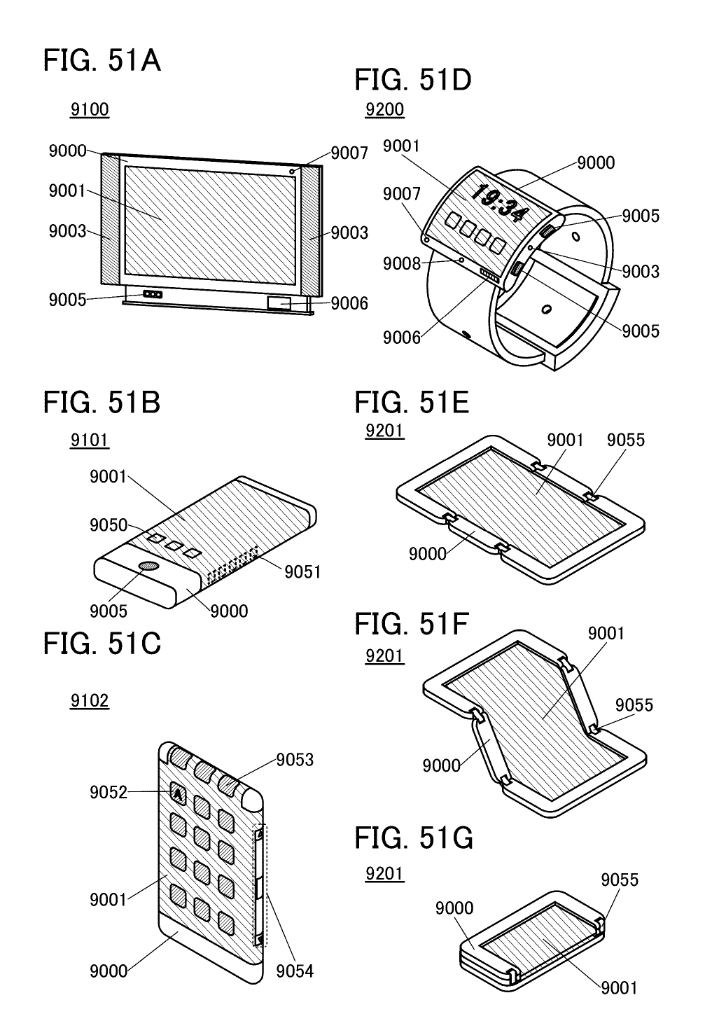

Next, FIGS. 51A to 51G illustrate examples of electronic devices that are different from those illustrated in FIGS. 50A to 50E.

Electronic devices illustrated in FIGS. 51A to 51G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIGS. 51A to 51G can have a variety of functions, for example, a function of displaying a variety of data (e.g., a still image, a moving image, and a text image) on the display portion, a touch panel function, a function of displaying a calendar, date, time, and the like, a function of controlling a process with a variety of software (programs), a wireless communication function, a function of being connected to a variety of computer networks with a wireless communication function, a function of transmitting and receiving a variety of data with a wireless communication function, and a function of reading a program or data stored in a memory medium and displaying the program or data on the display portion. Note that functions of the electronic devices in FIGS. 51A to 51G are not limited thereto, and the electronic devices can have a variety of functions. Although not illustrated in FIGS. 51A to 51G, the electronic devices may each have a plurality of display portions. The electronic devices may have a camera or the like and a function of taking a still image, a function of taking a moving image, a function of storing the taken image in a memory medium (an external memory medium or a memory medium incorporated in the camera), a function of displaying the taken image on the display portion, or the like.

The electronic devices in FIGS. 51A to 51G will be described in detail below.

FIG. 51A is a perspective view illustrating a television device 9100. The television device 9100 can include the display portion 9001 having a large screen size of, for example, 50 inches or more, or 100 inches or more.

FIG. 51B is a perspective view of a portable information terminal 9101. The portable information terminal 9101 functions as, for example, one or more of a telephone set, a notebook, and an information browsing system. Specifically, the portable information terminal can be used as a smartphone. Note that the portable information terminal 9101 may include the speaker, the connection terminal, the sensor, or the like. The portable information terminal 9101 can display characters and image information on its plurality of surfaces. For example, three operation buttons 9050 (also referred to as operation icons, or simply, icons) can be displayed on one surface of the display portion 9001. Furthermore, information 9051 indicated by dashed rectangles can be displayed on another surface of the display portion 9001. Examples of the information 9051 include display indicating reception of an incoming email, social networking service (SNS) message, call, and the like; the title and sender of an email and SNS message; the date; the time; remaining battery; and the reception strength of an antenna. Instead of the information 9051, the operation buttons 9050 or the like may be displayed on the position where the information 9051 is displayed.

FIG. 51C is a perspective view of a portable information terminal 9102. The portable information terminal 9102 has a function of displaying information on three or more surfaces of the display portion 9001. Here, information 9052, information 9053, and information 9054 are displayed on different surfaces. For example, a user of the portable information terminal 9102 can see the display (here, the information 9053) with the portable information terminal 9102 put in a breast pocket of his/her clothes. Specifically, a caller's phone number, name, or the like of an incoming call is displayed in a position that can be seen from above the portable information terminal 9102. Thus, the user can see the display without taking out the portable information terminal 9102 from the pocket and decide whether to answer the call.

FIG. 51D is a perspective view of a watch-type portable information terminal 9200. The portable information terminal 9200 is capable of executing a variety of applications such as mobile phone calls, e-mailing, viewing and editing texts, music reproduction, Internet communication, and computer games. The display surface of the display portion 9001 is bent, and images can be displayed on the bent display surface. The portable information terminal 9200 can employ near field communication that is a communication method based on an existing communication standard. For example, hands-free calling can be achieved by mutual communication between the portable information terminal 9200 and a headset capable of wireless communication. The portable information terminal 9200 includes the connection terminal 9006, and data can be directly transmitted to and received from another information terminal via a connector. Power charging through the connection terminal 9006 is possible. Note that the charging operation may be performed by wireless power feeding without using the connection terminal 9006.

FIGS. 51E, 51F, and 51G are perspective views of a foldable portable information terminal 9201 that is opened, that is shifted from the opened state to the folded state or from the folded state to the opened state, and that is folded, respectively. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. By folding the portable information terminal 9201 at a connection portion between two housings 9000 with the hinges 9055, the portable information terminal 9201 can be reversibly changed in shape from an opened state to a folded state. For example, the portable information terminal 9201 can be bent with a radius of curvature greater than or equal to 1 mm and less than or equal to 150 mm.

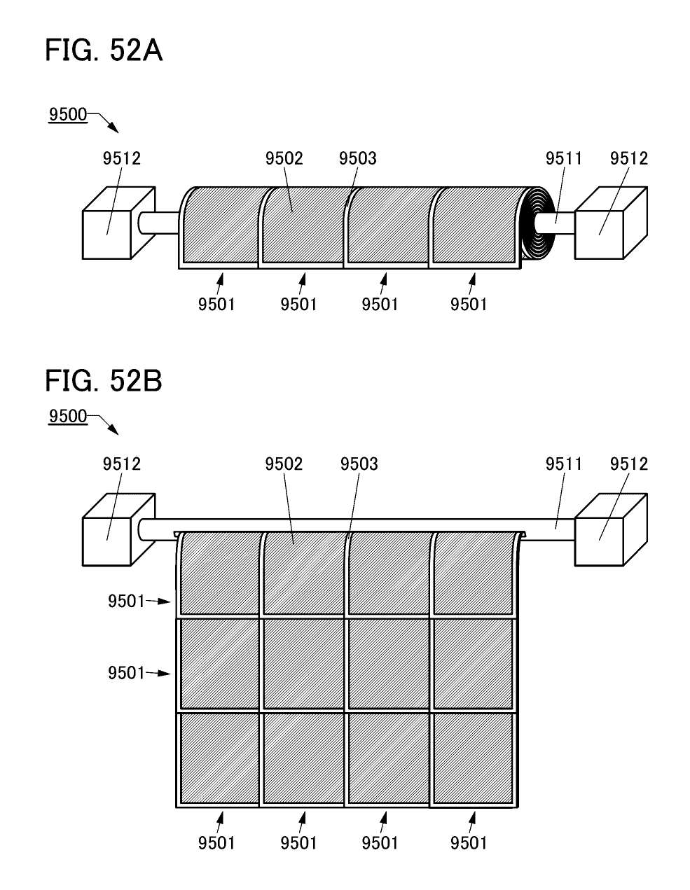

FIGS. 52A and 52B illustrate an example of an electronic device different from the electronic devices illustrated in FIGS. 50A to 50E and FIGS. 51A to 51G. FIGS. 52A and 52B are perspective views of a display device including a plurality of display panels. Note that the plurality of display panels are wound in the perspective view in FIG. 52A and are unwound in the perspective view in FIG. 52B.

A display device 9500 illustrated in FIGS. 52A and 52B includes a plurality of display panels 9501, a hinge 9511, and a bearing 9512. The plurality of display panels 9501 each include a display region 9502 and a light-transmitting region 9503.

Each of the plurality of display panels 9501 is flexible. Two adjacent display panels 9501 are provided so as to partly overlap with each other. For example, the light-transmitting regions 9503 of the two adjacent display panels 9501 can be overlapped each other. A display device having a large screen can be obtained with the plurality of display panels 9501. The display device is highly versatile because the display panels 9501 can be wound depending on its use.

Although the display regions 9502 of the adjacent display panels 9501 are separated from each other in FIGS. 52A and 52B, without limitation to this structure, the display regions 9502 of the adjacent display panels 9501 may overlap with each other without any space so that a continuous display region 9502 is obtained, for example.

The electronic devices described in this embodiment each include the display portion for displaying some sort of data. Note that the semiconductor device of one embodiment of the present invention can also be used for an electronic device that does not have a display portion.

The structure described in this embodiment can be used in appropriate combination with the structure described in any of the other embodiments.

### Example 1

In this example, the carrier density of an oxide semiconductor film of one embodiment of the present invention was measured. The measurement and its result are described below.

### <1-1. Carrier Density of Oxide Semiconductor Film>

In this example, heat treatment was performed on Sample A1, Sample A4, Sample A7, Sample A10, and Sample A11, which are described in Embodiment 1, and the carrier density of each sample was measured.

As the heat treatment, a first heat treatment was performed at 450° C. for 1 hour in a nitrogen atmosphere and then a second heat treatment was performed at 450° C. for 1 hour in a mixed atmosphere of nitrogen and oxygen.

For the measurement of carrier densities, a Hall effect measurement system (resistivity/Hall measurement system, ResiTest 8310 Series manufactured by TOYO Corporation) was used. The system ResiTest 8310 is capable of measuring alternate current (AC) Hall. In the measurement, the direction and strength of a magnetic field are changed in a certain cycle and in synchronization therewith, so that only a Hall electromotive voltage caused in a sample is detected. Even in the case of a material with low field-effect mobility and high resistivity, a Hall electromotive voltage can be detected.

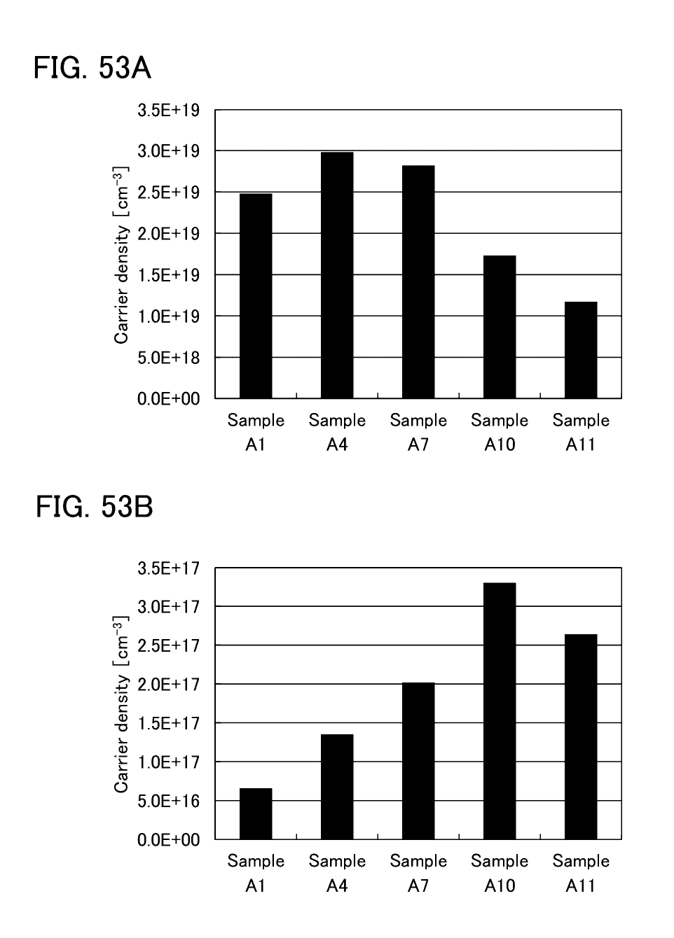

FIGS. 53A and 53B show the measurement results of carrier densities.

Specifically, FIG. 53A shows the measurement results of carrier densities of Sample A1, Sample A4, Sample A7, Sample A10, and Sample A11 that were subjected to the first heat treatment. FIG. 53B shows the measurement results of carrier densities of Sample A1, Sample A4, Sample A7, Sample A10, and Sample A11 that were subjected to the first and second heat treatments.

As shown in FIG. 53A, the carrier density of the oxide semiconductor film in each sample after being subjected to the first heat treatment is higher than or equal to 1×10¹⁹ cm⁻³ and lower than or equal to 3×10¹⁹ cm⁻³. As shown in FIG. 53B, the carrier density of an oxide semiconductor film in each sample after being subjected to the first and second heat treatment is higher than or equal to 5×10¹⁶ cm⁻³ and lower than or equal to 3.5×10¹⁷ cm⁻³.

The results suggest that the amount of oxygen vacancies in the oxide semiconductor film increases by the first heat treatment, and that the oxygen vacancies in the oxide semiconductor film are filled with oxygen by the subsequent second heat treatment.

Note that the structure described in this example can be combined as appropriate with any of the structures described in the embodiments or the other examples.

### Example 2

In this example, transistors in each of which the oxide semiconductor film of one embodiment of the present invention was used in a channel region (each transistor with a channel length L of 6.0 μm and a channel width W of 50 μm) were fabricated, and electrical characteristics of the transistors were measured. Note that Samples B1 to B3 were fabricated in this example.

Samples B1 to B3 each have a structure in which 5 transistors each corresponding to the transistor 100B illustrated in FIGS. 17A and 17B are formed over a substrate. In the description below, the same reference numerals are used for components having functions similar to those in the components of the transistor 100B illustrated in FIGS. 17A and 17B. First, a method for fabricating Sample B1 is described below.

### <2-1. Method for Fabricating Sample B1>

First, the substrate 102 was prepared. As the substrate 102, a glass substrate was used. Next, the conductive film 106 was formed over the substrate 102. For the conductive film 106, a 10-nm-thick titanium film and a 100-nm-thick copper film were formed with a sputtering apparatus.

Next, the insulating film 104 was formed over the substrate 102 and the conductive film 106. Note that in this example, as the insulating film 104, insulating films 104_1, 104_2, 104_3, and 104_4 were successively formed in this order with a PECVD apparatus in a vacuum. A 50-nm-thick silicon nitride film was formed as the insulating film 104_1. A 300-nm-thick silicon nitride film was formed as the insulating film 104_2. A 50-nm-thick silicon nitride film was formed as the insulating film 104_3. A 50-nm-thick silicon oxynitride film was formed as the insulating film 104_4.

Next, an oxide semiconductor film was formed over the insulating film 104 and was processed into an island shape, whereby the oxide semiconductor film 108 was formed. A 40-nm-thick oxide semiconductor film was formed as the oxide semiconductor film 108.

The oxide semiconductor film 108 in Sample B1 was formed under the following conditions: the substrate temperature was 170° C.; an argon gas with a flow rate of 140 sccm and an oxygen gas with a flow rate of 60 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). The oxygen flow rate ratio for fabricating Sample B1 was 30%.

Note that processing into the oxide semiconductor film 108 was performed by a wet etching method.

Next, an insulating film to be the insulating film 110 was formed over the insulating film 104 and the oxide semiconductor film 108. For the insulating film, a 150-nm-thick silicon oxynitride film was formed with a PECVD apparatus.

Next, heat treatment was performed. The heat treatment was performed at 350° C. in a mixed gas atmosphere of nitrogen and oxygen for one hour.

Next, the opening 143 was formed at desired regions in the insulating film 104 and the insulating film that is to be the insulating film 110. The formation method of the opening 143 was a dry etching method.

A 100-nm-thick oxide semiconductor film was formed over the insulating film so as to cover the opening 143, and the oxide semiconductor film was processed into an island shape, so that the conductive film 112 was formed. The insulating film in contact with the bottom surface of the conductive film 112 was processed in succession to the formation of the conductive film 112, whereby the insulating film 110 was formed.

As the conductive film 112, a 100-nm-thick oxide semiconductor film was formed. Note that the oxide semiconductor film had a stacked-layer structure including two layers. A first layer in the oxide semiconductor film was formed to have a thickness of 10 nm under the following conditions: the substrate temperature was 170° C.; an oxygen gas with a flow rate of 200 sccm was introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). A second layer of the oxide semiconductor film was formed to have thickness of 90 nm under the following conditions: the substrate temperature was 170° C.; an argon gas with a flow rate of 180 sccm and an oxygen gas with a flow rate of 20 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]).

Note that processing into the conductive film 112 was performed by a wet etching method, and processing into the insulating film 110 was performed by a dry etching method.

Next, plasma treatment was performed from above the insulating film 104, the oxide semiconductor film 108, the insulating film 110, and the conductive film 112. The plasma treatment was performed with a PECVD apparatus at a substrate temperature of 220° C. in a mixed gas atmosphere containing an argon gas and a nitrogen gas.

Then, the insulating film 116 was formed over the insulating film 104, the oxide semiconductor film 108, the insulating film 110, and the conductive film 112. As the insulating film 116, a 100-nm-thick silicon nitride film was formed with a PECVD apparatus.

Next, the insulating film 118 was formed over the insulating film 116. As the insulating film 118, a 300-nm-thick silicon oxynitride film was formed with a PECVD apparatus.

Next, a mask was formed over the insulating film 118, and the openings 141a and 141b were formed in the insulating films 116 and 118 using the mask. Processing into the openings 141a and 141b was performed with a dry etching apparatus.

Next, a conductive film was formed over the insulating film 118 so as to fill the openings 141a and 141b and was processed into island shapes, whereby the conductive films 120a and 120b were formed.

For the conductive films 120a and 120b, a 10-nm-thick titanium film and a 100-nm-thick copper film were formed with a sputtering apparatus.

The insulating film 122 was formed over the insulating film 118 and the conductive films 120a and 120b. A 1.5-μm-thick acrylic-based photosensitive resin film was used as the insulating film 122.

Through the above-described steps, the transistor corresponding to the transistor 100B illustrated in FIGS. 17A and 17B was formed.

### <2-2. Method for Fabricating Sample B2>

In fabrication of Sample B2, the formation conditions of the oxide semiconductor film 108 are different from those in fabrication of Sample B1. Note that other than the formation conditions of the oxide semiconductor film 108, fabrication conditions of Sample B2 are the same as those of Sample B1.

The oxide semiconductor film 108 in Sample B2 was formed under the following conditions: the substrate temperature was 130° C.; an argon gas with a flow rate of 180 sccm and an oxygen gas with a flow rate of 20 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). The oxygen flow rate ratio for fabricating Sample B2 was 10%.

### <2-3. Method for Fabricating Sample B3>

In fabrication of Sample B3, the formation conditions of the oxide semiconductor film 108 are different from those in fabrication of Sample B1. Note that other than the formation conditions of the oxide semiconductor film 108, fabrication conditions of Sample B3 are the same as those of Sample B1.

The oxide semiconductor film 108 in Sample B3 was formed under the following conditions: the substrate temperature was room temperature (R.T.); an argon gas with a flow rate of 180 sccm and an oxygen gas with a flow rate of 20 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). The oxygen flow rate ratio for fabricating Sample B3 was 10%.

<2-4. Drain Current-Gate Voltage (I_{d}-V_{g}) Characteristics of Transistor>

Next, I_{d}-V_{g} characteristics of the transistors in Samples B1 to B3 were measured.

As conditions for measuring the I_{d}-V_{g} characteristics of each transistor, a voltage applied to the conductive film 106 functioning as the first gate electrode of each transistor (hereinafter the voltage is also referred to as gate voltage (V_{g})) and a voltage applied to the conductive film 112 functioning as the second gate electrode of each transistor (hereinafter the voltage is also referred to as back gate voltage (V_{bg})) changed from −15 V to +20 V in increments of 0.25 V. A voltage (source voltage, referred to as Vₛ) applied to the conductive film 120a functioning as the source electrode was 0 V (comm), and a voltage (drain voltage, referred to as V_{d}) applied to the conductive film 120b functioning as the drain electrode was 0.1 V and 20 V.

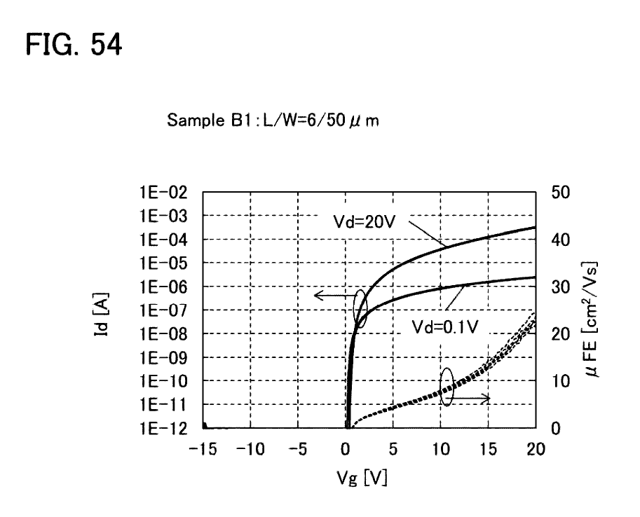

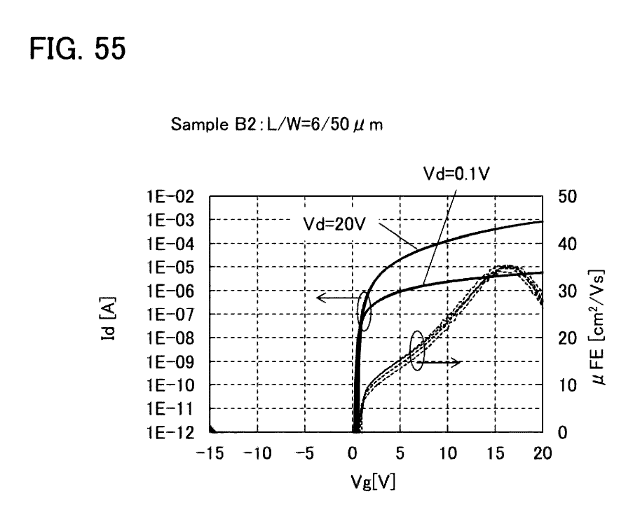

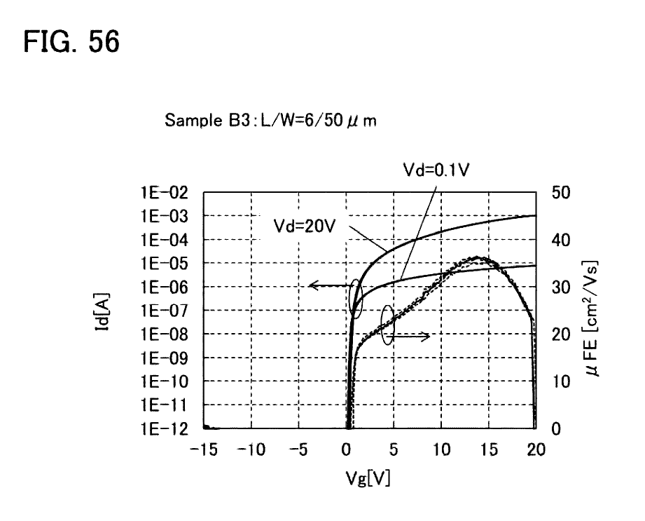

FIG. 54 shows I_{d}-V_{g} characteristics of Sample B1, FIG. 55 shows I_{d}-V_{g} characteristics of Sample B2, and FIG. 56 shows I_{d}-V_{g} characteristics of Sample B3. In each of FIG. 54, FIG. 55, and FIG. 56, the first vertical axis represents I_{d} (A), the second vertical axis represents field-effect mobility (μFE (cm²/Vs)), and the horizontal axis represents V_{g} (V). FIG. 54, FIG. 55, and FIG. 56 show superimposed I_{d}-V_{g} characteristics of the 5 transistors of Samples B1 to B3, respectively.

As shown in FIG. 54, FIG. 55, and FIG. 56, Samples B1 to B3 fabricated in this example have favorable electrical characteristics. In addition, according to the results shown in FIG. 54, FIG. 55, and FIG. 56, the descending order of field-effect mobility of transistors is as follows: the transistors in Sample B3, those in Sample B2, and those in Sample B1. In particular, Samples B3 and B2 have high field-effect mobility in the range of low V_{g}, e.g., the range where V_{g} is lower than or equal to 10 V, compared with Sample B1.

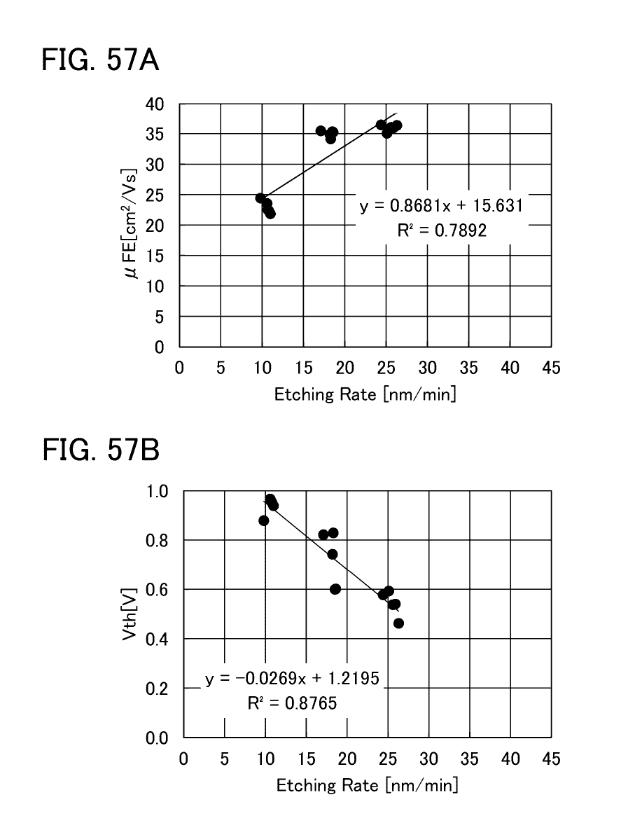

FIG. 57A shows a correlation between the field-effect mobilities of the transistors and the etching rates of the oxide semiconductor films in Samples B1 to B3. FIG. 57B shows a correlation between the threshold voltages (Vₜₕ) of the transistors and the etching rates of the oxide semiconductor films in Samples B1 to B3.

The etching rate of the oxide semiconductor film indicates an etching rate when the oxide semiconductor film was etched using a phosphoric acid aqueous solution that was obtained by diluting 85 vol % phosphoric acid with water 100 times. Measurement points of the etching rate of the oxide semiconductor films were regions in the vicinity of the 5 transistors formed over the substrate 102.

As shown in FIG. 57A, a correlation exists between the field-effect mobilities of the transistors and the etching rates of the oxide semiconductor films. As shown in FIG. 57B, a correlation exists between the threshold voltages (Vₜₕ) of the transistors and the etching rates of the oxide semiconductor films.

According to the results shown in FIGS. 57A and 57B, it is preferable to increase the etching rate of the oxide semiconductor film in order to increase the field-effect mobility of the transistor. On the other hand, when the etching rate of the oxide semiconductor film is increased, the threshold voltage of the transistor is shifted in the negative direction. In each of FIGS. 57A and 57B, a linear approximate curve and an equation of the approximate curve are shown. According to the equation, the etching rate of the oxide semiconductor film is lower than or equal to 45 nm/min in order to obtain a normally-on transistor, that is, a transistor with a threshold voltage higher than 0 V. Note that the lower limit of the etching rate of the oxide semiconductor film is preferably higher than or equal to 10 nm/min because the processing becomes difficult when the etching rate is too reduced.

Thus, when the etching is performed with use of a phosphoric acid aqueous solution obtained by diluting 85 vol % phosphoric acid with water 100 times, the oxide semiconductor film of one embodiment of the present invention has a region which is etched at an etching rate preferably higher than or equal to 10 nm/min and lower than or equal to 45 nm/min, further preferably higher than or equal to 10 nm/min and lower than or equal to 25 nm/min.

Note that the characteristics of the transistor, particularly the threshold voltage of the transistor vary depending on the channel length (L) and channel width (W). Therefore, the optimum etching rate may be selected by a practitioner.

Note that the structure described in this example can be combined as appropriate with any of the structures described in the embodiments or the other examples.

### Example 3

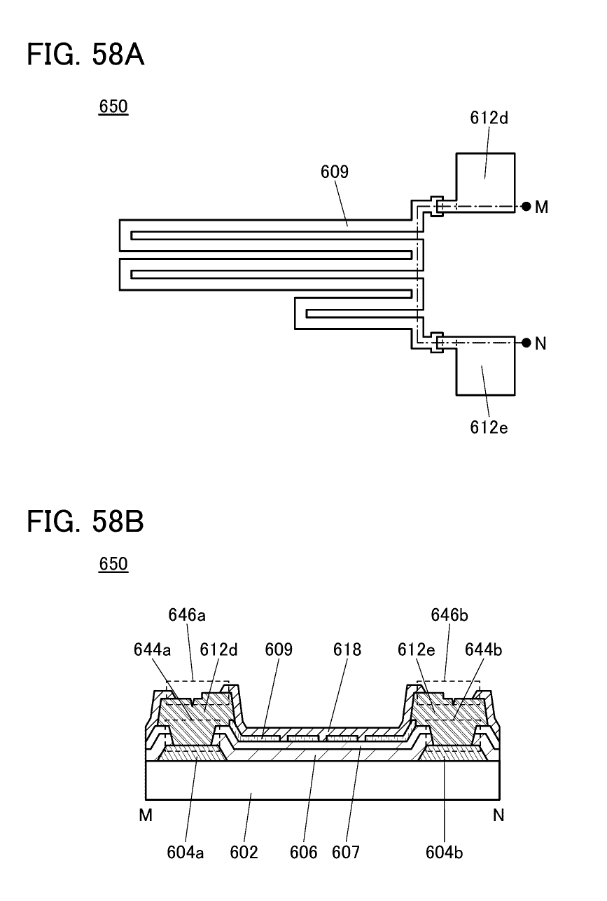

In this example, the sheet resistance of the oxide semiconductor film of one embodiment of the present invention was examined. In this example, samples (Samples C1 to C4) corresponding to a sample 650 for evaluation illustrated in FIGS. 58A and 58B were fabricated.

### <3-1. Structure of Sample for Evaluation>

First, the sample 650 for evaluation illustrated in FIGS. 58A and 58B is described. FIG. 58A is a top view of the sample 650 for evaluation, and FIG. 58B is a cross-sectional view taken along the dashed dotted line M-N in FIG. 58A.

The sample 650 for evaluation includes a conductive film 604a over the substrate 602, a conductive film 604b over the substrate 602, an insulating film 606 covering the substrate 602 and the conductive films 604a and 604b, an insulating film 607 over the insulating film 606, an oxide semiconductor film 609 over the insulating film 607, a conductive film 612d connected to the conductive film 604a through an opening 644a provided in the insulating films 606 and 607, a conductive film 612e connected to the conductive film 604b through an opening 644b provided in the insulating films 606 and 607, and an insulating film 618 covering the insulating film 607, the oxide semiconductor film 609, and the conductive films 612d and 612e.

Note that the conductive films 612d and 612e are connected to the oxide semiconductor film 609. In addition, openings 646a and 646b are provided in the insulating film 618 over the conductive films 612d and 612e, respectively.

Samples in which the oxide semiconductor films 609 have different structures from each other were fabricated as Samples C1 to C4, and the sheet resistance of each oxide semiconductor film 609 was examined. Note that in each of the samples C1 to C4, the size (W/L) of the oxide conductive film 609 was 10 μm/1500 μm.

### <3-2. Method for Fabricating Sample C1 and Sample C3>

A method for fabricating Samples C1 and C3 is described below.

First, the conductive films 604a and 604b were formed over the substrate 602. As the substrate 602, a glass substrate was used. As each of the conductive films 604a and 604b, a stacked film including a 10-nm-thick titanium film and a 100-nm-thick copper film was formed with a sputtering apparatus.

Next, the insulating films 606 and 607 were formed over the substrate 602 and the conductive films 604a and 604b. As the insulating film 606, a 400-nm-thick silicon nitride film was formed with a PECVD apparatus. As the insulating film 607, a 50-nm-thick silicon oxynitride film was formed with a PECVD apparatus.

Next, heat treatment was performed. The heat treatment was performed at 350° C. in a nitrogen atmosphere for one hour.

Next, the oxide semiconductor film 609 was formed over the insulating film 607. Note that the oxide semiconductor film 609 in Sample C1 and the oxide semiconductor film 609 in Sample C3 were formed under different conditions.

### [Sample C1]

As the oxide semiconductor film 609 in Sample C1, a 40-nm-thick IGZO film was formed. The IGZO film was formed under the following conditions: the substrate temperature was 170° C.; an argon gas with a flow rate of 100 sccm and an oxygen gas with a flow rate of 100 sccm were introduced into a chamber of the sputtering apparatus; the pressure was set to 0.6 Pa; and an AC power of 2.5 kW was applied to a metal oxide target containing indium, gallium, and zinc (In:Ga:Zn=1:1:1 [atomic ratio]). The oxygen flow rate ratio for fabricating Sample C1 was 50%.

### [Sample C3]

As the oxide semiconductor film 609 in Sample C3, a 40-nm-thick IGZO film was formed. The IGZO film was formed under the following conditions: the substrate temperature was 130° C.; an argon gas with a flow rate of 180 sccm and an oxygen gas with a flow rate of 20 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). The oxygen flow rate ratio for fabricating Sample C3 was 10%.

Next, a resist mask was formed over the insulating film 607 and the oxide semiconductor film 609, and desired regions were etched to form the openings 644a and 644b reaching the conductive films 604a and 604b, respectively. The openings 644a and 644b were formed with a dry etching apparatus. Note that the resist mask was removed after the formation of the openings 644a and 644b.

Next, a conductive film was formed over the insulating film 607, the oxide semiconductor film 609, and the openings 644a and 644b. A resist mask was formed over the conductive film, and a desired region was etched to form the conductive films 612d and 612e. As each of the conductive films 612d and 612e, a stacked film including a 10-nm-thick titanium film and a 100-nm-thick copper film were formed with a sputtering apparatus. The resist mask was removed after the formation of the conductive films 612d and 612e.

Next, the insulating film 618 was formed over the insulating film 607, the oxide semiconductor film 609, and the conductive films 612d and 612e. As the insulating film 618, a 300-nm-thick silicon oxynitride film was formed with a PECVD apparatus.

Next, a resist mask was formed over the insulating film 618, and desired regions were etched to form the openings 646a and 646b reaching the conductive films 612d and 612e, respectively. The openings 646a and 646b were formed with a dry etching apparatus. Note that the resist mask was removed after the formation of the openings 646a and 646b.

Through the above steps, Samples C1 and C3 were fabricated.

### <Method for Fabricating Sample C2 and Sample C4>

In fabrication of Samples C2 and C4, the formation conditions of the insulating film 618 were different from those in fabrication of Samples C1 and C3.

As the insulating film 618 in each of Samples C2 and C4, a stacked film including a 100-nm-thick silicon nitride film and a 300-nm-thick silicon oxynitride film was formed with a PECVD apparatus.

Note that Sample C2 was fabricated under the same formation conditions as those of Sample C1, other than the formation condition of the insulating film 618. Sample C4 was fabricated under the same formation conditions as those of Sample C3, other than the formation condition of the insulating film 618.

Through the above steps, Samples C2 and C4 in this example were fabricated.

### <3-3. Measurement of Sheet Resistance of Oxide Semiconductor Film>

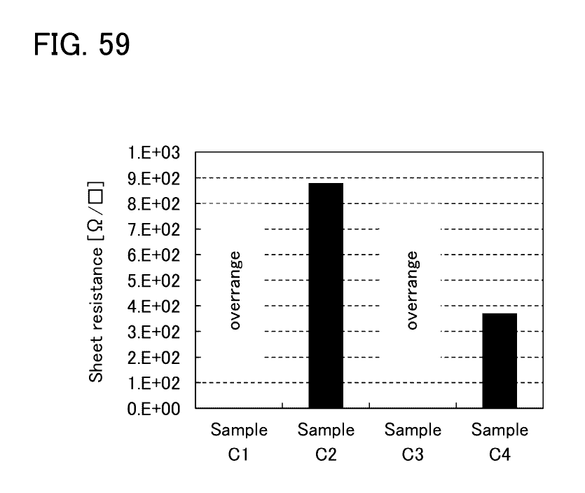

Next, Samples C1 to C4 were subjected to sheet resistance measurement. FIG. 59 shows measurement results of sheet resistance of Samples C1 to C4.

As shown in FIG. 59, in each of Samples C1 and C3, the sheet resistance of the oxide semiconductor film 609 exceeded the measurement upper limit (1×10⁶ Ω/square) and thus was not able to be measured. A conceivable reason of this is that the insulating film 618 includes a silicon oxynitride film, that is, the oxide semiconductor film 609 is in contact with the silicon oxynitride film. In contrast, in each of Samples C2 and C4, the sheet resistance of the oxide semiconductor film 609 was low. A conceivable reason of this is that the insulating film 618 includes a silicon nitride film and a silicon oxynitride film, that is, the oxide semiconductor film 609 is in contact with the silicon nitride film. In addition, when the Samples C2 and C4 were compared with each other, the sheet resistance of Sample C4 was observed to be lower than or equal to half of that of Sample C2. This result is probably caused by a difference in the formation conditions of the oxide semiconductor film 609 between Samples C2 and C4.

It was found that the sheet resistance of the oxide semiconductor film can be controlled by varying the formation condition of the oxide semiconductor film and the structure of the insulating film formed over the oxide semiconductor film as described above.

Note that the structure described in this example can be combined as appropriate with any of the structures described in the embodiments and the other examples.

### Example 4

In this example, transistors in each of which the oxide semiconductor film of one embodiment of the present invention is used for a channel region were fabricated, and I_{d}-V_{g} characteristics of the transistors were examined.

In this example, Samples D1 to D4 were fabricated.

Note that Samples D1 to D4 are each a sample in which 4 transistors each corresponding to the transistor 100B illustrated in FIGS. 17A and 17B are formed over a substrate. Note that in Samples D1 and D3, each transistor has a channel length L of 2.0 μm and a channel width W of 50 μm. In Samples D2 and D4, each transistor has a channel length L of 6.0 μm and a channel width W of 50 μm.

The formation condition of the oxide semiconductor film was different between the fabrication of Samples D1 and D2 and the fabrication of Samples D3 and D4.

In the description below, the same reference numerals are used for components having functions similar to those in the components of the transistor 100B illustrated in FIGS. 17A and 17B. Methods for fabricating Samples D1 and D2 are described below.

### <4-1. Method for Fabricating Sample D1 and Sample D2>

First, the substrate 102 was prepared. As the substrate 102, a glass substrate was used. Next, the conductive film 106 was formed over the substrate 102. For the conductive film 106, a 10-nm-thick titanium film and a 100-nm-thick copper film were formed with a sputtering apparatus.

Next, the insulating film 104 was formed over the substrate 102 and the conductive film 106. Note that in this example, as the insulating film 104, the insulating films 104_1, 104_2, 104_3, and 104_4 were successively formed in this order with a PECVD apparatus in a vacuum. A 50-nm-thick silicon nitride film was formed as the insulating film 104_1. A 300-nm-thick silicon nitride film was formed as the insulating film 104_2. A 50-nm-thick silicon nitride film was formed as the insulating film 104_3. A 50-nm-thick silicon oxynitride film was formed as the insulating film 104_4.

Next, an oxide semiconductor film was formed over the insulating film 104 and was processed into an island shape, whereby the oxide semiconductor film 108 was formed. A 40-nm-thick oxide semiconductor film was formed as the oxide semiconductor film 108.

Each of the oxide semiconductor films 108 in Samples D1 and D2 was formed under the following conditions: the substrate temperature was 170° C.; an argon gas with a flow rate of 100 sccm and an oxygen gas with a flow rate of 100 sccm were introduced into a chamber of the sputtering apparatus; the pressure was set to 0.6 Pa; and an AC power of 2.5 kW was applied to a metal oxide target containing indium, gallium, and zinc (In:Ga:Zn=1:1:1 [atomic ratio]). The oxygen flow rate ratio for fabricating Samples D1 and D2 was 50%.

Note that processing into the oxide semiconductor film 108 was performed by a wet etching method.

Next, an insulating film to be the insulating film 110 was formed over the insulating film 104 and the oxide semiconductor film 108. As the insulating film, a 150-nm-thick silicon oxynitride film was formed with a PECVD apparatus.

Next, heat treatment was performed. The heat treatment was performed at 350° C. in a mixed gas atmosphere of nitrogen and oxygen for one hour.

Next, the opening 143 was formed at desired regions in the insulating film 104 and the insulating film to be the insulating film 110. A formation method of the opening 143 was a dry etching method.

Next, a 100-nm-thick oxide semiconductor film was formed over the insulating film so as to cover the opening 143, and the oxide semiconductor film was processed into an island shape, whereby the conductive film 112 was formed. The insulating film in contact with the bottom surface of the conductive film 112 was processed in succession to the formation of the conductive film 112, whereby the insulating film 110 was formed.

As the conductive film 112, a 100-nm-thick oxide semiconductor film was formed. The oxide semiconductor film had a stacked-layer structure including two layers. A first layer of the oxide semiconductor film was formed to have a thickness of 10 nm under the following conditions: the substrate temperature was 170° C.; an oxygen gas with a flow rate of 200 sccm was introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). A second layer of the oxide semiconductor film was formed to have a thickness of 90 nm under the following conditions: the substrate temperature was 170° C.; an argon gas with a flow rate of 180 sccm and an oxygen gas with a flow rate of 20 sccm introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]).

Note that processing into the conductive film 112 was performed by a wet etching method, and processing into the insulating film 110 was performed by a dry etching method.

Next, plasma treatment was performed from above the insulating film 104, the oxide semiconductor film 108, the insulating film 110, and the conductive film 112. The plasma treatment was performed with a PECVD apparatus at a substrate temperature of 220° C. in a mixed gas atmosphere containing an argon gas and a nitrogen gas.

Then, the insulating film 116 was formed over the insulating film 104, the oxide semiconductor film 108, the insulating film 110, and the conductive film 112. As the insulating film 116, a 100-nm-thick silicon nitride film was formed with a PECVD apparatus.

Next, the insulating film 118 was formed over the insulating film 116. As the insulating film 118, a 300-nm-thick silicon oxynitride film was formed with a PECVD apparatus.

Next, a mask was formed over the insulating film 118, and the openings 141a and 141b were formed in the insulating films 116 and 118 using the mask. Processing into the openings 141a and 141b was performed with a dry etching apparatus.

Next, a conductive film was formed over the insulating film 118 so as to fill the openings 141a and 141b and was processed into island shapes, whereby the conductive films 120a and 120b were formed.

For the conductive films 120a and 120b, a 10-nm-thick titanium film and a 100-nm-thick copper film were formed, respectively, with a sputtering apparatus.

Next, the insulating film 122 was formed over the insulating film 118 and the conductive films 120a and 120b. A 1.5-μm-thick acrylic-based photosensitive resin film was used as the insulating film 122.

Through the above steps, Samples D1 and D2 were fabricated.

### <4-2. Method for Fabricating Sample D3 and Sample D4>

In fabrications of Samples D3 and D4, a difference from the fabrication in Samples D1 and D2 is only the formation conduction of the oxide semiconductor film 108. Other than the formation condition of the oxide semiconductor film 108, the conditions were the same as those of Samples D1 and D2.

Each of the oxide semiconductor films 108 in Samples D3 and D4 was formed under the following conditions: the substrate temperature was 130° C.; an argon gas with a flow rate of 180 sccm and an oxygen gas with a flow rate of 20 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). The oxygen flow rate ratio for fabricating Samples D3 and D4 was 10%.

Through the above steps, Samples D3 and D4 were fabricated.

<4-3. I_{d}-V_{g} Characteristics of Transistor>

Next, I_{d}-V_{g} characteristics of Samples D1 to D4 were measured.

The measurement conditions of I_{d}-V_{g} characteristics of the transistors were the same as those in Example 2. Note that in Samples D1 and D3, the range of voltage applied to V_{g} and V_{bg} was from −10 V to +10 V.

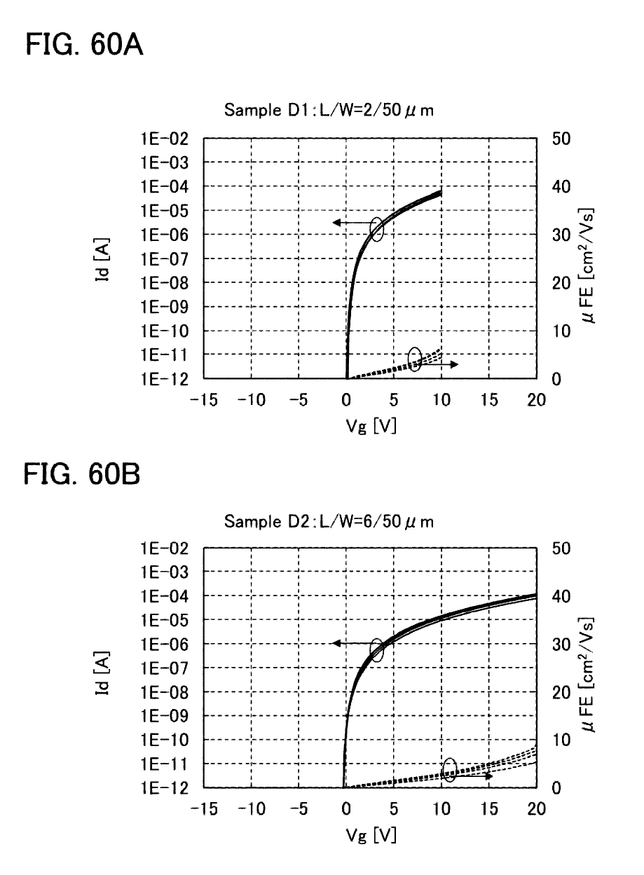

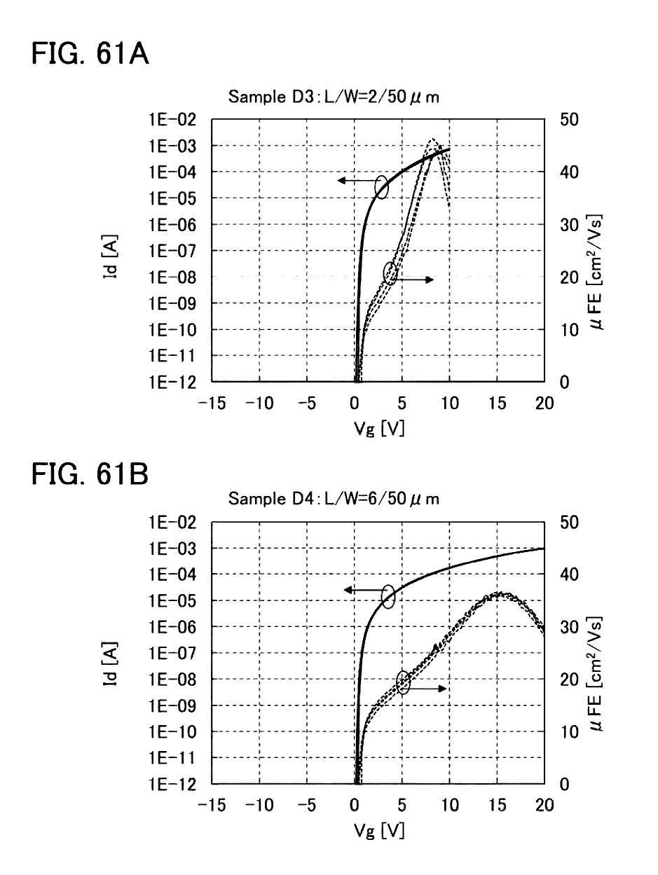

FIG. 60A shows results of I_{d}-V_{g} characteristics of Sample D1, FIG. 60B shows results of I_{d}-V_{g} characteristics of Sample D2, FIG. 61A shows results of I_{d}-V_{g} characteristics of Sample D3, and FIG. 61B shows results of I_{d}-V_{g} characteristics of Sample D4. In each of FIGS. 60A and 60B and FIGS. 61A and 61B, the first vertical axis represents I_{d} (A), the second vertical axis represents field-effect mobility (μFE (cm²/Vs)), and the horizontal axis represents V_{g} (V). FIGS. 60A and 60B and FIGS. 61A and 61B show superimposed I_{d}-V_{g} characteristics of the 4 transistors of Samples D1 to D4, respectively.

As shown in FIGS. 60A and 60B and FIGS. 61A and 61B, Samples D1 to D4 fabricated in this example have favorable electrical characteristics.

### <4-4. Comparison of I_{d} Depending on Condition of Forming Oxide Semiconductor Film>

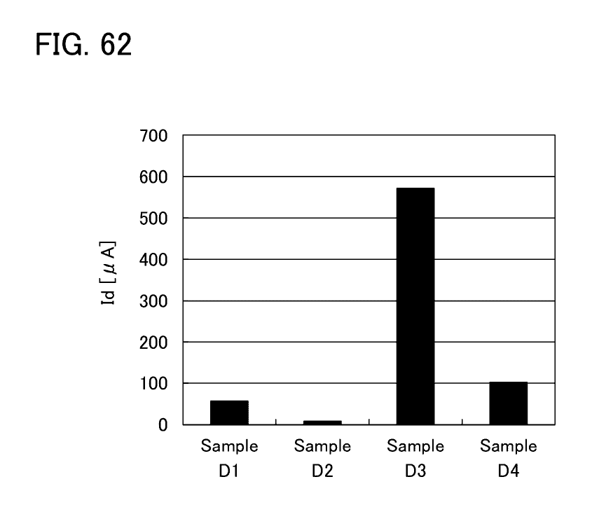

Next, the on-state currents (I_{d}) of the transistors in Samples D1 to D4 were compared. FIG. 62 shows the I_{d} comparison results.

As shown in FIG. 62, Samples D3 and D4 have higher I_{d} than Samples D1 and D2. When Sample D3 and Sample D4 are compared, Sample D3 whose transistor has a shorter channel length has higher I_{d} than Sample D4.

### <4-5. Display Example of Display Device>

Next, a display device including transistors corresponding to those in Samples D3 and D4 was formed, and the display quality of the display device was evaluated. Table 2 shows specifications of the display device formed in this example.

TABLE 2

| | Specifications |
|---|---|
| Screen Diagonal | 5.46-inch |
| Driving Method | Active Matrix |
| Resolution | 2160 × RGB × 3840 (QFHD) |
| Pixel Pitch | 10.5 μm × RGB × 31.5 μm |
| Aperture ratio | 45.0% |
| Pixel Arrangement | RGB Stripe |
| Source Driver | COG and DeMUX |
| Scan Driver | Integrated |

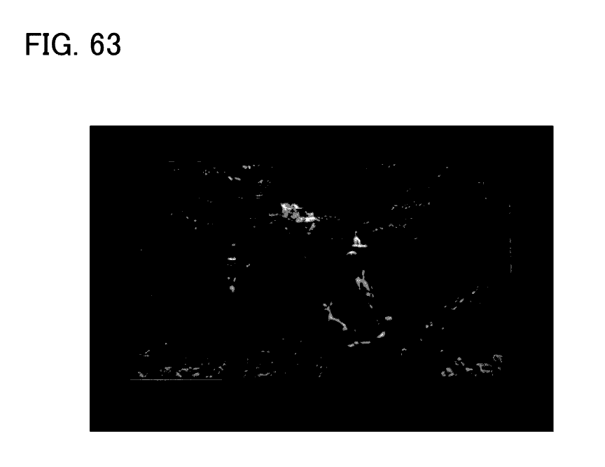

FIG. 63 shows a display example of the display device having the specifications shown in Table 2. As shown in FIG. 63, it was confirmed that the display device had favorable display quality.

Note that the structure described in this example can be combined as appropriate with any of the structures described in the embodiments and the other examples.

### Example 5

In this example, samples (Samples E1 to E3) each including an oxide semiconductor film were fabricated, and the resistivity in each sample was measured.

### <5-1. Structure and Fabrication Method of Each Sample>

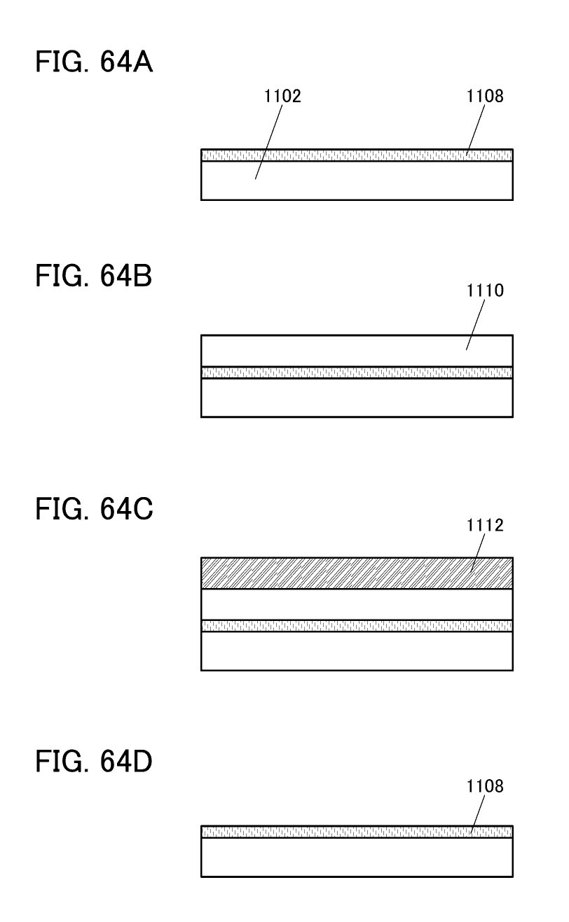

First, a structure and a fabrication method of each sample are described with reference to FIGS. 64A to 64D. FIGS. 64A to 64C are cross-sectional views illustrating a method for fabricating the sample in this example, and FIG. 64D is a cross-sectional view illustrating a structure of the sample in this example.

As illustrated in FIG. 64D, each of Samples E1 to E3 fabricated in this example includes a substrate 1102 and an oxide semiconductor film 1108 over the substrate 1102.

### [Method for Fabricating Sample E1]

First, the oxide semiconductor film 1108 was formed over the substrate 1102 (see FIG. 64A).

A glass substrate was used as the substrate 1102, and a 40-nm-thick In—Ga—Zn oxide was formed as the oxide semiconductor film 1108 with a sputtering apparatus. The In—Ga—Zn oxide was formed under the following conditions: the substrate temperature was 170° C., an argon gas with a flow rate of 35 sccm and an oxygen gas with a flow rate of 15 sccm were introduced into a chamber, the pressure was 0.2 Pa, and AC power of 1500 W was supplied to a metal oxide target (In:Ga:Zn=4:2:4.1 [atomic ratio]) placed in the sputtering apparatus.

Next, the insulating film 1110 was formed over the oxide semiconductor film 1108 (see FIG. 64B).

For the insulating film 1110, a 150-nm-thick silicon oxynitride film was formed with a PECVD apparatus.

Next, heat treatment was performed at a substrate temperature of 350° C. in a nitrogen atmosphere for one hour.

Then, the oxide semiconductor film 1112 was formed over the insulating film 1110 (FIG. 64C).

The oxide semiconductor film 1112 had a stacked-layer structure including two layers. A first layer in the oxide semiconductor film was formed to have thickness of 10 nm under the following conditions: the substrate temperature was 170° C.; an oxygen gas with a flow rate of 200 sccm was introduced into a chamber of the sputtering apparatus; the pressure was set to 0.6 Pa; and an AC power of 2500 W was applied to a metal oxide target (In:Ga:Zn=4:2:4.1 [atomic ratio]) placed in the sputtering apparatus. A second layer in the oxide semiconductor film was formed to have a thickness of 90 nm under the following conditions: the substrate temperature was 170° C.; an argon gas with a flow rate of 180 sccm was introduced into a chamber of the sputtering apparatus; the pressure was set to 0.6 Pa; and an AC power of 2500 W was applied to a metal oxide target (In:Ga:Zn=4:2:4.1 [atomic ratio]) placed in the sputtering apparatus.

Next, the oxide semiconductor film 1112 and the insulating film 1110 were removed, whereby a surface of the oxide semiconductor film 1108 was exposed.

Through the above steps, Sample E1 of this example was fabricated.

[Method for fabricating Sample E2]

The fabrication process of Sample E2 is the same as that of Sample E1, except for a step described below.

In fabricating Sample E2, plasma treatment was performed before the insulating film 1110 was formed over the oxide semiconductor film 1108. In the plasma treatment, a PECVD apparatus was used, the substrate temperature was 350° C., an argon gas with a flow rate of 100 sccm was introduced into a chamber, the pressure was set to 40 Pa, and an RF power of 1000 W was applied.

### [Method for Fabricating Sample E3]

The fabrication process of Sample E3 is the same as that of Sample E1, except for a step described below.

In fabricating Sample E3, plasma treatment was performed before the insulating film 1110 was formed over the oxide semiconductor film 1108. In the plasma treatment, a PECVD apparatus was used, the substrate temperature was 350° C., an argon gas with a flow rate of 100 sccm and a nitrogen gas with a flow rate of 100 sccm were introduced into a chamber, the pressure was set to 40 Pa, and an RF power of 1000 W was applied.

### <5-2. Measurement Result of Resistivity of Each Sample>

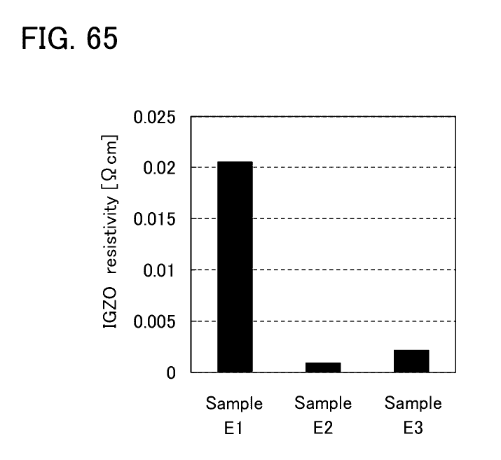

Next, the resistivity of the oxide semiconductor film in each of Samples E1 to E3 was measured. FIG. 65 shows measurement results of resistivity of the oxide semiconductor films in Samples E1 to E3.

According to the results shown in FIG. 65, the resistivity of the oxide semiconductor film in Sample E1 is approximately 0.02 Ωcm, the resistivity of the oxide semiconductor film in Sample E2 is approximately 0.001 Ωcm, and the resistivity of the oxide semiconductor film in Sample E3 is approximately 0.002 Ωcm.

Thus, it was found that the resistivity of the oxide semiconductor film was able to be reduced when the plasma treatment was performed after formation of the oxide semiconductor film.

The structure described in this example can be combined as appropriate with any of the structures described in other examples and the above embodiments.

### Example 6

In this example, a transistor in which the oxide semiconductor film of one embodiment of the present invention was used for a channel region was fabricated, and electrical characteristics of the transistor were measured. Note that Samples F1 to F4 were fabricated in this example.

Samples F1 and F3 each include a transistor with a channel length L of 2.0 μm and a channel width W of 50 μm, and Samples F2 and F4 each include a transistor with a channel length L of 3.0 μm and a channel width W of 50 μm.

Each of Samples F1 to F4 is a sample in which 20 transistors each corresponding to the transistor 100B illustrated in FIGS. 17A and 17B are formed over a substrate. In the description below, the same reference numerals are used for components having functions similar to those in the components of the transistor 100B illustrated in FIGS. 17A and 17B. First, a method for fabricating Sample F1 is described below.

### <6-1. Method for Fabricating Sample F1 and Sample F2>

First, the substrate 102 was prepared. As the substrate 102, a glass substrate was used. Next, the conductive film 106 was formed over the substrate 102. For the conductive film 106, a 10-nm-thick titanium film and a 100-nm-thick copper film were formed with a sputtering apparatus.

Next, the insulating film 104 was formed over the substrate 102 and the conductive film 106. Note that in this example, as the insulating film 104, the insulating films 104_1, 104_2, 104_3, and 104_4 were successively formed in this order with a PECVD apparatus in a vacuum. A 50-nm-thick silicon nitride film was formed as the insulating film 104_1. A 300-nm-thick silicon nitride film was formed as the insulating film 104_2. A 50-nm-thick silicon nitride film was formed as the insulating film 104_3. A 50-nm-thick silicon oxynitride film was formed as the insulating film 104_4.

Next, an oxide semiconductor film was formed over the insulating film 104 and was processed into an island shape, whereby the oxide semiconductor film 108 was formed. A 40-nm-thick oxide semiconductor film was formed as the oxide semiconductor film 108.

The oxide semiconductor film 108 was formed under the following conditions: the substrate temperature was 170° C.; an argon gas with a flow rate of 140 sccm and an oxygen gas with a flow rate of 60 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). The oxygen flow rate ratio for fabricating Sample F1 was 30%.

Note that processing into the oxide semiconductor film 108 was performed by a wet etching method.

Next, an insulating film to be the insulating film 110 was formed over the insulating film 104 and the oxide semiconductor film 108. As the insulating film, a 150-nm-thick silicon oxynitride film was formed with a PECVD apparatus.

Next, heat treatment was performed. The heat treatment was performed at 350° C. in a mixed gas atmosphere of nitrogen and oxygen for one hour.

Next, the opening 143 was formed at desired regions in the insulating film 104 and the insulating film to be the insulating film 110. A formation method of the opening 143 was a dry etching method.

Next, a 100-nm-thick oxide semiconductor film was formed over the insulating film so as to cover the opening 143, and the oxide semiconductor film was processed into an island shape, whereby the conductive film 112 was formed. The insulating film in contact with the bottom surface of the conductive film 112 was processed in succession to the formation of the conductive film 112, whereby the insulating film 110 was formed.

As the conductive film 112, a 100-nm-thick oxide semiconductor film was formed. The oxide semiconductor film had a stacked-layer structure including two layers. A first layer in the oxide semiconductor film was formed to have thickness of 10 nm under the following conditions: the substrate temperature was 170° C.; an oxygen gas with a flow rate of 200 sccm was introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). A second layer in the oxide semiconductor film was formed to have a thickness of 90 nm under the following conditions: the substrate temperature was 170° C.; an argon gas with a flow rate of 180 sccm and an oxygen gas with a flow rate of 20 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]).

Note that processing into the conductive film 112 was performed by a wet etching method, and processing into the insulating film 110 was performed by a dry etching method.

Then, the insulating film 116 was formed over the insulating film 104, the oxide semiconductor film 108, the insulating film 110, and the conductive film 112. As the insulating film 116, a 100-nm-thick silicon nitride film was formed with a PECVD apparatus.

Next, the insulating film 118 was formed over the insulating film 116. As the insulating film 118, a 300-nm-thick silicon oxynitride film was formed with a PECVD apparatus.

Next, a mask was formed over the insulating film 118, and the openings 141a and 141b were formed in the insulating films 116 and 118 using the mask. Processing into the openings 141a and 141b was performed with a dry etching apparatus.

Next, a conductive film was formed over the insulating film 118 so as to fill the openings 141a and 141b and was processed into island shapes, whereby the conductive films 120a and 120b were formed.

For the conductive films 120a and 120b, a 10-nm-thick titanium film and a 100-nm-thick copper film were formed, respectively, with a sputtering apparatus.

Next, the insulating film 122 was formed over the insulating film 118 and the conductive films 120a and 120b. A 1.5-μm-thick acrylic-based photosensitive resin film was used as the insulating film 122.

Through the above-described steps, the transistor corresponding to the transistor 100B illustrated in FIGS. 17A and 17B was formed.

Note that although the transistor size is different between Samples F1 and F2, the fabrication methods of Samples F1 and F2 are the same as each other.

### <6-2. Method for Fabricating Sample F3 and Sample F4>

The fabrication processes of Samples F3 and F4 are the same as those of Samples F1 and F2, except for a step described below.

In fabricating Samples F3 and F4, plasma treatment was performed on the insulating film 104, the oxide semiconductor film 108, the insulating film 110, and the conductive film 112 before the insulating film 116 was formed. In the plasma treatment, a PECVD apparatus was used, the substrate temperature was 220° C., an argon gas with a flow rate of 100 sccm was introduced into a chamber, the pressure was set to 40 Pa, and an RF power of 1000 W was applied.

Note that although the transistor size is different between Samples F3 and F4, the fabrication methods of Samples F3 and F4 are the same as each other.

<6-3. I_{d}-V_{g} Characteristics of Transistor>

Next, I_{d}-V_{g} characteristics of Samples F1 to F4 were measured.

The measurement conditions of I_{d}-V_{g} characteristics of the transistors were the same as those in Example 2.

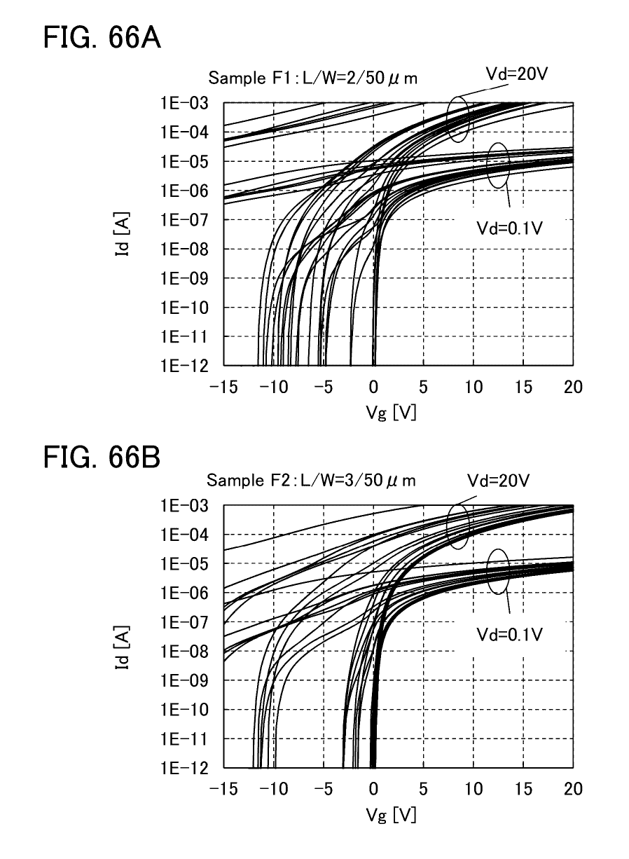

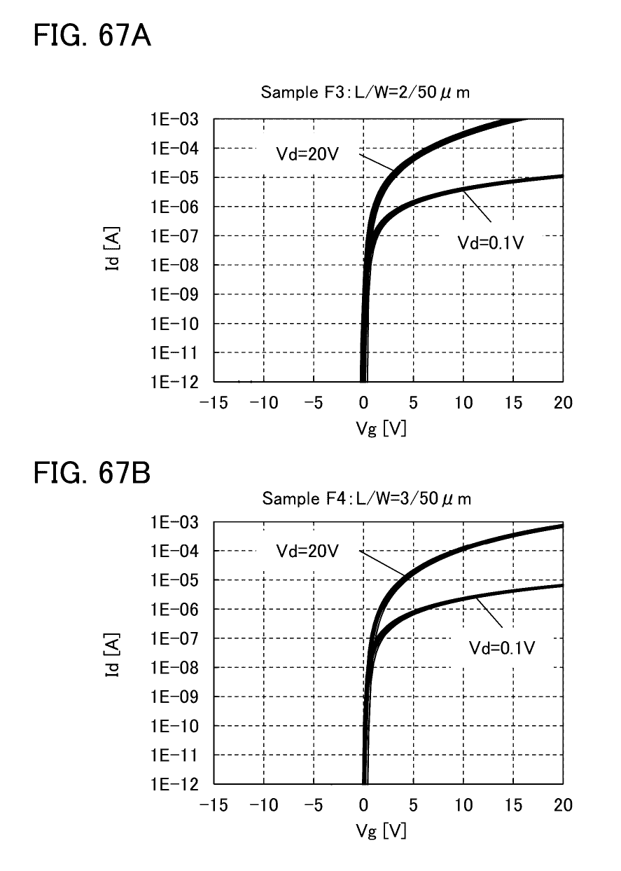

FIG. 66A shows I_{d}-V_{g} characteristics of Sample F1, FIG. 66B shows I_{d}-V_{g} characteristics of Sample F2, FIG. 67A shows I_{d}-V_{g} characteristics of Sample F3, and FIG. 67B shows I_{d}-V_{g} characteristics of Sample F4. In each of FIGS. 66A and 66B and FIGS. 67A and 67B, the vertical axis represents I_{d} (A), and the horizontal axis represents V_{g} (V). FIGS. 66A and 66B and FIGS. 67A and 67B show superimposed I_{d}-V_{g} characteristics of the 20 transistors of Samples F1 to F4, respectively.

As shown in FIGS. 66A and 66B and FIGS. 67A and 67B, Samples F3 and F4 have less variation between 20 transistors and further favorable electrical characteristics than Samples F1 and F2. A conceivable reason of this is that a source region and a drain region formed in the oxide semiconductor film 108 come to have low resistance due to the plasma treatment performed from above the oxide semiconductor film 108. A phenomenon in which the resistance of the oxide semiconductor film is reduced by plasma treatment performed from above the oxide semiconductor film is described in Example 5.

Note that the structure described in this example can be combined as appropriate with any of the structures described in the embodiments or the other examples.

### Example 7

In this example, a transistor in which the oxide semiconductor film of one embodiment of the present invention is used for a channel region was fabricated, and electrical characteristics of the transistor were measured. Samples G1 and G2 were fabricated in this example.

Sample G1 includes a transistor with a channel length L of 2.0 μm and a channel width W of 50 μm, and Sample G2 includes a transistor with a channel length L of 3.0 μm and a channel width W of 50 μm.

Each of Samples G1 and G2 is a sample in which 20 transistors each corresponding to the transistor 100B illustrated in FIGS. 17A and 17B are formed over a substrate. In the description below, the same reference numerals are used for components having functions similar to those in the components of the transistor 100B illustrated in FIGS. 17A and 17B. First, a method for fabricating Sample G1 is described below.

### <7-1. Method for Fabricating Sample G1 and Sample G2>

First, the substrate 102 was prepared. As the substrate 102, a glass substrate was used. Next, the conductive film 106 was formed over the substrate 102. For the conductive film 106, a 10-nm-thick titanium film and a 100-nm-thick copper film were formed with a sputtering apparatus.

Next, the insulating film 104 was formed over the substrate 102 and the conductive film 106. Note that in this example, as the insulating film 104, the insulating films 104_1, 104_2, 104_3, and 104_4 were successively formed in this order with a PECVD apparatus in a vacuum. A 50-nm-thick silicon nitride film was formed as the insulating film 104_1. A 300-nm-thick silicon nitride film was formed as the insulating film 104_2. A 50-nm-thick silicon nitride film was formed as the insulating film 104_3. A 50-nm-thick silicon oxynitride film was formed as the insulating film 104_4.

Next, an oxide semiconductor film was formed over the insulating film 104 and was processed into an island shape, whereby the oxide semiconductor film 108 was formed. A 40-nm-thick oxide semiconductor film was formed as the oxide semiconductor film 108.

The oxide semiconductor film 108 was formed under the following conditions: the substrate temperature was 170° C.; an argon gas with a flow rate of 140 sccm and an oxygen gas with a flow rate of 60 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). The oxygen flow rate ratio for fabricating Samples G1 and G2 was 30%.

Note that processing into the oxide semiconductor film 108 was performed by a wet etching method.

Next, an insulating film to be the insulating film 110 was formed over the insulating film 104 and the oxide semiconductor film 108. As the insulating film, a 50-nm-thick silicon oxynitride film was formed with a PECVD apparatus.

Next, heat treatment was performed at 350° C. in a nitrogen gas atmosphere for one hour.

Next, the opening 143 was formed at desired regions in the insulating film 104 and the insulating film to be the insulating film 110. A formation method of the opening 143 was a dry etching method.

Next, a 100-nm-thick oxide semiconductor film was formed over the insulating film to cover the opening 143, and the oxide semiconductor film was processed into an island shape, whereby the conductive film 112 was formed. The insulating film in contact with the bottom surface of the conductive film 112 was processed in succession to the formation of the conductive film 112, whereby the insulating film 110 was formed.

As the conductive film 112, a 100-nm-thick oxide semiconductor film was formed. The oxide semiconductor film had a stacked-layer structure including two layers. A first layer in the oxide semiconductor film was formed to have thickness of 10 nm under the following conditions: the substrate temperature was 170° C.; an oxygen gas with a flow rate of 200 sccm was introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). A second layer in the oxide semiconductor film was formed to have a thickness of 90 nm under the following conditions: the substrate temperature was 170° C.; an argon gas with a flow rate of 180 sccm and an oxygen gas with a flow rate of 20 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]).

Note that processing into the conductive film 112 was performed by a wet etching method, and processing into the insulating film 110 was performed by a dry etching method.

Next, plasma treatment was performed on the insulating film 104, the oxide semiconductor film 108, the insulating film 110, and the conductive film 112. In the plasma treatment, a PECVD apparatus was used, the substrate temperature was 220° C., an argon gas with a flow rate of 100 sccm and a nitrogen gas with a flow rate of 1000 sccm were introduced into a chamber, the pressure was set to 40 Pa, and an RF power of 1000 W was applied.

Then, the insulating film 116 was formed over the insulating film 104, the oxide semiconductor film 108, the insulating film 110, and the conductive film 112. As the insulating film 116, a 100-nm-thick silicon nitride film was formed with a PECVD apparatus. The above plasma treatment and the formation of the insulating film 116 were successively performed in this order with a PECVD apparatus in a vacuum.

Next, the insulating film 118 was formed over the insulating film 116. As the insulating film 118, a 300-nm-thick silicon oxynitride film was formed with a PECVD apparatus.

Next, a mask was formed over the insulating film 118, and the openings 141a and 141b were formed in the insulating films 116 and 118 using the mask. Processing into the openings 141a and 141b was performed with a dry etching apparatus.

Next, a conductive film was formed over the insulating film 118 so as to fill the openings 141a and 141b and was processed into island shapes, whereby the conductive films 120a and 120b were formed.

For the conductive films 120a and 120b, a 10-nm-thick titanium film and a 100-nm-thick copper film were formed, respectively, with a sputtering apparatus.

Next, the insulating film 122 was formed over the insulating film 118 and the conductive films 120a and 120b. A 1.5-μm-thick acrylic-based photosensitive resin film was used as the insulating film 122.

Through the above-described steps, the transistor corresponding to the transistor 100B illustrated in FIGS. 17A and 17B was formed.

Note that although the transistor size is different between Samples G1 and G2, the fabrication methods of Samples G1 and G2 are the same as each other

<7-2. I_{d}-V_{g} Characteristics of Transistor>

Next, I_{d}-V_{g} characteristics of Samples G1 and G2 were measured.

The measurement conditions of I_{d}-V_{g} characteristics of the transistors were the same as those in Example 2.

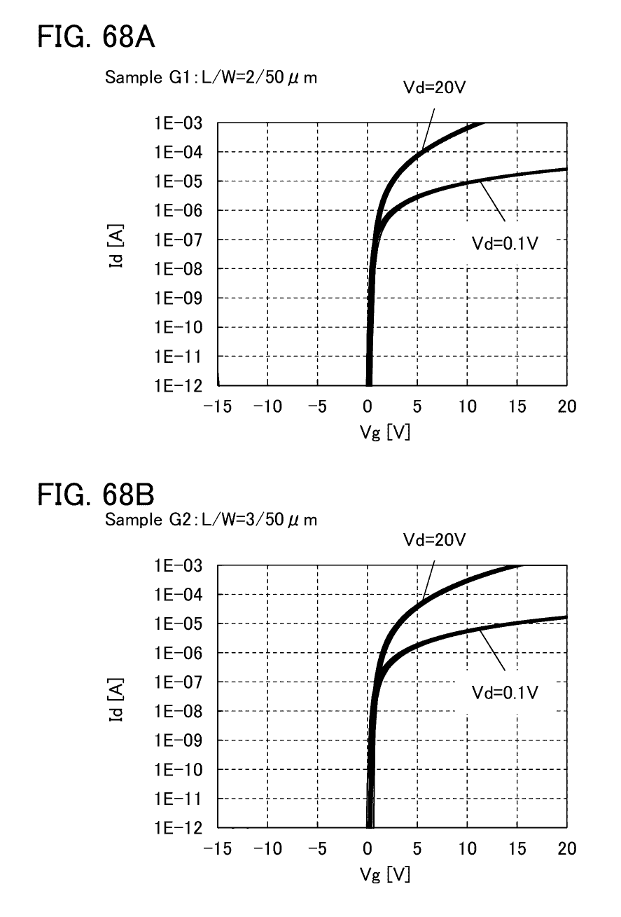

FIG. 68A shows the I_{d}-V_{g} characteristics of Sample G1, and FIG. 68B shows the I_{d}-V_{g} characteristics of Sample G2. In each of FIGS. 68A and 68B, the vertical axis represents I_{d} (A), and the horizontal axis represents V_{g} (V). FIGS. 68A and 68B show superimposed I_{d}-V_{g} characteristics of the 20 transistors of Samples G1 and G2, respectively.

As shown in FIGS. 68A and 68B, Samples G1 and G2 have favorable electrical characteristics.

<7-3. I_{d}/W−V_{d} Characteristics>

Next, I_{d}/W−V_{d} characteristics of the transistors in Samples G1 and G2 were measured. Note that one transistor was randomly selected in each of Samples G1 and G2, and I_{d}/W−V_{d} characteristics of the transistors were measured.

As the conditions for measuring the I_{d}/W−V_{d} characteristics of the transistor in Sample G1, V_{g} and V_{bg} were each 4.5 V, Vₛ was 0 V (comm), and V_{d} was applied from 0 V to 12 V at intervals of 0.25 V. As the conditions for measuring the I_{d}/W−V_{d} characteristics of the transistor in Sample G2, V_{g} and V_{bg} were each 4.05 V, Vₛ was 0 V (comm), and V_{d} was applied from 0 V to 12 V at intervals of 0.25 V.

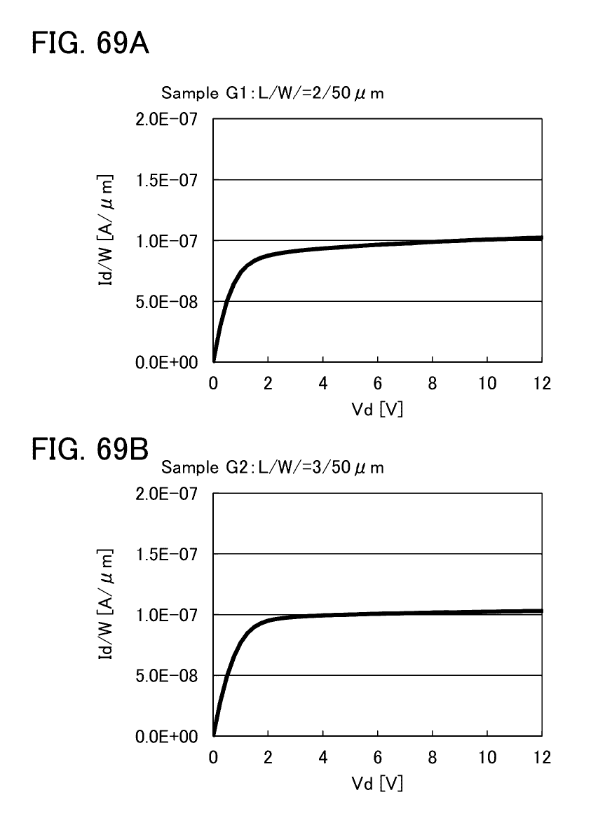

FIG. 69A shows measurement results of the I_{d}/W−V_{d} characteristics in Sample G1, and FIG. 69B shows measurement results of the I_{d}/W−V_{d} characteristics in Sample G2. In each of FIGS. 69A and 69B, the vertical axis represents I_{d}/W (A/μm), and the horizontal axis represents V_{d} (V). Note that I_{d}/W (A/μm) on the vertical axis is a value obtained by dividing the drain current flowing in the transistor by the channel width of the transistor.

As shown in FIGS. 69A and 69B, Samples G1 and G2 each have high saturability of I_{d}/W with respect to V_{d}, i.e., high consistency of current. Such a transistor can be preferably used as a driver FET for an organic EL display device.

### <7-4. Cross-Sectional Observation of Transistor>

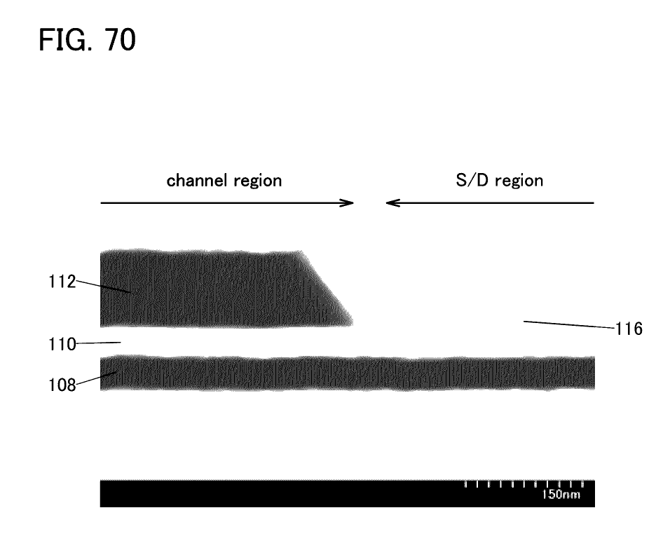

Next, a cross section at an end of a gate, in the channel length direction, of one transistor in Sample G1 was observed. Note that the cross-sectional observation was performed with a scanning transmission electron microscope (STEM). FIG. 70 shows a cross-sectional STEM observation result of Sample G1.

In FIG. 70, “S/D region” represents a source or drain region. As shown in FIG. 70, the transistor of one embodiment of the present invention has a favorable cross-sectional shape.

Note that the structure described in this example can be combined as appropriate with any of the structures described in the embodiments or the other examples.

### Example 8

In this example, a transistor in which the oxide semiconductor film of one embodiment of the present invention is used for a channel region was fabricated, and electrical characteristics of the transistor were measured. Sample H1 was fabricated in this example.

Note that Sample H1 was a transistor with a channel length L of 0.75 μm and a channel width W of 3 μm.

Note that Sample H1 is a sample in which transistors each corresponding to the transistor 100B illustrated in FIGS. 17A and 17B are formed over a substrate. In the description below, the same reference numerals are used for components having functions similar to those in the components of the transistor 100B illustrated in FIGS. 17A and 17B.

### <8-1. Method for Fabricating Sample H1>

First, the substrate 102 was prepared. As the substrate 102, a glass substrate was used. Next, the conductive film 106 was formed over the substrate 102. For the conductive film 106, a 10-nm-thick titanium film and a 100-nm-thick copper film were formed with a sputtering apparatus.

Next, the insulating film 104 was formed over the substrate 102 and the conductive film 106. Note that in this example, as the insulating film 104, the insulating films 104_1, 104_2, 104_3, and 104_4 were successively formed in this order with a PECVD apparatus in a vacuum. A 50-nm-thick silicon nitride film was formed as the insulating film 104_1. A 300-nm-thick silicon nitride film was formed as the insulating film 104_2. A 50-nm-thick silicon nitride film was formed as the insulating film 104_3. A 50-nm-thick silicon oxynitride film was formed as the insulating film 104_4.

Next, an oxide semiconductor film was formed over the insulating film 104 and was processed into an island shape, whereby the oxide semiconductor film 108 was formed. A 40-nm-thick oxide semiconductor film was formed as the oxide semiconductor film 108.

The oxide semiconductor film 108 was formed under the following conditions: the substrate temperature was 170° C.; an argon gas with a flow rate of 140 sccm and an oxygen gas with a flow rate of 60 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). The oxygen flow rate ratio for fabricating Sample H1 was 30%.

Note that processing into the oxide semiconductor film 108 was performed by a wet etching method.

Next, an insulating film to be the insulating film 110 was formed over the insulating film 104 and the oxide semiconductor film 108. As the insulating film, a 50-nm-thick silicon oxynitride film was formed with a PECVD apparatus.

Next, heat treatment was performed at 350° C. in a nitrogen gas atmosphere for one hour.

Next, the opening 143 was formed at desired regions in the insulating film 104 and the insulating film to be the insulating film 110. A formation method of the opening 143 was a dry etching method.

Next, a 100-nm-thick oxide semiconductor film was formed over the insulating film so as to cover the opening 143, and the oxide semiconductor film was processed into an island shape, whereby the conductive film 112 was formed. The insulating film in contact with the bottom surface of the conductive film 112 was processed in succession to the formation of the conductive film 112, whereby the insulating film 110 was formed.

As the conductive film 112, a 100-nm-thick oxide semiconductor film was formed. The oxide semiconductor film had a stacked-layer structure including two layers. A first layer in the oxide semiconductor film was formed to have thickness of 10 nm under the following conditions: the substrate temperature was 170° C.; an oxygen gas with a flow rate of 200 sccm was introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]). A second layer in the oxide semiconductor film was formed to have a thickness of 90 nm under the following conditions: the substrate temperature was 170° C.; an argon gas with a flow rate of 180 sccm and an oxygen gas with a flow rate of 20 sccm were introduced into a chamber of the sputtering apparatus; the pressure was set to 0.6 Pa; and an AC power of 2.5 kW was applied to a metal oxide target containing indium, gallium, and zinc (In:Ga:Zn=4:2:4.1 [atomic ratio]).

Note that processing into the conductive film 112 was performed by a wet etching method, and processing into the insulating film 110 was performed by a dry etching method.

Next, plasma treatment was performed on the insulating film 104, the oxide semiconductor film 108, the insulating film 110, and the conductive film 112. In the plasma treatment, a PECVD apparatus was used, the substrate temperature was 220° C., an argon gas with a flow rate of 100 sccm and a nitrogen gas with a flow rate of 1000 sccm were introduced into a chamber, the pressure was set to 40 Pa, and an RF power of 1000 W was applied.

Then, the insulating film 116 was formed over the insulating film 104, the oxide semiconductor film 108, the insulating film 110, and the conductive film 112. As the insulating film 116, a 100-nm-thick silicon nitride film was formed with a PECVD apparatus. The above plasma treatment and the formation of the insulating film 116 were successively performed in this order with a PECVD apparatus in a vacuum.

Next, the insulating film 118 was formed over the insulating film 116. As the insulating film 118, a 300-nm-thick silicon oxynitride film was formed with a PECVD apparatus.

Next, a mask was formed over the insulating film 118, and the openings 141a and 141b were formed in the insulating films 116 and 118 using the mask. Processing into the openings 141a and 141b was performed with a dry etching apparatus.

Next, a conductive film was formed over the insulating film 118 so as to fill the openings 141a and 141b and was processed into island shapes, whereby the conductive films 120a and 120b were formed.

For the conductive films 120a and 120b, a 10-nm-thick titanium film and a 100-nm-thick copper film were formed, respectively, with a sputtering apparatus.

Next, the insulating film 122 was formed over the insulating film 118 and the conductive films 120a and 120b. A 1.5-μm-thick acrylic-based photosensitive resin film was used as the insulating film 122.

Through the above-described steps, the transistor corresponding to the transistor 100B illustrated in FIGS. 17A and 17B was formed.

<8-2. I_{d}-V_{g} Characteristics of Transistor>

Next, I_{d}-V_{g} characteristics of Sample H1 were measured.

The measurement conditions of I_{d}-V_{g} characteristics of the transistor were the same as those in Example 2. Note that the range of voltage applied to V_{g} and V_{bg} was from −10 V to +10 V.

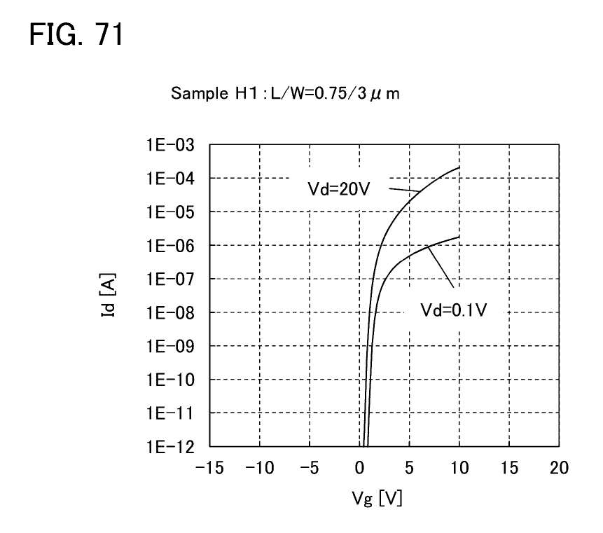

FIG. 71 shows the I_{d}-V_{g} characteristics of Sample H1. In FIG. 71, the vertical axis represents I_{d} (A), and the horizontal axis represents V_{g} (V).

As shown in FIG. 71, Sample H1 shows favorable electrical characteristics.

### <8-3. Cross-Sectional Observation of Transistor>

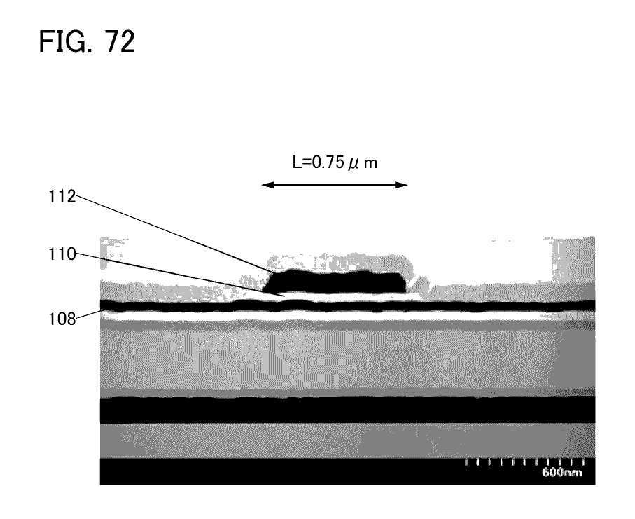

Next, a cross section of the transistor, in the channel length direction, of Sample H1 was observed. The cross-sectional observation was performed with an STEM. FIG. 72 shows a result of the cross-sectional STEM observation of Sample H1.

As shown in FIG. 72, the transistor of one embodiment of the present invention has a favorable cross-sectional shape even when having a short channel length of 0.75 μm.

Note that the structure described in this example can be combined as appropriate with any of the structures described in the embodiments or the other examples.

### EXPLANATION OF REFERENCE

100: transistor, 100A: transistor, 100B: transistor, 100C: transistor, 100D: transistor, 100E: transistor, 100F: transistor, 100G: transistor, 100H: transistor, 100J: transistor, 100K: transistor, 102: substrate, 104: insulating film, 104_1: insulating film, 104_2: insulating film, 104_3: insulating film, 104_4: insulating film, 106: conductive film, 108: oxide semiconductor film, 108_1: oxide semiconductor film, 108_2: oxide semiconductor film, 108_3: oxide semiconductor film, 108d: drain region, 108f: region, 108i: channel region, 108s: source region, 110: insulating film, 112: conductive film, 112_1: conductive film, 112_2: conductive film, 114: insulating film, 116: insulating film, 118: insulating film, 120a: conductive film, 120b: conductive film, 122: insulating film, 141a: opening, 141b: opening, 143: opening, 300A: transistor, 300B: transistor, 300C: transistor, 300D: transistor, 300E: transistor, 300F: transistor, 300G: transistor, 302: substrate, 304: conductive film, 306: insulating film, 307: insulating film, 308: oxide semiconductor film, 308_1: oxide semiconductor film, 308_2: oxide semiconductor film, 308_3: oxide semiconductor film, 312a: conductive film, 312b: conductive film, 312c: conductive film, 314: insulating film, 316: insulating film, 318: insulating film, 320a: conductive film, 320b: conductive film, 341a: opening, 341b: opening, 342a: opening, 342b: opening, 342c: opening, 351: opening, 352a: opening, 352b: opening, 501: pixel circuit, 502: pixel portion, 504: driver circuit portion, 504a: gate driver, 504b: source driver, 506: protection circuit, 507: terminal portion, 550: transistor, 552: transistor, 554: transistor, 560: capacitor, 562: capacitor, 570: liquid crystal element, 572: light-emitting element, 602: substrate, 604a: conductive film, 604b: conductive film, 606: insulating film, 607: insulating film, 609: oxide semiconductor film, 612d: conductive film, 612e: conductive film, 618: insulating film, 642a: opening, 644a: opening, 644b: opening, 646a: opening, 646b: opening, 650: sample for evaluation, 664: electrode, 665: electrode, 667: electrode, 700: display device, 701: substrate, 702: pixel portion, 704: source driver circuit portion, 705: substrate, 706: gate driver circuit portion, 708: FPC terminal portion, 710: signal line, 711: wiring portion, 712: sealant, 716: FPC, 730: insulating film, 732: sealing film, 734: insulating film, 736: coloring film, 738: light-blocking film, 750: transistor, 752: transistor, 760: connection electrode, 770: planarization insulating film, 772: conductive film, 773: insulating film, 774: conductive film, 775: liquid crystal element, 776: liquid crystal layer, 778: structure body, 780: anisotropic conductive film, 782: light-emitting element, 786: EL layer, 788: conductive film, 790: capacitor, 791: touch panel, 792: insulating film, 793: electrode, 794: electrode, 795: insulating film, 796: electrode, 797: insulating film, 800: inverter, 810: OS transistor, 820: OS transistor, 831: signal waveform, 832: signal waveform, 840: dashed line, 841: solid line, 850: OS transistor, 860: CMOS inverter, 900: semiconductor device, 901: power supply circuit, 902: circuit, 903: voltage generation circuit, 903A: voltage generation circuit, 903B: voltage generation circuit, 903C: voltage generation circuit, 904: circuit, 905: voltage generation circuit, 906: circuit, 911: transistor, 912: transistor, 912A: transistor, 912B: transistor, 921: control circuit, 922: transistor, 1102: substrate, 1108: oxide semiconductor film, 1110: insulating film, 1112: oxide semiconductor film, 7000: display module, 7001: upper cover, 7002: lower cover, 7003: FPC, 7004: touch panel, 7005: FPC, 7006: display panel, 7007: backlight, 7008: light source, 7009: frame, 7010: printed board, 7011: battery, 8000: camera, 8001: housing, 8002: display portion, 8003: operation button, 8004: shutter button, 8006: lens, 8100: finder, 8101: housing, 8102: display portion, 8103: button, 8200: head-mounted display, 8201: mounting portion, 8202: lens, 8203: main body, 8204: display portion, 8205: cable, 8206: battery, 8300: head-mounted display, 8301: housing, 8302: display portion, 8304: fixing band, 8305: lens, 9000: housing, 9001: display portion, 9003: speaker, 9005: operation key, 9006: connection terminal, 9007: sensor, 9008: microphone, 9050: operation button, 9051: information, 9052: information, 9053: information, 9054: information, 9055: hinge, 9100: television device, 9101: portable information terminal, 9102: portable information terminal, 9200: portable information terminal, 9201: portable information terminal, 9500: display device, 9501: display panel, 9502: display region, 9503: region, 9511: hinge, 9512: bearing

This application is based on Japanese Patent Application serial no. 2015-241798 filed with Japan Patent Office on Dec. 11, 2015, the entire contents of which are hereby incorporated by reference.

1. An oxide semiconductor film comprising In, M (M is any one of Al, Ga, Y, and Sn), and Zn,
wherein the oxide semiconductor film includes a region with a film density higher than or equal to 6.3 g/cm³ and lower than 6.5 g/cm³.

2. The oxide semiconductor film according to claim 1,
wherein the oxide semiconductor film includes a crystal part, and
wherein the crystal part includes a region having c-axis alignment and a region having alignment different from the c-axis alignment.

3. The oxide semiconductor film according to claim 1,
wherein an atomic ratio of the In, to the M and the Zn is in a neighborhood of 4:2:3, and
wherein when a proportion of the In is 4, a proportion of the M is higher than or equal to 1.5 and lower than or equal to 2.5 and a proportion of the Zn is higher than or equal to 2 and lower than or equal to 4.

4. An oxide semiconductor film comprising In, M (M is any one of Al, Ga, Y, and Sn), and Zn,
wherein the oxide semiconductor film includes a region with an etching rate higher than or equal to 10 nm/min and lower than or equal to 45 nm/min when a phosphoric acid aqueous solution obtained by diluting 85 vol % phosphoric acid with water 100 times is used for etching.

5. The oxide semiconductor film according to claim 4,
wherein the oxide semiconductor film includes a crystal part, and
wherein the crystal part includes a region having c-axis alignment and a region having alignment different from the c-axis alignment.

6. The oxide semiconductor film according to claim 4,
wherein an atomic ratio of the In, to the M and the Zn is in a neighborhood of 4:2:3, and
wherein when a proportion of the In is 4, a proportion of the M is higher than or equal to 1.5 and lower than or equal to 2.5 and a proportion of the Zn is higher than or equal to 2 and lower than or equal to 4.

7. A semiconductor device comprising:
an oxide semiconductor film over a first insulating film;
a gate insulating film over the oxide semiconductor film;
a gate electrode over the gate insulating film; and
a second insulating film over the oxide semiconductor film and the gate electrode,
wherein the oxide semiconductor film comprises a channel region in contact with the gate insulating film, a source region in contact with the second insulating film, and a drain region in contact with the second insulating film, and
wherein the oxide semiconductor film includes a region with a film density higher than or equal to 6.3 g/cm³ and lower than 6.5 g/cm³.

8. The semiconductor device according to claim 7,
wherein the oxide semiconductor film comprises In, M (M is any one of Al, Ga, Y, and Sn), and Zn.

9. The semiconductor device according to claim 7,
wherein the oxide semiconductor film includes a crystal part, and
wherein the crystal part includes a region having c-axis alignment and a region having alignment different from the c-axis alignment.

10. A display device comprising:
the semiconductor device according to claim 7; and
a display element.

11. A display module comprising:
the display device according to claim 10; and
a touch sensor.

12. An electronic device comprising:
the semiconductor device according to claim 7; and
any one of an operation key and a battery.

13. A semiconductor device comprising:
a gate electrode;
a gate insulating film over the gate electrode;
an oxide semiconductor film over the gate insulating film; and
a pair of electrodes over the oxide semiconductor film,
wherein the oxide semiconductor film includes a region with a film density higher than or equal to 6.3 g/cm³ and lower than 6.5 g/cm³.

14. The semiconductor device according to claim 13,
wherein the oxide semiconductor film comprises In, M (M is any one of Al, Ga, Y, and Sn), and Zn.

15. The semiconductor device according to claim 13,
wherein the oxide semiconductor film includes a crystal part, and
wherein the crystal part includes a region having c-axis alignment and a region having alignment different from the c-axis alignment.

16. A display device comprising:
the semiconductor device according to claim 13; and
a display element.

17. A display module comprising:
the display device according to claim 16; and
a touch sensor.

18. An electronic device comprising:
the semiconductor device according to claim 13; and
any one of an operation key and a battery.
